(19) United States
(12) Patent Application Publication
(10) Pub. No.: US 2025/0194074 A1
(43) Pub. Date: Jun. 12, 2025

(54) Semiconductor Device and Method For Fabricating The Semiconductor Device

(71) Applicant: Semiconductor Energy Laboratory Co., Ltd., Kanagawa-ken (JP)

(72) Inventors: Tatsuya ONUKI, Atsugi, Kanagawa (JP); Hitoshi KUNITAKE, Machida, Tokyo (JP); Yoshiaki OIKAWA, Atsugi, Kanagawa (JP); Shunpei YAMAZAKI, Setagaya, Tokyo (JP)

(73) Assignee: Semiconductor Energy Laboratory Co., Ltd., Kanagawa-ken (JP)

(21) Appl. No.: 18/842,288

(22) PCT Filed: Feb. 17, 2023
(86) PCT No.: PCT/IB2023/051436

§ 371 Date: Aug. 28, 2024

(30) Foreign Application Priority Data
Mar. 4, 2022 (JP) 2022-033336

(51) Int. Cl. H10B 12/00

(52) U.S. Cl. CPC H10B 12/31; H10B 12/033; H10B 12/05

(57) ABSTRACT

A semiconductor device that can be scaled down or highly integrated is provided. The semiconductor device includes a memory cell including a transistor and a capacitor. One of a source electrode and a drain electrode of the transistor is electrically connected to one electrode of the capacitor. A metal oxide can be used for a semiconductor layer of the transistor. An insulator is provided over the transistor, and an opening including a region overlapping with one of the source electrode and the drain electrode of the transistor and a region overlapping with a gate electrode of the transistor is provided in the insulator. The capacitor is provided in the opening. Accordingly, the area occupied by the memory cell is reduced while the capacitance of the capacitor is being ensured.

### TECHNICAL FIELD

One embodiment of the present invention relates to a transistor, a semiconductor device, a memory device, and an electronic device. Another embodiment of the present invention relates to a method for fabricating a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an image capturing device, an electronic device, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, the development of semiconductor devices has progressed, and a large-scale integration (LSI), a central processing unit (CPU), a memory, and the like are mainly used in the semiconductor devices. A CPU is an aggregation of semiconductor elements; the CPU includes a semiconductor integrated circuit formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in an off state. For example, Patent Document 1 discloses a low-power-consumption CPU utilizing a characteristically low leakage current of the transistor using an oxide semiconductor. Furthermore, for example, Patent Document 2 discloses a memory device that can retain stored contents for a long time by utilizing a characteristically low leakage current of the transistor using an oxide semiconductor.

In recent years, demand for an integrated circuit with higher density has risen with reductions in size and weight of electronic devices. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor using an oxide semiconductor film and a second transistor using an oxide semiconductor film.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be scaled down or highly integrated. Another object is to provide a semiconductor device with low power consumption. Another object is to provide a highly reliable semiconductor device. Another object is to provide a semiconductor device that operates at high speed. Another object is to provide a semiconductor device having excellent electrical characteristics. Another object is to provide a semiconductor device including a transistor with a small variation in electrical characteristics. Another object is to provide a semiconductor device including a transistor with a low off-state current. Another object is to provide a novel semiconductor device. Another object is to provide a memory device including any of the above semiconductor devices.

Another object is to provide a method for fabricating a semiconductor device that can be scaled down or highly integrated. Another object is to provide a method for fabricating a semiconductor device with low power consumption. Another object is to provide a method for fabricating a highly reliable semiconductor device. Another object is to provide a method for fabricating a semiconductor device that operates at high speed. Another object is to provide a method for fabricating a semiconductor device having excellent electrical characteristics. Another object is to provide a method for fabricating a semiconductor device including a transistor with a small variation in electrical characteristics. Another object is to provide a method for fabricating a semiconductor device including a transistor with a low off-state current. Another object is to provide a method for fabricating a novel semiconductor device. Another object is to provide a method for fabricating a memory device including any of the above semiconductor devices.

Note that the description of these objects does not preclude the existence of other objects. Note that one embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a semiconductor device including a first conductor, a first insulator, a second insulator, and a memory cell including a transistor and a capacitor. The transistor includes a metal oxide, a second conductor, a third conductor, a fourth conductor, and a third insulator. The capacitor includes a fifth conductor, a sixth conductor, and a fourth insulator. The second conductor covers a part of a top surface and a part of a side surface of the metal oxide and is electrically connected to the metal oxide. The third conductor covers a part of the top surface and a part of the side surface of the metal oxide and is electrically connected to the metal oxide. The third insulator includes a region provided between the second conductor and the third conductor. The fourth conductor is provided over the third insulator. The first insulator is provided over the fourth conductor. The second insulator is provided over the first insulator. The second insulator has an opening including a region overlapping with at least one of the second to fourth conductors. The fifth conductor includes a region provided in the opening and is electrically connected to the second conductor. The fourth insulator is provided over the fifth conductor and includes a region provided in the opening. The sixth conductor is provided over the fourth insulator and includes a region provided in the opening. The first conductor includes a region in contact with a first side surface of the first insulator, a region in contact with a side surface of the second insulator, and a region in contact with a side surface of the third conductor.

Another embodiment of the present invention is a semiconductor device including a plurality of layers each including a first conductor, a first insulator, a second insulator, and a memory cell including a transistor and a capacitor. The plurality of layers are stacked. The transistor includes a metal oxide, a second conductor, a third conductor, a fourth conductor, and a third insulator. The capacitor includes a fifth conductor, a sixth conductor, and a fourth insulator. The second conductor covers a part of a top surface and a part of a side surface of the metal oxide and is electrically connected to the metal oxide. The third conductor covers a part of the top surface and a part of the side surface of the metal oxide and is electrically connected to the metal oxide. The third insulator includes a region provided between the second conductor and the third conductor. The fourth conductor is provided over the third insulator. The first insulator is provided over the fourth conductor. The second insulator is provided over the first insulator. The second insulator has an opening including a region overlapping with at least one of the second to fourth conductors. The fifth conductor includes a region provided in the opening and is electrically connected to the second conductor. The fourth insulator is provided over the fifth conductor and includes a region provided in the opening. The sixth conductor is provided over the fourth insulator and includes a region provided in the opening. The first conductor includes a region in contact with a first side surface of the first insulator, a region in contact with a side surface of the second insulator, and a region in contact with a side surface of the third conductor. The plurality of first conductors are electrically connected to each other.

In the above embodiment, the memory cell may include a seventh conductor and an eighth conductor, the first insulator may be provided over the second conductor, the seventh conductor may include a region in contact with a second side surface of the first insulator, the eighth conductor may include a region in contact with a top surface of the first insulator, and the second conductor and the fifth conductor may be electrically connected to each other through the seventh conductor and the eighth conductor.

In the above embodiment, the seventh conductor may include a region in contact with a top surface of the second conductor, and the eighth conductor may include a region in contact with a top surface of the seventh conductor.

In the above embodiment, the second insulator may cover a top surface and a side surface of the eighth conductor, and the opening may reach the eighth conductor.

In the above embodiment, the first insulator may be provided over the third conductor, and, in a cross-sectional view, a width of the first conductor in the region in contact with the third conductor may be smaller than a width of the first conductor in the region in contact with the first insulator.

In the above embodiment, the metal oxide may contain indium, zinc, and one or more selected from gallium, aluminum, and tin.

Another embodiment of the present invention is a method for fabricating a semiconductor device, in which a metal oxide is formed; a first conductive film is formed over the metal oxide; a conductive layer covering a top surface and a side surface of the metal oxide is formed by processing the first conductive film; a first conductor and a second conductor each partly covering the top surface and the side surface of the metal oxide are formed by forming a first opening reaching the metal oxide in the conductive layer; a first insulator including a region positioned in the first opening and a third conductor over the first insulator are formed; a second insulator is formed over the first to third conductors; a third insulator is formed over the second insulator; a second opening including a region overlapping with at least one of the first to third conductors is formed in the third insulator; a fourth conductor electrically connected to the first conductor, a fourth insulator over the fourth conductor, and a fifth conductor over the fourth insulator are formed in the second opening; a third opening is formed in the third insulator and the second insulator to expose a side surface of the second conductor; and a sixth conductor is formed to include a region in contact with the side surface of the second conductor, a region in contact with a first side surface of the second insulator, and a region in contact with a side surface of the third insulator.

In the above embodiment, the metal oxide, the first to third conductors, and the first insulator may form a transistor; the fourth conductor, the fourth insulator, and the fifth conductor may form a capacitor; and the transistor and the capacitor may form a memory cell.

In the above embodiment, a fourth opening reaching the first conductor may be formed in the second insulator after the second insulator is formed; a seventh conductor may be formed in the fourth opening; an eighth conductor may be formed to include a region in contact with the seventh conductor and a region in contact with the second insulator; the third insulator may be formed to cover a top surface and a side surface of the eighth conductor; and the second opening reaching the eighth conductor may be formed in the third insulator.

In the above embodiment, the third opening may be formed such that the side surface of the second conductor protrudes from the side surface of the second insulator.

### Effect of the Invention

According to one embodiment of the present invention, a semiconductor device that can be scaled down or highly integrated can be provided. Alternatively, a semiconductor device with low power consumption can be provided. Alternatively, a highly reliable semiconductor device can be provided. Alternatively, a semiconductor device that operates at high speed can be provided. Alternatively, a semiconductor device having excellent electrical characteristics can be provided. Alternatively, a semiconductor device including a transistor with a small variation in electrical characteristics can be provided. Alternatively, a semiconductor device including a transistor with a low off-state current can be provided. Alternatively, a novel semiconductor device can be provided. Alternatively, a memory device including any of the above semiconductor devices can be provided.

Alternatively, a method for fabricating a semiconductor device that can be scaled down or highly integrated can be provided. Alternatively, a method for fabricating a semiconductor device with low power consumption can be provided. Alternatively, a method for fabricating a highly reliable semiconductor device can be provided. Alternatively, a method for fabricating a semiconductor device that operates at high speed can be provided. Alternatively, a method for fabricating a semiconductor device having excellent electrical characteristics can be provided. Alternatively, a method for fabricating a semiconductor device including a transistor with a small variation in electrical characteristics can be provided. Alternatively, a method for fabricating a semiconductor device including a transistor with a low off-state current can be provided. Alternatively, a method for fabricating a novel semiconductor device can be provided. Alternatively, a method for fabricating a memory device including any of the above semiconductor devices can be provided.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1 is a circuit diagram illustrating structure examples of memory cells.

FIG. 2A and FIG. 2B are cross-sectional views illustrating a structure example of a semiconductor device of one embodiment of the present invention.

FIG. 3A and FIG. 3B are cross-sectional views illustrating structure examples of a capacitor.

FIG. 4A and FIG. 4B are cross-sectional views illustrating structure examples of a semiconductor device of one embodiment of the present invention.

FIG. 5A and FIG. 5B are cross-sectional views illustrating structure examples of a semiconductor device of one embodiment of the present invention.

FIG. 6 is a cross-sectional view illustrating a structure example of a semiconductor device of one embodiment of the present invention.

FIG. 7 is a cross-sectional view illustrating a structure example of a semiconductor device of one embodiment of the present invention.

FIG. 8 is a cross-sectional view illustrating a structure example of a semiconductor device of one embodiment of the present invention.

FIG. 9A and FIG. 9B are plan views illustrating structure examples of a semiconductor device of one embodiment of the present invention.

FIG. 10A and FIG. 10B are plan views illustrating structure examples of a semiconductor device of one embodiment of the present invention.

FIG. 11A to FIG. 11D are cross-sectional views illustrating an example of a method for fabricating a semiconductor device of one embodiment of the present invention.

FIG. 12A to FIG. 12C are cross-sectional views illustrating an example of a method for fabricating a semiconductor device of one embodiment of the present invention.

FIG. 13A and FIG. 13B are cross-sectional views illustrating an example of a method for fabricating a semiconductor device of one embodiment of the present invention.

FIG. 14A and FIG. 14B are cross-sectional views illustrating an example of a method for fabricating a semiconductor device of one embodiment of the present invention.

FIG. 15A and FIG. 15B are cross-sectional views illustrating an example of a method for fabricating a semiconductor device of one embodiment of the present invention.

FIG. 16A and FIG. 16B are cross-sectional views illustrating an example of a method for fabricating a semiconductor device of one embodiment of the present invention.

FIG. 17A and FIG. 17B are cross-sectional views illustrating an example of a method for fabricating a semiconductor device of one embodiment of the present invention.

FIG. 18A and FIG. 18B are cross-sectional views illustrating an example of a method for fabricating a semiconductor device of one embodiment of the present invention.

FIG. 19 is a block diagram illustrating a structure example of a memory device of one embodiment of the present invention.

FIG. 20A is a perspective view illustrating a structure example of a memory device of one embodiment of the present invention. FIG. 20B is a schematic view illustrating the structure example of the memory device of one embodiment of the present invention.

FIG. 21A and FIG. 21B are schematic views illustrating structure examples of memory devices of one embodiment of the present invention.

FIG. 22 is a circuit diagram illustrating a structure example of a memory device of one embodiment of the present invention.

FIG. 23 is a timing chart showing an example of a method for operating a memory device of one embodiment of the present invention.

FIG. 24A and FIG. 24B are circuit diagrams illustrating structure examples of a memory device of one embodiment of the present invention.

FIG. 25A and FIG. 25B are circuit diagrams illustrating structure examples of a memory device of one embodiment of the present invention.

FIG. 26A is a block diagram illustrating a structure example of a chip. FIG. 26B is a perspective view illustrating a structure example of a GPU module.

FIG. 27A and FIG. 27B are perspective views illustrating structure examples of electronic components.

FIG. 28A to FIG. 28E are schematic views illustrating examples of memory devices of one embodiment of the present invention.

FIG. 29A to FIG. 29H are schematic views illustrating examples of electronic devices.

FIG. 30 is a schematic view illustrating an example of a device for space.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes, values, or the like shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions and the portions are not especially denoted by reference numerals in some cases.

The ordinal numbers such as first and second in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in the specification, the description can be changed appropriately depending on the situation.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that a metal oxide containing nitrogen is also referred to as a metal oxide in some cases. Furthermore, a metal oxide containing nitrogen may be referred to as a metal oxynitride.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, or a potential output from a circuit or the like, for example, changes with a change in the reference potential.

Note that in this specification and the like, the expression “level or substantially level” indicates a structure in which levels from a reference surface, specifically a flat surface such as a substrate surface, for example, are the same in a cross-sectional view. For example, in a fabrication process of a semiconductor device, the surface(s) of a single layer or a plurality of layers are sometimes exposed by planarization treatment, typically chemical mechanical polishing (CMP) treatment. In that case, the surfaces on which the CMP treatment is performed are at the same level from a reference surface. Note that the plurality of layers are not level with each other in some cases, depending on a treatment apparatus, a treatment method, or a material of the treated surfaces at the time when the CMP treatment is performed. This case is sometimes also regarded as being “level or substantially level” in this specification and the like. For example, the expression “level or substantially level” can also be used in the case where a level difference with respect to a reference surface between a first layer and a second layer is less than or equal to 20 nm.

Note that in this specification and the like, the expression “end portions are aligned or substantially aligned” means that outlines of stacked layers at least partly overlap with each other in a plan view. For example, the case of processing an upper layer and a lower layer with the use of the same mask pattern or mask patterns that are partly the same is included. Note that in some cases, the outlines do not exactly overlap with each other and the outline of the upper layer is located inward from the outline of the lower layer or the outline of the upper layer is located outward from the outline of the lower layer; such a case is also represented by the expression “end portions are aligned or substantially aligned”.

### Embodiment 1

In this embodiment, a structure example of a semiconductor device of one embodiment of the present invention and an example of a fabrication method thereof will be described.

One embodiment of the present invention relates to a semiconductor device in which a memory cell including a transistor and a capacitor is provided. One of a source electrode and a drain electrode of the transistor is electrically connected to one electrode of the capacitor. A metal oxide can be used for a semiconductor layer of the transistor.

In the semiconductor device of one embodiment of the present invention, the capacitor is provided over the transistor. Specifically, an insulator is provided over the transistor, and an opening including a region overlapping with the transistor is provided in the insulator. The opening specifically includes a region overlapping with one of the source electrode and the drain electrode of the transistor and a region overlapping with a gate electrode of the transistor, for example. The capacitor is provided in the opening.

In this specification and the like, the term “opening” can include a groove, a slit, and the like.

In the semiconductor device of one embodiment of the present invention, the area occupied by the memory cell can be reduced while the capacitance is being ensured as compared with the case where the capacitor is provided so as not to overlap with the gate electrode of the transistor, specifically provided next to the gate electrode, or the case where the opening is not provided in the insulator and the capacitor is placed, for example. Thus, the semiconductor device of one embodiment of the present invention can be a semiconductor device that can be scaled down or highly integrated. When the capacitance is ensured, data can be retained in the memory cell for a long time, so that the frequency of refresh operations for the memory cell can be reduced. Thus, the semiconductor device of one embodiment of the present invention can be a semiconductor device with low power consumption. In addition, when the capacitance is ensured, the semiconductor device of one embodiment of the present invention can perform a reading operation stably. Thus, the semiconductor device of one embodiment of the present invention can be a highly reliable semiconductor device.

### Structure Example 1 of Semiconductor Device

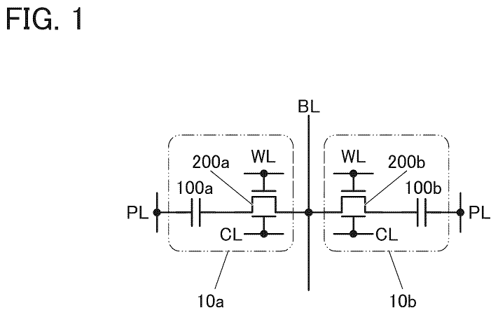

FIG. 1 is a circuit diagram illustrating a structure example of the semiconductor device of one embodiment of the present invention. The semiconductor device of one embodiment of the present invention includes a memory cell 10a and a memory cell 10b illustrated in FIG. 1. The semiconductor device of one embodiment of the present invention can be used as a memory device.

The memory cell 10a includes a transistor 200a and a capacitor 100a. The memory cell 10b includes a transistor 200b and a capacitor 100b.

One of a source electrode and a drain electrode of the transistor 200a is electrically connected to one electrode of the capacitor 100a. One of a source electrode and a drain electrode of the transistor 200b is electrically connected to one electrode of the capacitor 100b. The other of the source electrode and the drain electrode of the transistor 200a and the other of the source electrode and the drain electrode of the transistor 200b are electrically connected to a wiring BL functioning as a bit line. The other electrode of the capacitor 100a and the other electrode of the capacitor 100b are each electrically connected to a wiring PL functioning as a power supply line, e.g., a constant potential line.

The transistor 200a and the transistor 200b each include a first gate electrode and a second gate electrode. The first gate electrode of the transistor 200a and the first gate electrode of the transistor 200b are each electrically connected to a wiring WL functioning as a word line. The second gate electrode of the transistor 200a and the second gate electrode of the transistor 200b are each electrically connected to a wiring CL. Note that each of the transistor 200a and the transistor 200b does not necessarily include the second gate electrode.

The transistor 200a and the transistor 200b each have a function of a switch. The capacitor 100a and the capacitor 100b have a function of retaining electric charge corresponding to data.

The on states (also referred to as conduction states) and the off states (also referred to as non-conduction states) of the transistor 200a and the transistor 200b can be controlled by control of the potential of the wiring WL. The threshold voltages of the transistor 200a and the transistor 200b can be controlled with the potential of the wiring CL. The potential of the wiring CL can be, for example, a constant potential. The potential of the wiring CL can be equal to the potential of the wiring PL, for example, in which case the number of wirings electrically connected to the memory cell 10a and the memory cell 10b can be reduced when the wiring CL and the wiring PL are electrically connected to each other.

Turning on the transistor 200a enables data to be written from the wiring BL to the memory cell 10a, and turning on the transistor 200b enables data to be written from the wiring BL to the memory cell 10b. Turning off the transistor 200a enables retention of the data written to the memory cell 10a, and turning off the transistor 200b enables retention of the data written to the memory cell 10b. When the transistor 200a is turned on while the data is being retained in the memory cell 10a, the data retained in the memory cell 10a can be read through the wiring BL, and when the transistor 200b is turned on while the data is being retained in the memory cell 10b, the data retained in the memory cell 10b can be read through the wiring BL.

Although the wiring WL electrically connected to the first gate electrode of the transistor 200a and the wiring WL electrically connected to the first gate electrode of the transistor 200b are separated from each other in FIG. 1, these wirings WL may be electrically connected to each other. Although the wiring CL electrically connected to the second gate electrode of the transistor 200a and the wiring CL electrically connected to the second gate electrode of the transistor 200b are separated from each other in FIG. 1, these wirings CL may be electrically connected to each other. Although the wiring PL electrically connected to the other electrode of the capacitor 100a and the wiring PL electrically connected to the other electrode of the capacitor 100b are separated from each other in FIG. 1, these wirings PL may be electrically connected to each other.

In the following description of matters common to the memory cell 10a and the memory cell 10b, the alphabets are omitted from the reference numerals and the term “memory cell 10” is used in some cases. Similarly, in the description of matters common to the transistor 200a and the transistor 200b, the term “transistor 200” is used in some cases. In the description of matters common to the capacitor 100a and the capacitor 100b, the term “capacitor 100” is used in some cases. Similarly, the alphabets are omitted from the reference numerals representing other components in some cases.

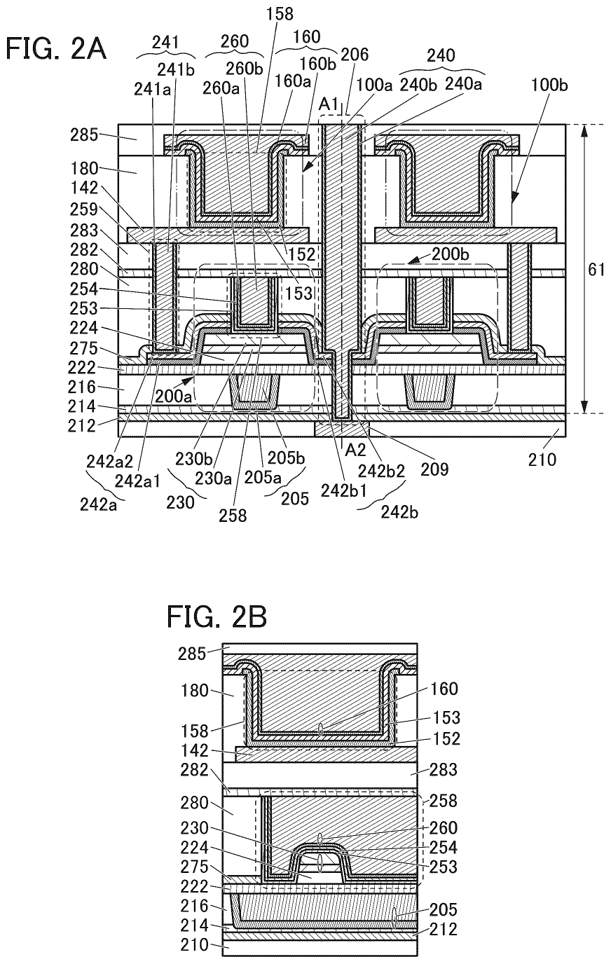

FIG. 2A is a cross-sectional view illustrating a structure example of the semiconductor device of one embodiment of the present invention. The semiconductor device of one embodiment of the present invention includes an insulator 210 over a substrate (not illustrated), an insulator 212 over the insulator 210, and a memory layer 61 over the insulator 212. The insulator 210 has an opening, and a conductor 209 is provided in the opening.

As the substrate, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate containing silicon or germanium as a material and a compound semiconductor substrate containing silicon carbide, silicon germanium, gallium arsenide, indium phosphide, zinc oxide, or gallium oxide as a material. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates may be provided with at least one of a capacitor, a resistor, a switch, a light-emitting device, a memory cell, and the like.

The memory layer 61 includes the transistor 200a, the transistor 200b, the capacitor 100a, and the capacitor 100b. Since the memory cell includes the transistor 200 and the capacitor 100 as described above, the memory cell is provided in the memory layer 61. FIG. 2A illustrates structure examples of two memory cells as a structure example of the memory layer 61. The two memory cells can be the memory cell 10a and the memory cell 10b illustrated in FIG. 1.

The memory layer 61 includes an insulator 214, an insulator 275, an insulator 280, an insulator 282, an insulator 283, an insulator 180, an insulator 285, a conductor 241, a conductor 142, a conductor 240, the transistor 200a, the transistor 200b, the capacitor 100a, and the capacitor 100b. The insulator 214 is provided over the insulator 212, and the transistor 200a and the transistor 200b are provided over the insulator 214. The insulator 275 is provided to partly cover the transistor 200. The insulator 280 is provided over the insulator 275, the insulator 282 is provided over the insulator 280 and the transistor 200, and the insulator 283 is provided over the insulator 282. An opening 259 reaching the transistor 200 is provided in the insulator 283, the insulator 282, the insulator 280, and the insulator 275, and the conductor 241 is placed in the opening 259. The conductor 142 is provided over the insulator 283 and the conductor 241. The insulator 180 is provided over the insulator 283 to cover the top surface and the side surface of the conductor 142. An opening 158 reaching the conductor 142 is provided in the insulator 180, and the capacitor 100 is placed in the opening 158. The insulator 285 is provided over the insulator 180 and the capacitor 100. An opening 206 reaching the conductor 209 is provided in the insulator 285, the insulator 180, the insulator 283, the insulator 282, the insulator 280, the insulator 275, an insulator 222, an insulator 216, the insulator 214, and the insulator 212, and the conductor 240 is placed in the opening 206. Here, the conductor 209 and the conductor 240 can correspond to the wiring BL illustrated in FIG. 1.

The transistor 200 includes a metal oxide 230 functioning as a semiconductor layer, a conductor 260 functioning as a first gate electrode (also referred to as a top gate electrode), a conductor 205 functioning as a second gate electrode (also referred to as a back gate electrode), a conductor 242a functioning as one of a source electrode and a drain electrode, and a conductor 242b functioning as the other of the source electrode and the drain electrode. An insulator 253 and an insulator 254 functioning as a first gate insulator are also included. The insulator 222 and an insulator 224 functioning as a second gate insulator are also included.

The conductor 242a and the conductor 242b partly cover the top surface and the side surface of the metal oxide 230 and, for example, are partly in contact with the top surface and the side surface of the metal oxide. The conductor 242a functions as one of the source electrode and the drain electrode of the transistor 200, and the conductor 242b functions as the other of the source electrode and the drain electrode of the transistor 200. Thus, the conductor 242a and the conductor 242b can be regarded as being electrically connected to the metal oxide 230.

An opening 258 reaching the metal oxide 230 is provided in the insulator 280 and the insulator 275. In the channel length direction of the transistor 200, the conductor 242a and the conductor 242b are provided to face each other with the opening 258 therebetween. Thus, the insulator 275 and the insulator 280 are provided over the conductor 242a and the conductor 242b.

The first gate insulator and the first gate electrode are provided in the opening 258. That is, the insulator 253, the insulator 254, and the conductor 260 are provided in the opening 258. Here, the uppermost portion of the insulator 253, the uppermost portion of the insulator 254, and the top surface of the conductor 260 can be level or substantially level with the top surface of the insulator 280. The insulator 282 is provided over the insulator 253, the insulator 254, the conductor 260, and the insulator 280.

The side surface of the opening 258 may be perpendicular or substantially perpendicular to the top surface of the insulator 222 or may have a tapered shape, for example. That is, the side surface of the insulator 280 may be perpendicular or substantially perpendicular to the top surface of the insulator 222 or may have a tapered shape in the opening 258, for example. The tapered side surface of the opening 258 can improve the coverage with the insulator 253 and the like provided in the opening 258; as a result, the number of defects such as voids can be reduced.

In this specification and the like, a tapered shape refers to such a shape that at least part of a side surface of a component is inclined with respect to a substrate surface or a formation surface. For example, the tapered shape refers to a shape including a region where the angle formed between the inclined side surface and the substrate surface or the formation surface (the angle is hereinafter referred to as a taper angle in some cases) is less than 90°. Note that the side surface of the component and the substrate surface or the formation surface are not necessarily completely flat, and may have a substantially planar shape with a slight curvature or a substantially planar shape with slight unevenness.

The insulator 253 is provided over the metal oxide 230 and includes a region in contact with the top surface of the metal oxide 230, for example. The insulator 253 can include a region in contact with at least part of the side surface of the insulator 275 and a region in contact with at least part of the side surface of the insulator 280. The insulator 254 is provided over the insulator 253, and the conductor 260 is provided over the insulator 254. The insulator 254 includes a region in contact with the side surface of the conductor 260 and a region in contact with the bottom surface of the conductor 260, for example. Accordingly, the insulator 253, the insulator 254, and the conductor 260 each include a region overlapping with the metal oxide 230. At least part of a region of the metal oxide 230 that overlaps with the conductor 260 functions as a channel formation region.

Here, at least the insulator 253 includes a region provided between the conductor 242a and the conductor 242b. The insulator 254 sometimes also includes a region provided between the conductor 242a and the conductor 242b. Furthermore, not only the insulator 253 and the insulator 254 but also the conductor 260 sometimes includes a region provided between the conductor 242a and the conductor 242b.

The capacitor 100 includes a conductor 152 and a conductor 160 that function as a pair of electrodes and an insulator 153 that is provided between the conductor 152 and the conductor 160 and functions as a dielectric. That is, the capacitor 100 forms a MIM (Metal-Insulator-Metal) capacitor. Here, the conductor 152 can be referred to as one electrode of the capacitor 100 or a lower electrode of the capacitor 100, and the conductor 160 can be referred to as the other electrode of the capacitor 100 or an upper electrode of the capacitor 100.

At least part of each of one electrode, the dielectric, and the other electrode of the capacitor 100 is placed in the opening 158 provided in the insulator 180. That is, the conductor 152, the insulator 153 over the conductor 152, and the conductor 160 over the insulator 153 each include a region provided in the opening 158.

The side surface of the opening 158 may be perpendicular or substantially perpendicular to the top surface of the insulator 222 or may have a tapered shape, for example. That is, the side surface of the insulator 180 may be perpendicular or substantially perpendicular to the top surface of the insulator 222 or may have a tapered shape in the opening 158, for example. The tapered side surface of the opening 158 can improve the coverage with the insulator 153 and the like provided in the opening 158; as a result, the number of defects such as voids can be reduced.

The conductor 242a functioning as one of the source electrode and the drain electrode of the transistor 200 is electrically connected to the conductor 152 functioning as one electrode of the capacitor 100 through the conductor 241 and the conductor 142. The conductor 241 and the conductor 142 function as a wiring (also referred to as a plug or a connection electrode). Note that the conductor 142 as well as the conductor 152 may function as one electrode of the capacitor 100. Furthermore, the conductor 152, the conductor 142, and the conductor 241 may function as one electrode of the capacitor 100.

The conductor 241 is provided in the opening 259. The conductor 241 includes a region in contact with the top surface of the conductor 242a, for example. The conductor 241 also includes a region in contact with the side surface of the opening 259. That is, the conductor 241 includes a region in contact with the side surface of the insulator 275, a region in contact with the side surface of the insulator 280, a region in contact with the side surface of the insulator 282, and a region in contact with the side surface of the insulator 283 in the opening 259, for example. The top surface of the conductor 241 can be level or substantially level with the top surface of the insulator 283.

The conductor 142 is provided between a plane including the top surface of the conductor 241 and a plane including the bottom surface of the conductor 152. For example, the conductor 142 includes a region in contact with the top surface of the conductor 241, a region in contact with the top surface of the insulator 283, and a region in contact with the bottom surface of the conductor 152.

In each of the memory cells included in the semiconductor device of one embodiment of the present invention, the opening 158 is provided in the insulator 180 over the transistor 200, and the capacitor 100 is provided in the opening 158. For example, the opening 158 is provided to include a region overlapping with at least one of the conductor 242a, the conductor 242b, and the conductor 260. Accordingly, the capacitor 100 includes a region overlapping with at least one of the conductor 242a, the conductor 242b, and the conductor 260. With such a structure, for example, the area occupied by the memory cells can be reduced while the capacitance of the capacitor 100 is being ensured as compared with the case where an opening reaching the conductor 242a is provided in the insulator 280 and the capacitor 100 is provided in the opening. Thus, the semiconductor device of one embodiment of the present invention can be a semiconductor device that can be scaled down or highly integrated.

When the capacitor 100 is provided in the opening 158, the conductor 152 and the conductor 160 can face each other with the insulator 153 therebetween not only in a position along the bottom surface of the opening 158 but also in a position along the side surface of the opening 158. Thus, the capacitance per unit area of the capacitor 100 can be larger than that in the case where an opening is not provided and the capacitor 100 is placed over an insulator, for example.

Increasing the capacitance of the capacitor 100 enables data to be retained in the memory cell for a long time. Specifically, increasing the capacitance of the capacitor 100 enables electric charge corresponding to data to be retained in the capacitor 100 for a long time. This can reduce the frequency of refresh operations for the memory cell. Thus, the semiconductor device of one embodiment of the present invention can be a semiconductor device with low power consumption. Increasing the capacitance of the capacitor 100 enables the semiconductor device of one embodiment of the present invention to perform a reading operation stably. Thus, the semiconductor device of one embodiment of the present invention can be a highly reliable semiconductor device. Here, the capacitor 100 preferably includes both a region overlapping with the conductor 242a and a region overlapping with the conductor 260, in which case the capacitance of the capacitor 100 can be larger than that in the case of not including the region overlapping with the conductor 260, for example. Furthermore, the capacitor 100 can be provided to include a region overlapping with the conductor 242b as well as the region overlapping with the conductor 242a and the region overlapping with the conductor 260. In a plan view, a region occupied by the metal oxide 230 overlaps with the capacitor 100, specifically with the opening 158, at preferably 50% or more, further preferably 70% or more, still further preferably 80% or more in an area ratio, for example. Thus, the semiconductor device of one embodiment of the present invention can be a semiconductor device that can be suitably scaled down or highly integrated.

The conductor 240 is provided in the opening 206. The conductor 240 includes a region in contact with the top surface of the conductor 209 and a region in contact with the side surface of the conductor 242b. In addition, the conductor 240 can include a region in contact with the top surface of the conductor 242b. The conductor 240 can also include a region in contact with at least part of the side surface of the insulator 212, a region in contact with at least part of the side surface of the insulator 214, a region in contact with at least part of the side surface of the insulator 216, a region in contact with at least part of the side surface of the insulator 222, a region in contact with at least part of the side surface of the insulator 275, a region in contact with at least part of the side surface of the insulator 280, a region in contact with at least part of the side surface of the insulator 282, a region in contact with at least part of the side surface of the insulator 283, a region in contact with at least part of the side surface of the insulator 180, and a region in contact with at least part of the side surface of the insulator 285.

In this specification and the like, the side surfaces of the insulator 275, the insulator 280, the insulator 282, and the insulator 283 in the opening 206 may be referred to as first side surfaces, and the side surfaces of the insulator 275, the insulator 280, the insulator 282, and the insulator 283 in the opening 259 may be referred to as second side surfaces. In that case, the conductor 240 can be regarded as including a region in contact with the first side surface of the insulator 275, a region in contact with the first side surface of the insulator 280, a region in contact with the first side surface of the insulator 282, and a region in contact with the first side surface of the insulator 283, and the conductor 241 can be regarded as including a region in contact with the second side surface of the insulator 275, a region in contact with the second side surface of the insulator 280, a region in contact with the second side surface of the insulator 282, and a region in contact with the second side surface of the insulator 283. Note that the side surfaces of the insulator 275, the insulator 280, the insulator 282, and the insulator 283 in the opening 259 may be referred to as the first side surfaces, and the side surfaces of the insulator 275, the insulator 280, the insulator 282, and the insulator 283 in the opening 206 may be referred to as the second side surfaces. The side surfaces of the insulator 275, the insulator 280, the insulator 282, and the insulator 283 in the opening 206 and/or the side surfaces of the insulator 275, the insulator 280, the insulator 282, and the insulator 283 in the opening 259 may be referred to as third side surfaces, fourth side surfaces, or the like, for example.

As described above, the conductor 209 and the conductor 240 correspond to the wiring BL illustrated in FIG. 1. In that case, the conductor 240 is electrically connected to a sense amplifier, for example. The conductor 209 and the conductor 240 can function as a plug or a wiring for electrically connecting the transistor 200 to a circuit element such as a switch, a transistor, a capacitor, an inductor, a resistor, or a diode, a wiring, an electrode, or a terminal.

The conductor 240 preferably has a stacked-layer structure of a conductor 240a and a conductor 240b. For example, as illustrated in FIG. 2A, the conductor 240 can have a structure in which the conductor 240a is provided to include a region in contact with the inner wall of the opening 206 and the conductor 240b is provided on the inner side. That is, the conductor 240a is provided closer to the insulator 285, the insulator 180, the insulator 283, the insulator 282, the insulator 280, the insulator 275, the conductor 242b, the insulator 222, the insulator 216, the insulator 214, and the insulator 212 than the conductor 240b is.

In this specification and the like, an inner wall of an opening refers to one or both of a side surface and a bottom surface of the opening.

Here, the conductor 240a is preferably formed by a deposition method that offers excellent coverage, such as an atomic layer deposition (ALD) method. The outline of the conductor 240a formed in this manner is substantially the same as the shape of the inner wall of the opening 206.

A conductive material having a function of inhibiting passage of impurities such as water and hydrogen is preferably used for the conductor 240a. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 282 can be inhibited from entering the metal oxide 230 through the conductor 240.

The conductor 240 functions as a wiring and thus is preferably formed using a conductor having high conductivity. For example, a conductive material containing tungsten, copper, or aluminum as its main component can be used for the conductor 240b.

For example, it is preferable to use titanium nitride for the conductor 240a and tungsten for the conductor 240b. In that case, the conductor 240a is a conductor that contains titanium and nitrogen, and the conductor 240b is a conductor that contains tungsten.

Although the conductor 240 has a two-layer stacked structure of the conductor 240a and the conductor 240b in FIG. 2A, the present invention is not limited thereto. For example, the conductor 240 may be a single layer or have a stacked-layer structure of three or more layers. In the case where a component has a stacked-layer structure, layers may be distinguished by ordinal numbers given corresponding to the formation order.

Although FIG. 2A illustrates an example in which the level of the conductor 240 is the same or substantially the same as the level of the insulator 285, one embodiment of the present invention is not limited thereto. For example, the level of the top surface of the conductor 240 may be higher than the level of the top surface of the insulator 285.

The semiconductor device described in this embodiment has a line-symmetric structure with the dashed double-dotted line A1-A2 illustrated in FIG. 2A as the symmetric axis. That is, the transistor 200a and the transistor 200b can be regarded as being placed line-symmetrically with the conductor 240 as the symmetric axis. In addition, the capacitor 100a and the capacitor 100b can be regarded as being placed line-symmetrically with the conductor 240 as the symmetric axis. Here, the conductor 242b functions as both the other of the source electrode and the drain electrode of the transistor 200a and the other of the source electrode and the drain electrode of the transistor 200b. In addition, the conductor 240 functioning as the wiring BL is shared by the transistor 200a and the transistor 200b. The two transistors 200, the two capacitors 100, and the conductor 240 are connected in this manner, so that a semiconductor device that can be scaled down or highly integrated can be provided.

Like the conductor 240, the conductor 241 preferably has a stacked-layer structure. For example, the conductor 241 preferably has a stacked-layer structure of a conductor 241a and a conductor 241b as illustrated in FIG. 2A. For example, the conductor 241 can have a structure in which the conductor 241a is provided to include a region in contact with the inner wall of the opening 259 and the conductor 241b is provided on the inner side. That is, the conductor 241a is provided closer to the insulator 283, the insulator 282, the insulator 280, and the insulator 275 than the conductor 241b is.

The conductor 241a can be formed using a material similar to any of the materials that can be used for the conductor 240a, and the conductor 241b can be formed using a material similar to any of the materials that can be used for the conductor 240b. The conductor 241a can be formed by a method similar to that for forming the conductor 240a, and the conductor 241b can be formed by a method similar to that for forming the conductor 240b.

Note that the conductor 241 does not necessarily have a two-layer stacked structure of the conductor 241a and the conductor 241b and, for example, may be a single layer or have a stacked-layer structure of three or more layers.

FIG. 2B is a cross-sectional view illustrating a structure example of the transistor 200 illustrated in FIG. 2A in the channel width direction and a structure example of the capacitor 100 in the direction parallel to the above direction.

In the example illustrated in FIG. 2B, the side surface of the insulator 224 and the top surface and the side surface of the metal oxide 230 are covered with the insulator 253, the insulator 254, and the conductor 260. That is, the conductor 260 including the region functioning as the first gate electrode covers not only the top surface but also the side surface of the metal oxide 230.

In this specification and the like, a transistor structure in which a channel formation region is electrically surrounded by at least the electric field of the first gate electrode is referred to as a surrounded channel (S-channel) structure. The S-channel structure disclosed in this specification and the like has a structure that is different from a Fin-type structure and a planar structure. The S-channel structure disclosed in this specification and the like can be regarded as a kind of the Fin-type structure. Note that in this specification and the like, the Fin-type structure refers to a structure in which a gate electrode is placed to cover at least two or more surfaces (specifically, two surfaces, three surfaces, or four surfaces) of a channel. With the use of the Fin-type structure and the S-channel structure, a transistor with high resistance to a short-channel effect, i.e., a transistor in which a short-channel effect is unlikely to occur, can be obtained.

When the transistor included in the semiconductor device of this embodiment has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having the S-channel structure, the GAA structure, or the LGAA structure, the channel formation region that is formed at the interface between a metal oxide and a gate insulator or in the vicinity of the interface can be the entire bulk of the metal oxide. Accordingly, the density of current flowing through the transistor can be improved, which can be expected to improve the on-state current of the transistor or increase the field-effect mobility of the transistor.

Although FIG. 2B illustrates a transistor with the S-channel structure as the transistor, the semiconductor device of one embodiment of the present invention is not limited thereto. For example, a transistor structure that can be used in one embodiment of the present invention may be one or more selected from the planar structure, the Fin-type structure, and the GAA structure.

As illustrated in FIG. 2B, a curved surface may be provided between the side surface of the metal oxide 230 and the top surface of the metal oxide 230 in the channel width direction of the transistor 200. That is, an end portion of the side surface and an end portion of the top surface may be curved.

The radius of curvature of the curved surface is preferably greater than 0 nm and less than the thickness of the metal oxide 230 in a region overlapping with the conductor 242a or the conductor 242b or less than half of the length of a region not having the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the metal oxide 230 with the insulator 253, the insulator 254, and the conductor 260 in the channel width direction of the transistor 200.

A portion of the conductor 160 above the insulator 180 can be led to be formed into a wiring shape. Thus, in the case where the plurality of transistors 200 and the plurality of capacitors 100 are provided, the conductor 160 can function as a wiring. In that case, the insulator 153 together with the conductor 160 can be provided to extend.

### <Structure Example of Transistor>

Next, a structure example of the transistor will be described in detail.

The metal oxide 230 preferably includes a metal oxide 230a over the insulator 224 and a metal oxide 230b over the metal oxide 230a. Including the metal oxide 230a under the metal oxide 230b makes it possible to inhibit diffusion of impurities into the metal oxide 230b from components formed below the metal oxide 230a.

Although an example in which the metal oxide 230 has a two-layer structure of the metal oxide 230a and the metal oxide 230b is described in this embodiment, the present invention is not limited thereto. For example, the metal oxide 230 may have a single-layer structure of the metal oxide 230b or a stacked-layer structure of three or more layers.

The metal oxide 230b includes a channel formation region of the transistor 200 and a source region and a drain region provided to sandwich the channel formation region. At least part of the channel formation region overlaps with the conductor 260. One of the source region and the drain region overlaps with the conductor 242a, and the other overlaps with the conductor 242b.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1× 10⁻⁹ cm⁻³ In order to reduce the carrier concentration in the metal oxide 230b, the impurity concentration in the metal oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

In order to obtain stable electrical characteristics of the transistor 200, reducing the impurity concentration in the metal oxide 230b is effective. In order to reduce the impurity concentration in the metal oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the metal oxide 230b refers to, for example, an element other than the main components of the metal oxide 230b. For example, an element with a concentration lower than 0.1 atomic % can be regarded as an impurity.

Note that the channel formation region, the source region, and the drain region may each be formed not only in the metal oxide 230b but also in the metal oxide 230a.

In the metal oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter, also referred to as an oxide semiconductor) is preferably used as the metal oxide 230 (the metal oxide 230a and the metal oxide 230b).

The oxide semiconductor preferably has a band gap of 2 eV or more, further preferably 2.5 eV or more. With the use of a metal oxide having a wide band gap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

It is particularly preferable to use an oxide containing indium (In), gallium (Ga), and zinc (Zn) (also referred to as In—Ga—Zn oxide or IGZO) as the metal oxide 230. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

The metal oxide 230 preferably has a stacked-layer structure of a plurality of oxide layers with different chemical compositions. For example, the atomic ratio of the element M to a metal element that is a main component in the metal oxide 230a is preferably greater than the atomic ratio of the element M to a metal element that is a main component in the metal oxide 230b. Moreover, the atomic ratio of the element M to In in the metal oxide 230a is preferably greater than the atomic ratio of the element M to In in the metal oxide 230b. With this structure, impurities and oxygen can be inhibited from diffusing into the metal oxide 230b from the components formed below the metal oxide 230a.

Furthermore, the atomic ratio of In to the element M in the metal oxide 230b is preferably greater than the atomic ratio of In to the element M in the metal oxide 230a. With this structure, the transistor 200 can have a high on-state current and high frequency characteristics.

When the metal oxide 230a and the metal oxide 230b contain a common element as the main component besides oxygen, the density of defect states at an interface between the metal oxide 230a and the metal oxide 230b can be decreased. Thus, the influence of interface scattering on carrier conduction is small, and the transistor 200 can have a high on-state current and high frequency characteristics.

Specifically, for the metal oxide 230a, a material with a composition of In:M:Zn=1:3:4 [atomic ratio] or in the neighborhood thereof or a composition of In:M:Zn=1:1:0.5 [atomic ratio] or in the neighborhood thereof can be used. For the metal oxide 230b, a material with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. In the case where a single layer of the metal oxide 230b is provided as the metal oxide 230, any of the materials that can be used for the metal oxide 230a may be used for the metal oxide 230b. The compositions of the metal oxide 230a and the metal oxide 230b are not limited to the above. For example, the metal oxide 230b may have the composition of the metal oxide 230a described above. Similarly, the metal oxide 230a may have the composition of the metal oxide 230b described above.

When the metal oxide is deposited by a sputtering method, the above atomic ratio is not limited to the atomic ratio of the deposited metal oxide and may be the atomic ratio of a sputtering target used for depositing the metal oxide.

A transistor using an oxide semiconductor is likely to have its electrical characteristics changed by impurities and oxygen vacancies in a region where a channel is formed in the oxide semiconductor, which might reduce the reliability. In some cases, a defect that is an oxygen vacancy into which hydrogen in the vicinity of the oxygen vacancy has entered (hereinafter, sometimes referred to as V_{O}H) is formed, which generates an electron serving as a carrier. Therefore, when the region where a channel is formed in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and V_{O}H are preferably reduced as much as possible in the region where a channel is formed in the oxide semiconductor. In other words, the region where a channel is formed in the oxide semiconductor is preferably an i-type (intrinsic) or substantially i-type region with a reduced carrier concentration.

As a countermeasure against the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 200. Furthermore, a variation in the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. Furthermore, a structure is preferable in which a reduction in the conductivity of the conductor 260, the conductor 242a, the conductor 242b, and the like is inhibited. For example, a structure is preferable in which oxidation of the conductor 260, the conductor 242a, the conductor 242b, and the like is inhibited. Note that hydrogen in the oxide semiconductor can form V_{O}H; thus, the hydrogen concentration needs to be reduced in order to reduce the amount of V_{O}H.

Thus, the semiconductor device of one embodiment of the present invention preferably has a structure in which the hydrogen concentration in the channel formation region of the metal oxide 230 is reduced, oxidation of the conductor 242a, the conductor 242b, and the conductor 260 is inhibited, and a reduction in the hydrogen concentration in the source region and the drain region is inhibited.

The insulator 253 in contact with the channel formation region of the metal oxide 230b preferably has a function of capturing hydrogen or a function of fixing hydrogen. Thus, the hydrogen concentration in the channel formation region of the metal oxide 230b can be reduced. Accordingly, V_{O}H in the channel formation region can be reduced, so that the channel formation region can be an i-type or substantially i-type region.

Examples of an insulator having a function of capturing hydrogen or a function of fixing hydrogen include a metal oxide having an amorphous structure. As the insulator 253, for example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

The insulator 253 functions as part of the first gate insulator. A high dielectric constant (high-k) material is preferably used for the insulator 253. An example of the high-k material is an oxide containing one or both of aluminum and hafnium. With the use of the high-k material for the insulator 253, a gate potential applied during the operation of the transistor can be reduced while the physical thickness of the insulator 253 is being maintained. In addition, the equivalent oxide thickness (EOT) of the insulator 253 can be reduced.

As described above, for the insulator 253, an oxide containing one or both of aluminum and hafnium is preferably used. For the insulator 253, an oxide containing one or both of aluminum and hafnium and having an amorphous structure is further preferably used. Hafnium oxide having an amorphous structure is still further preferably used. In this embodiment, hafnium oxide is used for the insulator 253. In that case, the insulator 253 is an insulator that contains at least oxygen and hafnium. The hafnium oxide has an amorphous structure. In that case, the insulator 253 has an amorphous structure.

Alternatively, as the insulator 253, an insulator having a thermally stable structure, such as silicon oxide or silicon oxynitride, may be used. For example, the insulator 253 may have a stacked-layer structure including aluminum oxide and silicon oxide or silicon oxynitride over the aluminum oxide. For another example, the insulator 253 may have a stacked-layer structure including aluminum oxide, silicon oxide or silicon oxynitride over the aluminum oxide, and hafnium oxide over the silicon oxide or silicon oxynitride.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. For example, a barrier insulator against oxygen refers to an insulator having a barrier property against oxygen, and a barrier insulator against hydrogen refers to an insulator having a barrier property against hydrogen. A barrier property in this specification and the like means a function of inhibiting diffusion of a targeted substance (also referred to as having low permeability). Alternatively, the barrier property means a function of capturing and fixing (also referred to as gettering) a targeted substance.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 preferably has a single-layer structure or a stacked-layer structure of the barrier insulator against oxygen.

The insulator 253 preferably has a barrier property against oxygen. It is preferable that oxygen be less likely to pass through the insulator 253 than at least the insulator 280. The insulator 253 includes a region in contact with the side surface of the conductor 242a and a region in contact with the side surface of the conductor 242b. When the insulator 253 has a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200 can be inhibited.

The insulator 253 is provided to include a region in contact with the top surface of the metal oxide 230b, a region in contact with the side surface of the metal oxide 230b, a region in contact with the side surface of the metal oxide 230a, a region in contact with the side surface of the insulator 224, and a region in contact with the top surface of the insulator 222. When the insulator 253 has a barrier property against oxygen, release of oxygen from the channel formation region of the metal oxide 230b caused by heat treatment or the like can be inhibited. This can reduce formation of oxygen vacancies in the metal oxide 230a and the metal oxide 230b.

Even when an excess amount of oxygen is contained in the insulator 280, in contrast, oxygen can be inhibited from being excessively supplied to the metal oxide 230a and the metal oxide 230b. Thus, it is possible to inhibit excessive oxidation of the source region and the drain region and a decrease in the on-state current or field-effect mobility of the transistor 200.

The oxide containing one or both of aluminum and hafnium has a barrier property against oxygen and thus can be suitably used for the insulator 253.

The insulator 254 functions as part of the first gate insulator. The insulator 254 preferably has a barrier property against oxygen. The insulator 254 is provided between the conductor 260 and the channel formation region of the metal oxide 230 and between the insulator 280 and the conductor 260. Such a structure can inhibit diffusion of oxygen contained in the channel formation region of the metal oxide 230 into the conductor 260 and formation of oxygen vacancies in the channel formation region of the metal oxide 230. Oxygen contained in the metal oxide 230 and oxygen contained in the insulator 280 can be inhibited from diffusing into the conductor 260 and oxidizing the conductor 260. It is preferable that oxygen be less likely to pass through the insulator 254 than at least the insulator 280. For example, silicon nitride is preferably used for the insulator 254. In that case, the insulator 254 is an insulator that contains at least nitrogen and silicon.

The insulator 254 preferably has a barrier property against hydrogen. Accordingly, diffusion of impurities contained in the conductor 260, such as hydrogen, into the metal oxide 230b can be inhibited.

The insulator 275 preferably has a barrier property against oxygen. The insulator 275 is provided between the insulator 280 and the conductor 242a and between the insulator 280 and the conductor 242b. With this structure, oxygen contained in the insulator 280 can be inhibited from diffusing into the conductor 242a and the conductor 242b. Thus, the conductor 242a and the conductor 242b can be inhibited from being oxidized by oxygen contained in the insulator 280, so that an increase in resistivity and a reduction in on-state current can be inhibited. It is preferable that oxygen be less likely to pass through the insulator 275 than at least the insulator 280. For example, silicon nitride is preferably used for the insulator 275. In that case, the insulator 275 is an insulator that contains at least nitrogen and silicon.

In order to inhibit a reduction in hydrogen concentration in the source region and the drain region in the metal oxide 230, a barrier insulator against hydrogen is preferably provided in the vicinity of each of the source region and the drain region. Thus, the source region and the drain region in the metal oxide 230 can be n-type regions. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

With the above structure, the channel formation region can be an i-type or substantially i-type region, and the source region and the drain region can be n-type regions; thus, a semiconductor device with excellent electrical characteristics can be provided. The semiconductor device with the above structure can have excellent electrical characteristics even when scaled down or highly integrated. Scaling down of the transistor 200 can improve the high-frequency characteristics. Specifically, the cutoff frequency can be improved.

The insulator 253 and the insulator 254 are provided together with the conductor 260 in the opening 258. The thickness of the insulator 253 and the thickness of the insulator 254 are preferably small for scaling down of the transistor 200. The thickness of the insulator 253 is preferably greater than or equal to 0.1 nm and less than or equal to 5.0 nm, further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. The thickness of the insulator 254 is preferably greater than or equal to 0.1 nm and less than or equal to 5.0 nm, further preferably greater than or equal to 0.5 nm and less than or equal to 3.0 nm, still further preferably greater than or equal to 1.0 nm and less than or equal to 3.0 nm. Note that at least part of each of the insulator 253 and the insulator 254 includes a region having the above-described thickness.

To form the insulator 253 and the insulator 254 each having a small thickness as described above, an ALD method is preferably used for deposition. Examples of an ALD method include a thermal ALD method, in which a precursor and a reactant react with each other only by a thermal energy, and a plasma ALD (PEALD: Plasma Enhanced ALD) method, in which a reactant excited by plasma is used. The use of plasma in a PEALD method is sometimes preferable because deposition at a lower temperature is possible.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 253 and the insulator 254 can be formed with good coverage and small thicknesses as described above on the inner wall of the opening 258, the side end portion of the conductor 242a, the side end portion of the conductor 242b, and the like.

Note that some of precursors usable in an ALD method contain carbon or the like. Thus, in some cases, a film formed by an ALD method contains impurities such as carbon in a larger amount than a film formed by another deposition method. Note that impurities can be quantified by secondary ion mass spectrometry (SIMS), X-ray photoelectron spectroscopy (XPS), or auger electron spectroscopy (AES).

For example, silicon nitride deposited by a PEALD method can be used for the insulator 254.

Note that when an insulator having a function of inhibiting passage of oxygen and impurities such as hydrogen, e.g., hafnium oxide, is used as the insulator 253, the insulator 253 can also have the function of the insulator 254. In such a case, the structure without the insulator 254 enables simplification of the fabrication process and the improvement in productivity of the semiconductor device.

In addition to the above structure, the semiconductor device of one embodiment of the present invention preferably has a structure in which hydrogen is inhibited from entering the transistor 200 and the like. For example, an insulator having a function of inhibiting diffusion of hydrogen is preferably provided to cover one or both of the upper portion and the lower portion of the transistor 200 and the like. In the semiconductor device described in this embodiment, the insulator is, for example, the insulator 212.

As the insulator 212, an insulator having a function of inhibiting diffusion of hydrogen is preferably used. This can inhibit diffusion of hydrogen into the transistor 200 and the like from below the insulator 212. As the insulator 212, the above-described insulator that can be used as the insulator 275 can be used.

One or more of the insulator 210, the insulator 212, the insulator 214, and the insulator 282 preferably function as a barrier insulator, which inhibits diffusion of impurities such as water and hydrogen into the transistor 200 and the like from the substrate side or from above the transistor 200 and the like. Thus, one or more of the insulator 210, the insulator 212, the insulator 214, and the insulator 282 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom, i.e., an insulating material through which the impurities are less likely to pass. Alternatively, it is preferable to contain an insulating material having a function of inhibiting diffusion of oxygen, specifically at least one of an oxygen atom, an oxygen molecule, and the like, for example, i.e., an insulating material through which the oxygen is less likely to pass.

The insulator 212, the insulator 214, and the insulator 282 each preferably have a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride or the like, which has a high hydrogen barrier property, is preferably used for the insulator 212. For example, aluminum oxide, magnesium oxide, or the like, which has an excellent function of capturing hydrogen or an excellent function of fixing hydrogen, is preferably used for each of the insulator 214 and the insulator 282. Accordingly, impurities such as water and hydrogen can be inhibited from diffusing from the substrate side into the transistor 200 and the like through the insulator 212 and the insulator 214. Furthermore, impurities such as water and hydrogen can be inhibited from diffusing into the transistor 200 and the like from an interlayer insulating film and the like placed outside the insulator 282. Moreover, oxygen contained in the insulator 224 and the like can be inhibited from diffusing to the substrate side. In addition, oxygen contained in the insulator 280 and the like can be inhibited from diffusing to the components over the transistor 200 and the like through the insulator 282 and the like. In this manner, it is preferable that the transistor 200 and the like be surrounded by the insulators having a function of inhibiting diffusion of oxygen and impurities such as water and hydrogen.

In the transistor 200, the conductor 205 is provided to include a region overlapping with the metal oxide 230 and a region overlapping with the conductor 260. Here, the conductor 205 is preferably provided to be embedded in an opening formed in the insulator 216. Part of the conductor 205 is embedded in the insulator 214 in some cases. The top surface of the conductor 205 can be level or substantially level with the top surface of the insulator 216.

The conductor 205 functions as the second gate electrode of the transistor 200. The conductor 205 may have a single-layer structure or a stacked-layer structure. In FIG. 2A or the like, the conductor 205 includes a conductor 205a and a conductor 205b. The conductor 205a is placed to include a region in contact with the inner wall of the opening provided in the insulator 216. The conductor 205b is provided to be embedded in a depressed portion formed in the conductor 205a. Here, the top surface of the conductor 205b is level or substantially level with the uppermost portion of the conductor 205a and the top surface of the insulator 216, for example.

Here, the conductor 205a preferably contains a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to contain a conductive material having a function of inhibiting diffusion of oxygen, specifically at least one of an oxygen atom, an oxygen molecule, and the like, for example.

When a conductive material having a function of inhibiting diffusion of hydrogen is used for the conductor 205a, impurities such as hydrogen contained in the conductor 205b can be inhibited from diffusing into the metal oxide 230 through the insulator 216, the insulator 224, and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride.

A conductive material containing tungsten, copper, or aluminum as its main component is preferably used for the conductor 205b. For example, the conductor 205b preferably contains tungsten.

The insulator 222 and the insulator 224 each function as part of the second gate insulator.

It is preferable that the insulator 222 have a function of inhibiting diffusion of hydrogen, specifically at least one of a hydrogen atom, a hydrogen molecule, and the like, for example. In addition, it is preferable that the insulator 222 have a function of inhibiting diffusion of oxygen, specifically at least one of an oxygen atom, an oxygen molecule, and the like, for example. The insulator 222 preferably has a function of inhibiting diffusion of one or both of hydrogen and oxygen more than the insulator 224, for example.

The insulator 222 preferably includes an insulator containing an oxide of one or both of aluminum and hafnium, which is an insulating material. For the insulator, aluminum oxide, hafnium oxide, hafnium aluminate, or the like is preferably used. Alternatively, an oxide containing hafnium and zirconium, e.g., a hafnium zirconium oxide, is preferably used. In the case where such a material is used for the insulator 222, the insulator 222 functions as a layer that inhibits release of oxygen from the metal oxide 230 to the substrate side and diffusion of impurities such as hydrogen from the periphery of the transistor 200 into the metal oxide 230. Thus, providing the insulator 222 can inhibit diffusion of impurities such as hydrogen to the inside of the transistor 200 and inhibit generation of oxygen vacancies in the metal oxide 230. Moreover, the conductor 205 and the conductor 260 can be inhibited from reacting with oxygen contained in the insulator 224 and oxygen contained in the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, these insulators may be subjected to nitriding treatment. A stack of silicon oxide, silicon oxynitride, or silicon nitride over the above insulators may be used for the insulator 222.

For example, the insulator 222 may have a single-layer structure or a stacked-layer structure of an insulator(s) containing what is called a high-k material such as aluminum oxide, hafnium oxide, tantalum oxide, zirconium oxide, or hafnium zirconium oxide. Furthermore, a material with a high dielectric constant such as lead zirconate titanate (PZT), strontium titanate (SrTiO₃), or (Ba,Sr) TiO₃ (BST) can be used for the insulator 222 in some cases.

The insulator 224 that is in contact with the metal oxide 230 preferably contains silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is not easily oxidized or a conductive material having a function of inhibiting diffusion of oxygen is preferably used for each of the conductor 242a, the conductor 242b, and the conductor 260. Examples of the conductive material include a conductive material containing nitrogen and a conductive material containing oxygen. This can inhibit a reduction in the conductivity of the conductor 242a, the conductor 242b, and the conductor 260.

The conductor 242a and the conductor 242b may each have a single-layer structure or a stacked-layer structure. The conductor 260 may have a single-layer structure or a stacked-layer structure.

FIG. 2A illustrates the conductor 242a and the conductor 242b each having a two-layer structure. In that case, a conductive material that is not easily oxidized or a conductive material having a function of inhibiting diffusion of oxygen is preferably used for a layer (a conductor 242al and a conductor 242b1) in contact with the metal oxide 230b. This can inhibit a reduction in the conductivity of the conductor 242a and the conductor 242b. For the layer (the conductor 242al and the conductor 242b1) in contact with the metal oxide 230b, a material that is likely to absorb (extract) hydrogen is preferably used, in which case the hydrogen concentration in the metal oxide 230 can be reduced.

A conductor 242a2 and a conductor 242b2 preferably have higher conductivity than the conductor 242al and the conductor 242b1. For example, the thicknesses of the conductor 242a2 and the conductor 242b2 are preferably larger than the thicknesses of the conductor 242al and the conductor 242b1.

For example, tantalum nitride or titanium nitride can be used for the conductor 242al and the conductor 242b1, and tungsten can be used for the conductor 242a2 and the conductor 242b2.

For the conductor 242a and the conductor 242b, for example, a nitride containing tantalum, a nitride containing titanium, a nitride containing molybdenum, a nitride containing tungsten, a nitride containing tantalum and aluminum, or a nitride containing titanium and aluminum is preferably used. It is particularly preferable to use a nitride containing tantalum for the conductor 242a and the conductor 242b. For another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the metal oxide 230b or the like diffuses into the conductor 242a or the conductor 242b in some cases. In particular, when a nitride containing tantalum is used for the conductor 242a and the conductor 242b, hydrogen contained in the metal oxide 230b or the like is likely to diffuse into the conductor 242a or the conductor 242b, and the diffused hydrogen is bonded to nitrogen contained in the conductor 242a or the conductor 242b in some cases. That is, hydrogen contained in the metal oxide 230b or the like is absorbed by the conductor 242a or the conductor 242b in some cases.

The conductor 260 functions as the first gate electrode of the transistor 200. The conductor 260 preferably includes a conductor 260a and a conductor 260b placed over the conductor 260a. For example, the conductor 260a is preferably placed to cover the bottom surface and the side surface of the conductor 260b.

A conductive material that is not easily oxidized or a conductive material having a function of inhibiting diffusion of oxygen is preferably used for the conductor 260a. Moreover, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used for the conductor 260a. Alternatively, it is preferable to use a conductive material having a function of inhibiting diffusion of oxygen, specifically at least one of an oxygen atom, an oxygen molecule, and the like, for example.

When the conductor 260a has a function of inhibiting diffusion of oxygen, the conductivity of the conductor 260b can be inhibited from being lowered because of oxidation due to oxygen contained in the insulator 280 or the like. As the conductive material having a function of inhibiting diffusion of oxygen, for example, titanium, titanium nitride, tantalum, tantalum nitride, ruthenium, or ruthenium oxide is preferably used.

As the conductor 260b, a conductor having high conductivity is preferably used. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening 258. The formation of the conductor 260 in this manner allows the conductor 260 to be placed properly in a region between the conductor 242a and the conductor 242b without alignment.

The insulator 216, the insulator 280, the insulator 283, the insulator 180, and the insulator 285 each preferably have a lower dielectric constant than the insulator 214. When a material with a low dielectric constant is used for an interlayer film, parasitic capacitance generated between wirings can be reduced.

For example, the insulator 216, the insulator 280, the insulator 283, the insulator 180, and the insulator 285 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region containing oxygen released by heating can be easily formed.

The top surfaces of the insulator 216, the insulator 280, the insulator 283, the insulator 180, and the insulator 285 may be planarized.

The concentration of impurities such as water and hydrogen in the insulator 280 is preferably reduced. For example, the insulator 280 preferably contains an oxide containing silicon, such as silicon oxide or silicon oxynitride.

The above is the description of the transistor 200.

### <Structure Example of Capacitor>

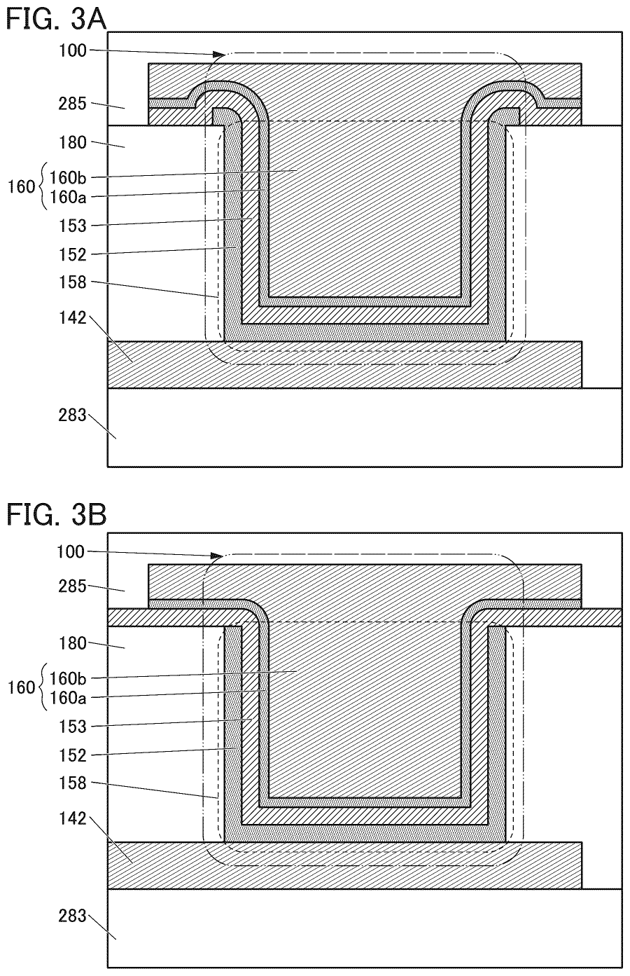

FIG. 3A is an enlarged view of the capacitor 100 illustrated in FIG. 2A and the vicinity thereof. As described above, the capacitor 100 includes the conductor 152 over the conductor 142, the insulator 153 over the conductor 152, and the conductor 160 over the insulator 153. At least part of each of the conductor 152, the insulator 153, and the conductor 160 is placed in the opening 158 that is provided in the insulator 180 and reaches the conductor 142.

The conductor 152 is placed along the opening 158. Here, the level of part of the top surface of the conductor 152 is preferably higher than the level of the top surface of the insulator 180. The conductor 152 is preferably formed by a deposition method that offers excellent coverage, such as an ALD method. The conductor 152 can be formed using any of the materials that can be used for the conductor 205, the conductor 260, and the conductor 242; for example, any of the materials that can be used for the conductor 205a, the conductor 260a, the conductor 242al, and the conductor 242b1 can be used. For example, titanium nitride or tantalum nitride deposited by an ALD method can be used for the conductor 152.

The insulator 153 is placed to cover the conductor 152 and part of the insulator 180. A high-k material is preferably used for the insulator 153. The insulator 153 is preferably formed by a deposition method that offers excellent coverage, such as an ALD method.

Note that as the insulator of the high-k material, an oxide, an oxynitride, a nitride oxide, or a nitride containing one or more kinds of metal elements selected from aluminum, hafnium, zirconium, gallium, and the like can be used. The above-described oxide, oxynitride, nitride oxide, or nitride may contain silicon. Stacked insulators formed of any of the above-described materials can also be used.

For example, as the insulator of the high-k material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used. Using such a high-k material allows the insulator 153 to be thick enough to inhibit leakage current and the capacitor 100 to have a sufficiently high capacitance.

It is preferable to use stacked insulators formed of any of the above-described materials; specifically, it is preferable to use a stacked-layer structure of a high-k material and a material having a higher dielectric strength than the high-k material. As the insulator 153, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used as the insulator 153. For another example, an insulator in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength of the insulator 153 and inhibit electrostatic breakdown of the capacitor 100.

The conductor 160 is placed to fill the opening 158. The conductor 160 is preferably formed by an ALD method, a chemical vapor deposition (CVD) method, or the like. As the conductor 160, any of the conductors that can be used as the conductor 205 and the conductor 260 can be used.

Here, the conductor 160 can have a structure including a conductor 160a and a conductor 160b over the conductor 160a, i.e., a two-layer stacked structure. For example, titanium nitride deposited by an ALD method can be used for the conductor 160a, and tungsten deposited by a CVD method can be used for the conductor 160b. Note that in the case where the adhesion of tungsten to the insulator 153 is sufficiently high, for example, a single-layer film of tungsten formed by a CVD method may be used as the conductor 160.

As illustrated in FIG. 3A, the conductor 152 can be provided to include a region in contact with the inner wall of the opening 158. Thus, the conductor 152 can include a region in contact with the top surface of the conductor 142 and a region in contact with the side surface of the insulator 180. The insulator 153 can be provided to include a region in contact with the top surface of the conductor 152 and a region in contact with the side surface of the conductor 152, the conductor 160a can be provided to include a region in contact with the top surface of the insulator 153 and a region in contact with the side surface of the insulator 153, and the conductor 160b can be provided to include a region in contact with the top surface of the conductor 160a and a region in contact with the side surface of the conductor 160a.

In this manner, the capacitor 100 can have a structure in which the conductor 152 and the conductor 160 are placed to face each other with the insulator 153 therebetween on the bottom surface and the side surface of the opening 158. Thus, when the depth of the opening 158 (which can also be referred to as the thickness of the insulator 180) is made larger, the capacitance of the capacitor 100 can be increased. Increasing the capacitance per unit area of the capacitor 100 in this manner can reduce the frequency of refresh operations for the memory cell and reduce the power consumption of the semiconductor device. Increasing the capacitance of the capacitor 100 enables the semiconductor device of one embodiment of the present invention to perform a reading operation stably. Thus, the semiconductor device of one embodiment of the present invention can be a highly reliable semiconductor device.

As illustrated in FIG. 3A, part of the conductor 152, part of the insulator 153, and part of the conductor 160 can be provided to be exposed from the opening 158. In other words, part of the conductor 152, part of the insulator 153, and part of the conductor 160 can be provided over the top surface of the insulator 180.

Part of the conductor 152 and part of the insulator 153 can be in contact with the top surface of the insulator 180. That is, the side end portion of the conductor 152 can be covered with the insulator 153. Furthermore, the conductor 160 preferably includes a region overlapping with the insulator 180 with the insulator 153 therebetween. Here, as illustrated in FIG. 3A, the side end portion of the conductor 160 and the side end portion of the insulator 153 are substantially aligned with each other. With such a structure, the conductor 160 and the conductor 152 can be separated from each other by the insulator 153, so that a short circuit between the conductor 160 and the conductor 152 can be inhibited.

FIG. 3B illustrates a modification example of the structure illustrated in FIG. 3A, in which the uppermost portion of the conductor 152 is level or substantially level with the top surface of the insulator 180 and part of the insulator 153 is exposed from the conductor 160 to be in contact with the insulator 285. Note that a structure may be employed in which part of the conductor 152 is provided over the top surface of the insulator 180 and part of the insulator 153 is exposed from the conductor 160. Alternatively, a structure may be employed in which the side end portion of the insulator 153 is aligned or substantially aligned with the side end portion of the conductor 160 and the uppermost portion of the conductor 152 is level or substantially level with the top surface of the insulator 180.

The above is the description of the capacitor 100.

### <Structure Example 2 of Semiconductor Device>

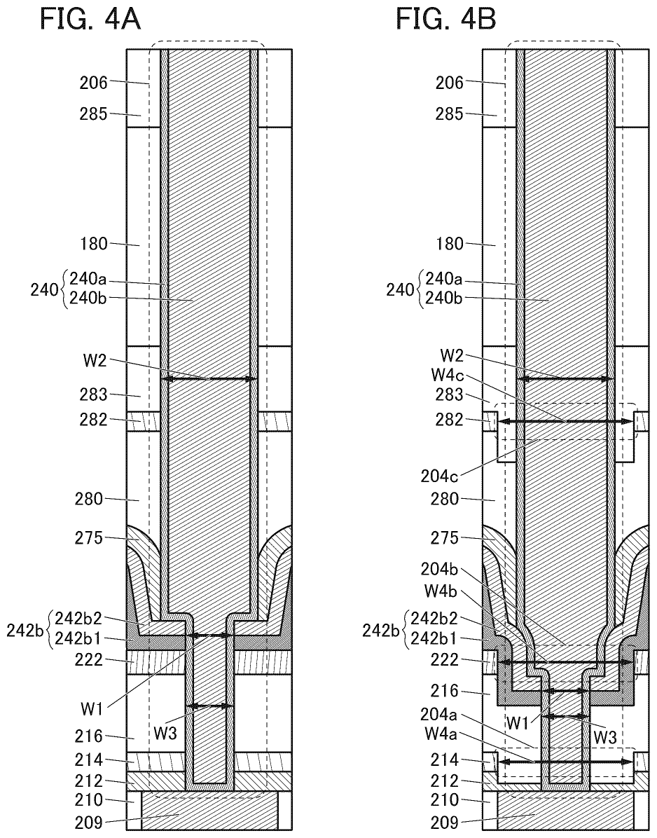

FIG. 4A is an enlarged view of the conductor 240 illustrated in FIG. 2A and the vicinity thereof. As illustrated in a cross-sectional view of FIG. 4A, the conductor 240 includes a region having a width W1 and a region having a width W2. The width W1 is a distance between the side end portion of the conductor 242b included in the transistor 200a and the side end portion of the conductor 242b included in the transistor 200b in the cross-sectional view. That is, the width W1 is a width of the conductor 240 in a region in contact with the conductor 242b in the cross-sectional view. The width W2 is a distance between the interface between the conductor 240 and the insulator 275, the insulator 280, the insulator 282, the insulator 283, the insulator 180, or the insulator 285 on the transistor 200a side and the interface therebetween on the transistor 200b side in the cross-sectional view. That is, the width W2 is a width of the conductor 240 in a region in contact with the insulator 275, the insulator 280, the insulator 282, the insulator 283, the insulator 180, or the insulator 285 in the cross-sectional view. In the cross-sectional view, a distance between the interface between the insulator 216 and the conductor 240 on the transistor 200a side and the interface therebetween on the transistor 200b side is referred to as a width W3. That is, the width W3 is a width of the conductor 240 in a region in contact with the insulator 216 in the cross-sectional view.

As illustrated in FIG. 4A, the width W1 is preferably smaller than the width W2. In that case, the conductor 240 can include not only a region in contact with the side surface of the conductor 242b but also a region in contact with the top surface of the conductor 242b. Thus, the area of a region where the conductor 240 and the conductor 242b are in contact with each other can be increased. This can reduce the contact resistance between the conductor 240 and the conductor 242b. Accordingly, the semiconductor device of one embodiment of the present invention can be a semiconductor device with high operation speed and low power consumption. Here, as illustrated in FIG. 4A, the side surface of the conductor 242b can protrude to the center of the opening 206 from the side surface of the insulator 275, the side surface of the insulator 280, the side surface of the insulator 282, the side surface of the insulator 283, the side surface of the insulator 180, and the side surface of the insulator 285, for example.

FIG. 4B illustrates a modification example of the structure illustrated in FIG. 4A, in which an opening 204a is provided in the insulator 214, an opening 204b is provided in the insulator 222, and an opening 204c is provided in the insulator 282. In the example illustrated in FIG. 4B, the insulator 216 is provided to cover the side surface of the insulator 214, the conductor 242b is provided to cover the side surface of the insulator 222, and the insulator 283 is provided to cover the side surface of the insulator 282. Thus, the insulator 216 includes a region that protrudes from the side surface of the insulator 214. The conductor 242b includes a region that protrudes from the side surface of the insulator 222. The insulator 283 includes a region that protrudes from the side surface of the insulator 282. Here, in the example illustrated in FIG. 4B, a structure can be employed in which the insulator 214, the insulator 222, and the insulator 282 are not in contact with the conductor 240.

In a cross-sectional view of FIG. 4B, the width W2 can be the distance between the interface between the conductor 240 and the insulator 275, the insulator 280, the insulator 283, the insulator 180, or the insulator 285 on the transistor 200a side and the interface therebetween on the transistor 200b side. In the cross-sectional view of FIG. 4B, the width of the opening 204a is referred to as a width W4a, the width of the opening 204b is referred to as a width W4b, and the width of the opening 204c is referred to as a width W4c. The width W4a, the width W4b, and the width W4c are each larger than the width W2.

Providing the opening 204a, the opening 204b, and the opening 204c eliminates the need for processing the insulator 282, the insulator 222, and the insulator 214 at the time of forming the opening 206. Accordingly, even when the insulator 282, the insulator 222, and the insulator 214 are formed using a difficult-to-process material, e.g., a hard-to-etch material such as aluminum oxide or hafnium oxide, the side surface of the opening 206 can be easily made perpendicular or substantially perpendicular to the substrate surface or the top surface of the conductor 209, for example. Hence, the area occupied by the opening 206 can be reduced, and the area occupied by one memory cell can be reduced. Thus, the semiconductor device can be scaled down or highly integrated.

Here, as illustrated in FIG. 4B, the top surface of the insulator 212 sometimes has a depressed portion overlapping with the opening 204a in the insulator 214. In addition, the top surface of the insulator 216 sometimes has a depressed portion overlapping with the opening 204b in the insulator 222. Furthermore, the top surface of the insulator 280 sometimes has a depressed portion overlapping with the opening 204c in the insulator 282. Note that in the case where the thickness of the insulator 212 is small, the opening 204a is sometimes formed not only in the insulator 214 but also in the insulator 212. In that case, part of the insulator 216 is in contact with part of the conductor 209.

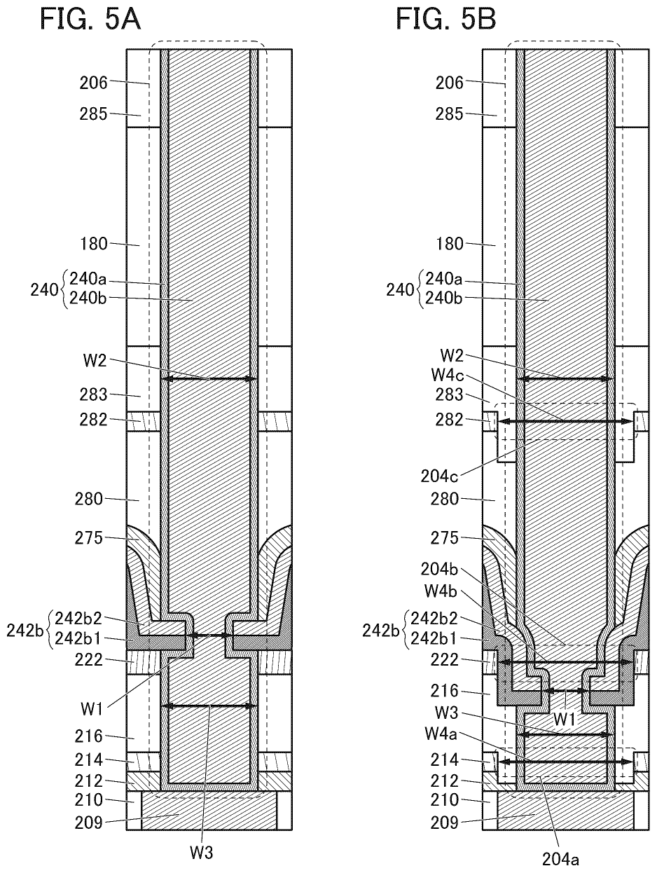

Although FIG. 4A and FIG. 4B illustrate an example in which the width W3 is equal to the width W1, one embodiment of the present invention is not limited thereto. FIG. 5A and FIG. 5B respectively illustrate modification examples of FIG. 4A and FIG. 4B, in which the width W3 is larger than the width W1; specifically, the width W3 is equal to the width W2. Note that the width W3 may be larger than the width W1 and smaller than the width W2.

In the structures illustrated in FIG. 5A and FIG. 5B, the conductor 240 can include a region in contact with the bottom surface of the conductor 242b as well as a region in contact with the side surface of the conductor 242b and a region in contact with the top surface of the conductor 242b. Thus, the area of the region where the conductor 240 and the conductor 242b are in contact with each other can be further increased.

In the structures illustrated in FIG. 5A and FIG. 5B, the opening 206 can be formed in the following manner, for example: the top surface of the conductor 209 is exposed by anisotropic etching and then isotropic etching is performed.

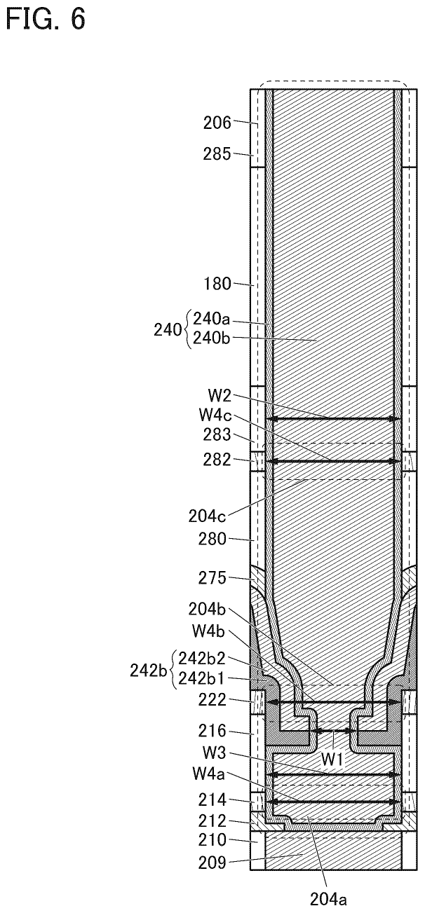

FIG. 6 illustrates a modification example of the structure illustrated in FIG. 5B, in which the width W2, the width W3, the width W4a, the width W4b, and the width W4c are equal to one another. In the example illustrated in FIG. 6, at least part of each of the side surface of the insulator 214 and the side surface of the insulator 282 can be in contact with the conductor 240. For example, the diameter of the opening formed by anisotropic etching is made larger or isotropic etching time is made longer than that in the case of forming the conductor 240 illustrated in FIG. 5B, whereby the conductor 240 illustrated in FIG. 6 is formed.

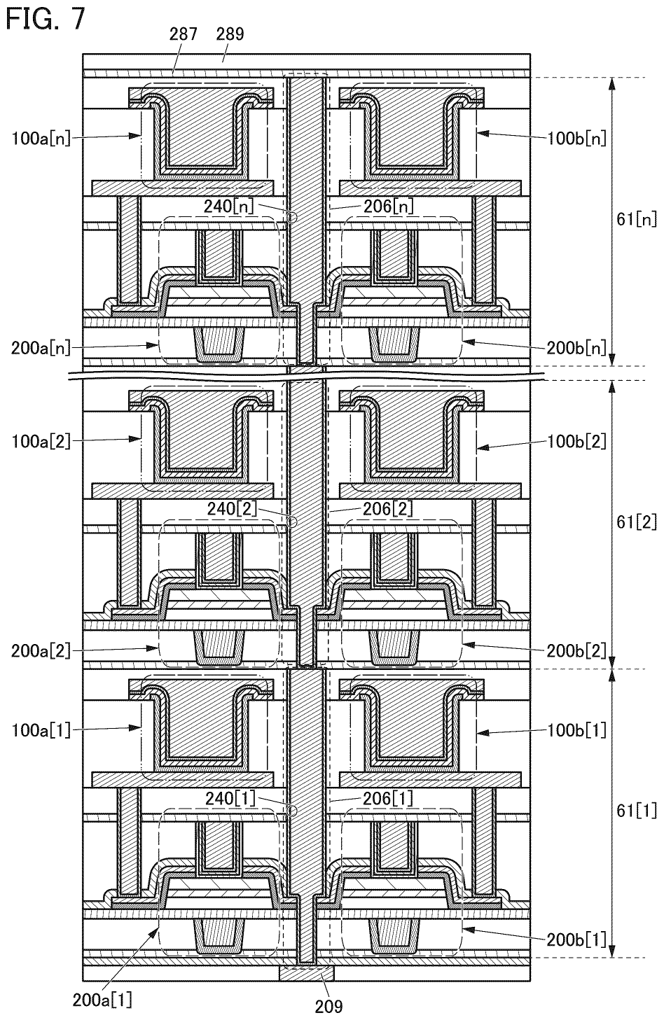

FIG. 7 is a cross-sectional view illustrating a structure example in which n (n is an integer greater than or equal to 1) memory layers 61 each of which is illustrated in FIG. 2A are stacked. The n memory layers 61 are each provided with the transistor 200a, the transistor 200b, the capacitor 100a, and the capacitor 100b.

In this specification and the like, when a plurality of components are denoted with the same reference numerals, and in particular, need to be distinguished from each other, an identification sign such as “[1]”, “[n]”, “[1,1]”, “[p,q]”, or “_1” is sometimes added to the reference numerals.

As illustrated in FIG. 7, the opening 206 is provided in each of the n memory layers 61, and the conductor 240 is provided in the opening 206. For example, an opening 206[1] is provided in the memory layer 61[1], and a conductor 240[1] is provided in the opening 206[1]. An opening 206[2] is provided in the memory layer 61[2], and a conductor 240[2] is provided in the opening 206[2]. An opening 206[n] is provided in the memory layer 61[n], and a conductor 240[n] is provided in the opening 206[n]. The conductor 240[1] to the conductor 240[n] are electrically connected to each other to be electrically connected to the conductor 209.

An insulator 287 is provided over the memory layer 61[n], and an insulator 289 is provided over the insulator 287. For the insulator 287, a material similar to any of the materials that can be used for the insulator 212, the insulator 214, the insulator 222, and the insulator 282 can be used. Thus, the insulator 287 can function as a barrier insulator. For the insulator 289, a material similar to any of the materials that can be used for the insulator 216, the insulator 280, the insulator 283, the insulator 180, and the insulator 285 can be used. The top surface of the insulator 289 may be planarized.

When the plurality of memory layers 61 are provided in stacked layers in the semiconductor device as illustrated in FIG. 7, the number of memory cells provided in the semiconductor device can be increased without an increase in the area occupied by the memory layers 61 in a plan view, as compared with the case where only one memory layer 61 is provided in the semiconductor device. Thus, the occupation area per bit of the semiconductor device can be reduced. Accordingly, the semiconductor device of one embodiment of the present invention can be a semiconductor device that can be highly integrated.

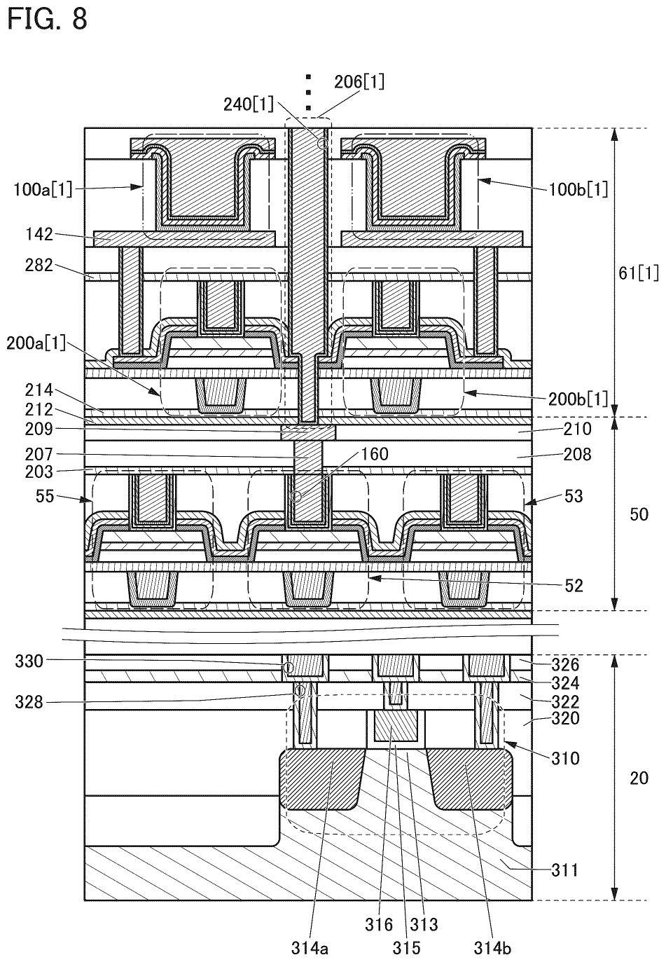

FIG. 8 is a cross-sectional view illustrating an example in which a driver circuit 20 and a functional layer 50 are provided under the memory layer 61[1]. FIG. 8 illustrates an example in which the functional layer 50 is provided over the driver circuit 20.

The driver circuit 20 includes a sense amplifier, for example. When data retained in the memory cell provided in the memory layer 61 is read, for example, the functional layer 50 has a function of amplifying a data potential representing the data. The data potential amplified is supplied to the sense amplifier included in the driver circuit 20.

A transistor 310 can be provided in the driver circuit 20. The transistor 310 is provided over a substrate 311 and includes a conductor 316 functioning as a gate electrode, an insulator 315 functioning as a gate insulator, a semiconductor region 313 that is part of the substrate 311, a low-resistance region 314a functioning as one of a source region and a drain region, and a low-resistance region 314b functioning as the other of the source region and the drain region. The transistor 310 may be either a p-channel transistor or an n-channel transistor.

Here, in the transistor 310 illustrated in FIG. 8, the semiconductor region 313 (part of the substrate 311) in which a channel is formed has a protruding shape. The conductor 316 is provided to cover the top surface of the semiconductor region 313 with the insulator 315 therebetween. Note that a material adjusting the work function may be used for the conductor 316. Such a transistor 310 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 310 illustrated in FIG. 8 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are sequentially provided in stacked layers over the transistor 310 as an interlayer film. Moreover, a conductor 328, a conductor 330, and the like are embedded in the insulator 320, the insulator 322, the insulator 324, and the insulator 326. Note that the conductor 328 and the conductor 330 function as a plug or a wiring.

The insulators functioning as the interlayer film may also function as a planarization film that covers an uneven shape thereunder. For example, the top surface of the insulator 322 may be planarized through planarization treatment using a CMP method or the like to increase the level of planarity.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material with a low relative permittivity is used for the insulators functioning as the interlayer film, parasitic capacitance generated between wirings can be reduced. Thus, a material is preferably selected depending on the function of the insulators.

As the insulator 320, the insulator 322, the insulator 326, and the like, for example, an insulator having a low relative permittivity is preferably used. For example, as the insulator, silicon oxide to which fluorine is added, silicon oxide to which carbon is added, silicon oxide to which carbon and nitrogen are added, porous silicon oxide, a resin, or the like is preferably used. Alternatively, as the insulator, a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide is preferably used. When silicon oxide and silicon oxynitride, which are thermally stable, are combined with a resin, the stacked-layer structure can have thermal stability and a low relative permittivity. Examples of the resin include polyester, polyolefin, polyamide (nylon, aramid, and the like), polyimide, polycarbonate, and acrylic.

When a transistor using an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen can be used as the insulator 324, the insulator 212, the insulator 214, and the like.

As the insulator having a function of inhibiting passage of oxygen and impurities such as hydrogen, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

For the conductors that can be used as a wiring and a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. A semiconductor having high electrical conductivity, typified by polycrystalline silicon containing an impurity element such as phosphorus, or silicide such as nickel silicide may be used.

For example, for the conductor 328, the conductor 330, the conductor 209, the conductor 142, and the like, a single layer or stacked layers including a conductive material such as a metal material, an alloy material, a metal nitride material, or a metal oxide material that is formed using any of the above materials can be used. It is preferable to use a high-melting-point material that has both heat resistance and conductivity, such as tungsten or molybdenum, and it is further preferable to use tungsten. Alternatively, it is preferable to use a low-resistance conductive material such as aluminum or copper. The use of a low-resistance conductive material can reduce wiring resistance.

FIG. 8 illustrates a transistor 52, a transistor 53, and a transistor 55 provided in the functional layer 50. Here, the transistor 52, the transistor 53, and the transistor 55 have structures similar to those of the transistor 200a and the transistor 200b. Source electrodes and drain electrodes of the transistor 52, the transistor 53, and the transistor 55 are connected in series.

An insulator 203 is provided over the transistor 52, the transistor 53, and the transistor 55, an insulator 208 is provided over the insulator 203, the insulator 210 is provided over the insulator 208, and the insulator 212 is provided over the insulator 210. A conductor 207 is provided in an opening formed in the insulator 208 and the insulator 203. For the insulator 203, a material similar to any of the materials that can be used for the insulator 282 can be used, for example. For the insulator 208, a material similar to any of the materials that can be used for the insulator 283 can be used. For the conductor 207, a material similar to any of the materials that can be used for the conductor 209 can be used.

FIG. 8 illustrates an example in which the conductor 207 is provided such that its bottom surface includes a region in contact with the top surface of the conductor 160 of the transistor 52. In the illustrated example, the conductor 207 is provided such that its top surface includes a region in contact with the bottom surface of the conductor 209. With such a structure, the conductor 240 corresponding to the wiring BL functioning as a bit line can be electrically connected to a gate electrode of the transistor 52.

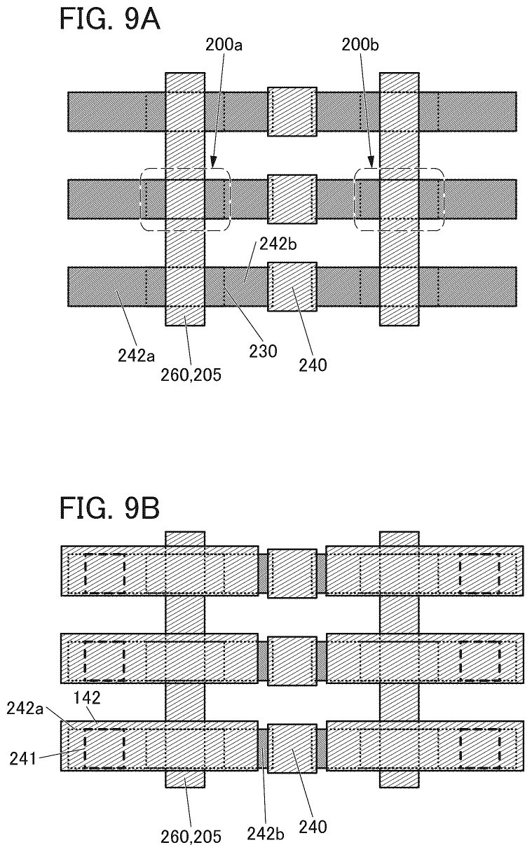

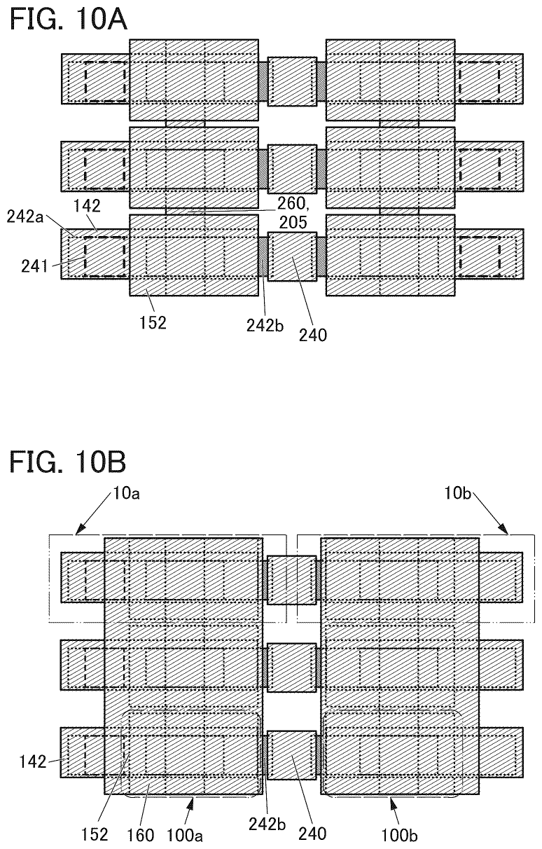

FIG. 9A, FIG. 9B, FIG. 10A, and FIG. 10B are plan views illustrating structure examples of the semiconductor device of one embodiment of the present invention. FIG. 9A illustrates the transistor 200a, the transistor 200b, and the conductor 240. Specifically, the conductor 205, the metal oxide 230, the conductor 242a, the conductor 242b, and the conductor 260 are illustrated as each of the transistor 200a and the transistor 200b.

FIG. 9B illustrates the conductor 241 and the conductor 142 in addition to the components illustrated in FIG. 9A. Here, the conductor 241 is denoted by a dashed line. The conductor 242a is electrically connected to the conductor 142 through the conductor 241.

FIG. 10A illustrates the conductor 152 in addition to the components illustrated in FIG. 9B. The conductor 152 can be provided to include a region overlapping with the conductor 260 and the conductor 205. Although FIG. 10A illustrates an example in which the conductor 152 does not overlap with the conductor 241, the conductor 152 may include a region overlapping with the conductor 241.

FIG. 10B illustrates the conductor 160 in addition to the components illustrated in FIG. 10A. FIG. 10B illustrates the conductor 152 functioning as one electrode of the capacitor 100 and the conductor 160 functioning as the other electrode of the capacitor 100; thus, the capacitor 100 can be regarded as being illustrated. Specifically, FIG. 10B illustrates structure examples of the capacitor 100a and the capacitor 100b.

The conductor 160 can cover the conductor 152. For example, the conductor 160 can cover the entire conductor 152. Although FIG. 10B illustrates an example in which the conductor 160 included in the memory cell 10a and the conductor 160 included in the memory cell 10b are separated from each other, the conductor 160 included in the memory cell 10a and the conductor 160 included in the memory cell 10b may be electrically connected to each other.

### <Metal Oxide>

A material that can be used for the metal oxide 230, specifically an In—Ga—Zn oxide, will be described below.

Amorphous (including completely amorphous), CAAC (c-axis-aligned crystalline), nc (nanocrystalline), CAC (cloud-aligned composite), single crystal, and polycrystalline (polycrystal) structures can be given as examples of crystal structures of an oxide semiconductor.

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the transistor including a metal oxide in its channel formation region (sometimes referred to as an OS transistor) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

### [A-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas can be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, leakage current can be inhibited.

Thus, in the case where the CAC-OS is used for a transistor, the complementary action of the conductivity due to the first region and the insulating property due to the second region enables the CAC-OS to have a switching function (on/off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), high field-effect mobility (μ), and excellent switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

The metal oxide 230 is not necessarily used for a semiconductor layer of a transistor. For example, a semiconductor material that has a band gap (a semiconductor material that is not a zero-gap semiconductor) may be used for the semiconductor layer of the transistor. A single element semiconductor such as silicon or a compound semiconductor such as gallium arsenide may also be used for the semiconductor layer of the transistor. A semiconductor such as crystalline silicon, polycrystalline silicon, or amorphous silicon may also be used for the semiconductor layer of the transistor. Furthermore, low-temperature polysilicon (LTPS) may be used for the semiconductor layer of the transistor.

For the semiconductor layer of the transistor, transition metal chalcogenide functioning as a semiconductor is preferably used, for example. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer of the transistor can increase the on-state current of the transistor.

### <Example of Method for Fabricating Semiconductor Device>

Next, a method for fabricating the semiconductor device illustrated in FIG. 7 will be described.

Hereinafter, an insulating material for forming an insulator, a conductive material for forming a conductor, or a semiconductor material for forming a semiconductor can be deposited by a sputtering method, a CVD method, a molecular beam epitaxy (MBE) method, a pulsed laser deposition (PLD) method, an ALD method, and the like as appropriate.

Examples of the sputtering method include a radio frequency (RF) sputtering method in which a high-frequency power source is used as a sputtering power source, a DC sputtering method in which a DC power source is used, and a pulsed DC sputtering method in which voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that the CVD method can be classified into a plasma CVD (PECVD: Plasma-Enhanced CVD) method using plasma, a thermal CVD (TCVD) method using heat, a photo CVD method using light, and the like. Moreover, the CVD method can be classified into a metal CVD (MCVD) method, a metal organic CVD (MOCVD) method, and the like depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, a transistor, a capacitor, or the like included in a semiconductor device may be charged up by receiving electric charge from plasma. In that case, accumulated electric charge may break the wiring, the electrode, the circuit element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

Examples of the ALD method include a thermal ALD method, in which a precursor and a reactant react with each other only by a thermal energy, and a PEALD method, in which a reactant excited by plasma is used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, the ALD method enables excellent step coverage and excellent thickness uniformity and thus can be suitably used for covering a surface of an opening with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be formed depending on the flow rate ratio of the source gases. For example, by the CVD method, a film whose composition is continuously changed can be formed by changing the flow rate ratio of the source gases during film formation. In the case where the film is formed while the flow rate ratio of the source gases is changed, as compared with the case where the film is formed using a plurality of deposition chambers, the time taken for the film formation can be shortened because the time taken for transfer and pressure adjustment is not required. Thus, the productivity of the semiconductor device can be increased in some cases.

By the ALD method, a film with a certain composition can be formed by concurrently introducing different kinds of precursors. In the case where different kinds of precursors are introduced, a film with a certain composition can be formed by controlling the number of cycles for each of the precursors.

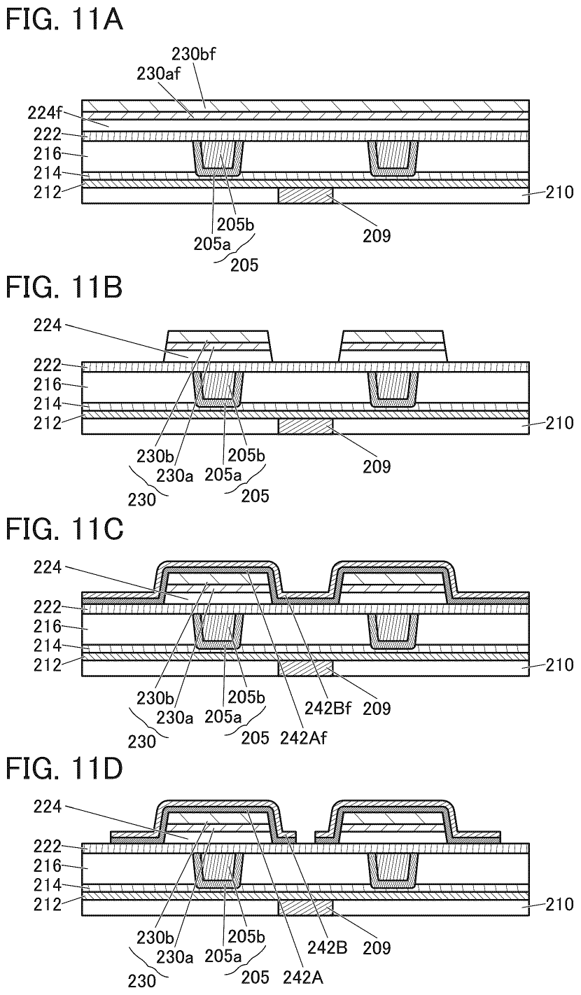

In order to fabricate the semiconductor device illustrated in FIG. 7, a substrate (not illustrated) is prepared first, and then the insulator 210 and the conductor 209 are formed over the substrate as illustrated in FIG. 11A.

Next, the insulator 212 is formed over the insulator 210 and the conductor 209 as illustrated in FIG. 11A. The insulator 212 is preferably formed by a sputtering method. By using a sputtering method that does not need to use a molecule containing hydrogen as a deposition gas, the hydrogen concentration in the insulator 212 can be reduced. Without limitation to a sputtering method, the insulator 212 may be formed by a CVD method, an MBE method, a PLD method, an ALD method, and the like as appropriate.

In this embodiment, for the insulator 212, silicon nitride is deposited by a pulsed DC sputtering method using a silicon target in an atmosphere containing a nitrogen gas. The use of the pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

Then, the insulator 214 is formed over the insulator 212 as illustrated in FIG. 11A. The insulator 214 is preferably formed by a sputtering method. By using a sputtering method that does not need to use a molecule containing hydrogen as a deposition gas, the hydrogen concentration in the insulator 214 can be reduced. Without limitation to a sputtering method, the insulator 214 may be formed by a CVD method, an MBE method, a PLD method, an ALD method, and the like as appropriate.

In this embodiment, for the insulator 214, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. Here, RF power may be applied to the substrate. The RF power is higher than or equal to 0 W/cm² and lower than or equal to 1.86 W/cm². The RF frequency is preferably 10 MHz or higher and is typically 13.56 MHz. The higher the RF frequency is, the less damage the substrate receives.

After the insulator 214 is formed, the opening 204a illustrated in FIG. 4B may be formed, for example. The opening 204a can be formed by a lithography method and an etching method, for example. The opening 204a is formed to include a region overlapping with a region where the opening 206 is formed in a later step. For example, the opening 204a is formed to include a region overlapping with the conductor 209.

Then, the insulator 216 is formed over the insulator 214 as illustrated in FIG. 11A. The insulator 216 is preferably formed by a sputtering method. By using a sputtering method that does not need to use a molecule containing hydrogen as a deposition gas, the hydrogen concentration in the insulator 216 can be reduced. Without limitation to a sputtering method, the insulator 216 may be formed by a CVD method, an MBE method, a PLD method, an ALD method, and the like as appropriate.

In this embodiment, for the insulator 216, silicon oxide is deposited by a pulsed DC sputtering method using a silicon target in an atmosphere containing an oxygen gas. The use of the pulsed DC sputtering method can achieve more uniform film thickness and improve the sputtering rate and film quality.

The insulator 212, the insulator 214, and the insulator 216 are preferably successively formed without exposure to the air. For example, a multi-chamber deposition apparatus can be used. As a result, the amounts of hydrogen in the formed insulator 212, insulator 214, and insulator 216 can be reduced, and furthermore, entry of hydrogen into the films in intervals between deposition steps can be inhibited.

Next, an opening reaching the insulator 214 is formed in the insulator 216. A wet etching method may be used for forming the opening; however, a dry etching method is preferably used for fine processing. As the insulator 214, it is preferable to use an insulator that functions as an etching stopper film in forming the opening by etching the insulator 216. For example, in the case where silicon oxide or silicon oxynitride is used for the insulator 216 in which the opening is to be formed, silicon nitride, aluminum oxide, or hafnium oxide is preferably used for the insulator 214.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

After the formation of the opening, a conductive film to be the conductor 205a is formed. The conductive film to be the conductor 205a desirably contains a conductor having a function of inhibiting passage of oxygen. The conductive film to be the conductor 205a can be formed by a sputtering method, a CVD method, an MBE method, a PLD method, an ALD method, or the like. In this embodiment, titanium nitride is deposited for the conductive film to be the conductor 205a.

Next, a conductive film to be the conductor 205b is formed. The conductive film can be formed by a plating method, a sputtering method, a CVD method, an MBE method, a PLD method, an ALD method, or the like. In this embodiment, tungsten is deposited for the conductive film to be the conductor 205b.

Next, by performing CMP treatment, the conductive film to be the conductor 205a and the conductive film to be the conductor 205b are partly removed to expose the insulator 216. As a result, the conductor 205 (the conductor 205a and the conductor 205b) remains only in the opening as illustrated in FIG. 11A. Note that the insulator 216 is partly removed by the CMP treatment in some cases.

Then, the insulator 222 is formed over the insulator 216 and the conductor 205 as illustrated in FIG. 11A. The insulator 222 can be formed by a sputtering method, a CVD method, an MBE method, a PLD method, an ALD method, or the like. In this embodiment, for the insulator 222, hafnium oxide is deposited by an ALD method.

Subsequently, heat treatment is preferably performed. The heat treatment can be performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment performed using a highly purified gas can inhibit entry of moisture or the like into the insulator 222 and the like as much as possible.

In this embodiment, the heat treatment is performed at 400° C. for one hour with a flow rate ratio of a nitrogen gas to an oxygen gas of 4:1 after the formation of the insulator 222. Through the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after the formation of the insulator 224, for example.

Then, an insulating film 224f is formed over the insulator 222 as illustrated in FIG. 11A. The insulating film 224f can be formed by a sputtering method, a CVD method, an MBE method, a PLD method, an ALD method, or the like. In this embodiment, for the insulating film 224f, silicon oxide is deposited by a sputtering method. By using a sputtering method that does not need to use a molecule containing hydrogen as a deposition gas, the hydrogen concentration in the insulating film 224f can be reduced. The hydrogen concentration in the insulating film 224f is preferably reduced in this manner because the insulating film 224f is in contact with the metal oxide 230a in a later step.

Next, a metal oxide film 230af and a metal oxide film 230bf are formed in this order over the insulating film 224f as illustrated in FIG. 11A. Note that it is preferable to form the metal oxide film 230af and the metal oxide film 230bf successively without exposure to the atmospheric environment. The film formation without exposure to the air can inhibit attachment of impurities or moisture from the atmospheric environment to the vicinity of an interface between the metal oxide film 230af and the metal oxide film 230bf, so that the vicinity of the interface can be kept clean.

The metal oxide film 230af and the metal oxide film 230bf can be formed by a sputtering method, a CVD method, an MBE method, a PLD method, an ALD method, or the like. In this embodiment, the metal oxide film 230af and the metal oxide film 230bf are formed by a sputtering method.

For example, in the case where the metal oxide film 230af and the metal oxide film 230bf are formed by a sputtering method, oxygen or a mixed gas of oxygen and a noble gas is used as a sputtering gas. Increasing the proportion of oxygen contained in the sputtering gas can increase the amount of excess oxygen in the formed metal oxide film 230af and metal oxide film 230bf. In the case where the metal oxide films are formed by a sputtering method, an In-M-Zn oxide target or the like can be used.

In particular, when the metal oxide film 230af is formed, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the metal oxide film 230bf is formed by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. Note that one embodiment of the present invention is not limited thereto. In the case where the metal oxide film 230bf is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor for its channel formation region, relatively high field-effect mobility can be obtained. Furthermore, when the film formation is performed while the substrate is being heated, the crystallinity of the metal oxide film can be improved.

In this embodiment, the metal oxide film 230af is formed by a sputtering method using an oxide target with In:Ga:Zn=1:3:4 [atomic ratio]. In addition, the metal oxide film 230bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the metal oxide films is preferably formed to have characteristics required for the metal oxide 230a and the metal oxide 230b by selecting the film formation conditions and the atomic ratios as appropriate.

Note that the insulating film 224f, the metal oxide film 230af, and the metal oxide film 230bf are preferably formed by a sputtering method without exposure to the air. For example, a multi-chamber deposition apparatus can be used. As a result, entry of hydrogen into the insulating film 224f, the metal oxide film 230af, and the metal oxide film 230bf in intervals between film formation steps can be inhibited.

Note that the metal oxide film 230af and the metal oxide film 230bf may be formed by an ALD method. When the metal oxide film 230af and the metal oxide film 230bf are formed by an ALD method, films with a uniform thickness can be formed even in a groove or an opening having a high aspect ratio. The metal oxide film 230af and the metal oxide film 230bf can be formed at a lower temperature by a PEALD method than by a thermal ALD method.

Next, heat treatment is preferably performed. The heat treatment can be performed in a temperature range where the metal oxide film 230af and the metal oxide film 230bf do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment performed using a highly purified gas can inhibit entry of moisture or the like into the metal oxide film 230af, the metal oxide film 230bf, and the like as much as possible.

In this embodiment, the heat treatment is performed at 400° C. for one hour with a flow rate ratio of a nitrogen gas to an oxygen gas of 4:1. Through such heat treatment using the oxygen gas, impurities such as carbon, water, and hydrogen in the metal oxide film 230af and the metal oxide film 230bf can be reduced. The reduction of impurities in the films in this manner improves the crystallinity of the metal oxide film 230af and the metal oxide film 230bf, thereby offering a dense structure with a higher density. Thus, crystalline regions in the metal oxide film 230af and the metal oxide film 230bf are expanded, so that in-plane variations of the crystalline regions in the metal oxide film 230af and the metal oxide film 230bf can be reduced. Accordingly, an in-plane variation of electrical characteristics of the transistor 200 can be reduced.

By performing the heat treatment, hydrogen in the insulator 216, the insulating film 224f, the metal oxide film 230af, and the metal oxide film 230bf moves into the insulator 222 and is absorbed by the insulator 222. In other words, hydrogen in the insulator 216, the insulating film 224f, the metal oxide film 230af, and the metal oxide film 230bf diffuses into the insulator 222. Accordingly, the hydrogen concentration in the insulator 222 increases, while the hydrogen concentrations in the insulator 216, the insulating film 224f, the metal oxide film 230af, and the metal oxide film 230bf decrease.

Specifically, the insulating film 224f functions as the gate insulator of the transistor 200, and the metal oxide film 230af and the metal oxide film 230bf function as the channel formation region of the transistor 200. Thus, the transistor 200 including the insulating film 224f, the metal oxide film 230af, and the metal oxide film 230bf with reduced hydrogen concentrations has high reliability.

Next, the insulating film 224f, the metal oxide film 230af, and the metal oxide film 230bf are processed into island shapes by a lithography method and an etching method, for example. Thus, as illustrated in FIG. 11B, the insulator 224 and the metal oxide 230 (the metal oxide 230a and the metal oxide 230b) each having an island shape are formed. The insulator 224, the metal oxide 230a, and the metal oxide 230b are formed to at least partly overlap with the conductor 205. A dry etching method or a wet etching method can be used as the etching method, and processing by a dry etching method is suitable for fine processing. The insulating film 224f, the metal oxide film 230af, and the metal oxide film 230bf may be processed under different conditions.

In this specification and the like, the term “island shape” refers to a state where two or more components formed using the same material in the same step are physically separated from each other. For example, the term “island-shaped metal oxide” refers to a state where the metal oxide and the adjacent metal oxide are physically separated from each other.

As illustrated in FIG. 11B, the side surface of the insulator 224, the side surface of the metal oxide 230a, and the side surface of the metal oxide 230b may have tapered shapes. The taper angle of each of the side surface of the insulator 224, the side surface of the metal oxide 230a, and the side surface of the metal oxide 230b is, for example, greater than or equal to 60° and less than 90°. Such tapered side surfaces can improve the coverage with the insulator 275 and the like formed in a later step; as a result, the number of defects such as voids can be reduced.

Not being limited to the above, the side surface of the insulator 224, the side surface of the metal oxide 230a, and the side surface of the metal oxide 230b may be substantially perpendicular to the top surface of the insulator 222, for example. With such a structure, when a plurality of transistors 200 are provided, the transistors 200 can be provided at high density in a small area in a plan view.

In the lithography method, first, a resist is exposed to light through a mask. Next, a region exposed to light is removed or left using a developing solution, so that a resist mask is formed. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid, e.g., water, in light exposure. An electron beam or an ion beam may be used instead of the light. A mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

After the resist mask is formed by a lithography method, etching is performed, specifically etching treatment is performed through the resist mask, for example, whereby a conductor, a semiconductor, an insulator, or the like can be processed into a desired shape.

For the etching, a dry etching method or a wet etching method can be used as described above. In the case of using a dry etching method, a halogen-containing etching gas containing one or more of fluorine, chlorine, and bromine can be used as an etching gas. As the etching gas, for example, a gas selected from a C₄F₆ gas, a C₅F₆ gas, a C₄F₈ gas, a CF₄ gas, a SF₆ gas, a CHF₃ gas, a Cl₂ gas, a BC₁₃ gas, a SiCl₄ gas, a BBr₃ gas, and the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. The etching conditions are set as appropriate depending on an object to be etched.

Here, a hard mask formed of an insulator or a conductor may be used under the resist mask. In the case where a hard mask is formed over the metal oxide film 230bf, for example, the hard mask with a desired shape can be formed in the following manner: an insulating film or a conductive film that is the material of the hard mask is formed over the metal oxide film 230bf, a resist mask is formed thereover, and then the hard mask material is etched. The etching of the metal oxide film 230bf and the like may be performed after removal of the resist mask or with the resist mask remaining. In the latter case, the resist mask sometimes disappears during the etching. The hard mask may be removed by etching after the etching of the metal oxide film 230bf and the like. Meanwhile, the hard mask is not necessarily removed when the hard mask material does not affect later steps or can be utilized in later steps. The same applies to the case where a film other than the metal oxide film 230bf is processed using a hard mask.

After the insulator 224, the metal oxide 230a, and the metal oxide 230b are formed, the opening 204b illustrated in FIG. 4B may be formed, for example. Like the opening 204a, the opening 204b can be formed by a lithography method and an etching method, for example. The opening 204b is formed to include a region overlapping with a region where the opening 206 is formed in a later step. For example, the opening 204b is formed to include a region overlapping with the conductor 209.

Next, as illustrated in FIG. 11C, a conductive film 242Af and a conductive film 242Bf are formed in this order over the insulator 222 and the metal oxide 230b. The conductive film 242Af and the conductive film 242Bf can be formed by a sputtering method, a CVD method, an MBE method, a PLD method, an ALD method, or the like. For example, tantalum nitride is deposited by a sputtering method for the conductive film 242Af, and tungsten is deposited by a sputtering method for the conductive film 242Bf. Note that heat treatment may be performed before the formation of the conductive film 242Af. The heat treatment may be performed under reduced pressure, and the conductive film 242Af may be formed successively after the heat treatment without exposure to the air. Such treatment can remove moisture and hydrogen adsorbed on the surface of the metal oxide 230b and can reduce the moisture concentration and the hydrogen concentration in each of the metal oxide 230a and the metal oxide 230b. The heat treatment temperature is preferably higher than or equal to 100° C. and lower than or equal to 400° C. In this embodiment, the heat treatment temperature is 200° C.

Next, the conductive film 242Af and the conductive film 242Bf are processed by a lithography method and an etching method, for example, whereby a conductive layer 242A and a conductive layer 242B are formed as illustrated in FIG. 11D. Thus, at least part of a region of the insulator 222 that overlaps with the conductor 209 is exposed.

A dry etching method or a wet etching method can be used as the etching method, and processing by a dry etching method is suitable for fine processing. The conductive film 242Af and the conductive film 242Bf may be processed under different conditions.

The conductive layer 242A is formed to cover the side surface of the insulator 224 and the top surface and the side surface of the metal oxide 230. Specifically, the conductive layer 242A is formed to cover the side surface of the insulator 224, the side surface of the metal oxide 230a, and the top surface and the side surface of the metal oxide 230b. The conductive layer 242B is formed over the conductive layer 242A. Note that the two conductive layers 242A illustrated in FIG. 11D can be island-shaped layers separated from each other. Alternatively, the two conductive layers 242A illustrated in FIG. 11D may be one island-shaped layer having an opening in a position overlapping with the conductor 209. That is, the two conductive layers 242A illustrated in FIG. 11D may be continuous in a plan view. Like the conductive layers 242A, the two conductive layers 242B illustrated in FIG. 11D may be separated from each other or continuous.

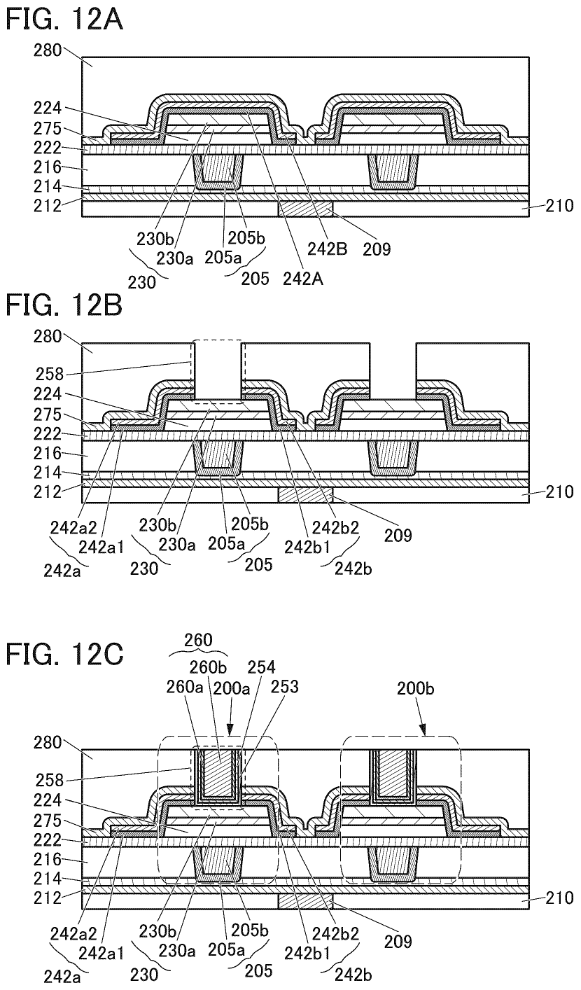

Next, as illustrated in FIG. 12A, the insulator 275 is formed to cover the insulator 224, the metal oxide 230a, the metal oxide 230b, the conductive layer 242A, and the conductive layer 242B. Here, it is preferable that the insulator 275 be in contact with the top surface of the insulator 222. The insulator 275 can be formed by a sputtering method, a CVD method, an MBE method, a PLD method, an ALD method, or the like. The insulator 275 is preferably formed using an insulating film having a function of inhibiting passage of oxygen. For example, silicon nitride is deposited for the insulator 275 by an ALD method. Alternatively, for the insulator 275, aluminum oxide is deposited by a sputtering method, and silicon nitride is deposited thereover by a PEALD method. When the insulator 275 has such a stacked-layer structure, the function of inhibiting diffusion of oxygen and impurities such as water and hydrogen is sometimes improved.

In this manner, the metal oxide 230a, the metal oxide 230b, the conductive layer 242A, and the conductive layer 242B can be covered with the insulator 275, which has a function of inhibiting diffusion of oxygen. This can inhibit diffusion of oxygen from the insulator 280 or the like formed in a later step into the insulator 224, the metal oxide 230a, the metal oxide 230b, the conductive layer 242A, and the conductive layer 242B in a later step.

Then, the insulator 280 is formed over the insulator 275 as illustrated in FIG. 12A. The insulator 280 can be formed by a sputtering method, a CVD method, an MBE method, a PLD method, an ALD method, or the like. A silicon oxide film is formed by a sputtering method as the insulator 280, for example. Here, when the insulator 280 is formed by a sputtering method in an oxygen-containing atmosphere, the insulator 280 can contain excess oxygen. By using a sputtering method that does not need to use a molecule containing hydrogen as a deposition gas, the hydrogen concentration in the insulator 280 can be reduced.

Note that heat treatment may be performed before the formation of the insulator 280. The heat treatment may be performed under reduced pressure, and the insulator 280 may be successively formed after the heat treatment without exposure to the air. Such treatment can remove moisture and hydrogen adsorbed onto the surface of the insulator 275 and the like, and further can reduce the moisture concentration and the hydrogen concentration in each of the metal oxide 230a, the metal oxide 230b, and the insulator 224. For the heat treatment, the above heat treatment conditions can be used. Moreover, CMP treatment is preferably performed after the formation of the insulator 280 to planarize the top surface of the insulator 280.

Next, as illustrated in FIG. 12B, the opening 258 reaching the metal oxide 230b is formed in the insulator 280, the insulator 275, the conductive layer 242B, and the conductive layer 242A. The opening 258 can be formed to include a region overlapping with the conductor 205. Note that the opening 258 can be formed to cover the side surface of the insulator 224 and the top surface and the side surface of the metal oxide 230 as illustrated in FIG. 2B. Specifically, the opening 258 can be formed to cover the side surface of the insulator 224, the side surface of the metal oxide 230a, and the top surface and the side surface of the metal oxide 230b.

By the formation of the opening 258, the conductor 242al covering part of the side surface of the insulator 224 and part of the top surface and part of the side surface of the metal oxide 230 can be formed from the conductive layer 242A. Specifically, the conductor 242al covering part of the side surface of the insulator 224, part of the side surface of the metal oxide 230a, and part of the top surface and part of the side surface of the metal oxide 230b can be formed from the conductive layer 242A. Similarly, the conductor 242b1 can be formed from the conductive layer 242A to cover part of the side surface of the insulator 224 and part of the top surface and part of the side surface of the metal oxide 230. Specifically, the conductor 242b1 can be formed from the conductive layer 242A to cover part of the side surface of the insulator 224, part of the side surface of the metal oxide 230a, and part of the top surface and part of the side surface of the metal oxide 230b. The conductor 242a2 over the conductor 242al and the conductor 242b2 over the conductor 242b1 can be formed from the conductive layer 242B. In this manner, the conductor 242a including the conductor 242al and the conductor 242a2 and the conductor 242b including the conductor 242b1 and the conductor 242b2 are formed.

A dry etching method or a wet etching method can be used for processing part of the insulator 280, part of the insulator 275, part of the conductive layer 242B, and part of the conductive layer 242A, and processing by a dry etching method is suitable for fine processing. Part of the insulator 280, part of the insulator 275, part of the conductive layer 242B, and part of the conductive layer 242A may be processed under different conditions. For example, part of the insulator 280 may be processed by a dry etching method, part of the insulator 275 may be processed by a wet etching method, and part of the conductive layer 242B and part of the conductive layer 242A may be processed by a dry etching method.

Through the etching treatment, impurities are sometimes attached to the top surface of the metal oxide 230b, the side surface of the conductor 242, the side surface of the insulator 275, the side surface of the insulator 280, and the like. In addition, the impurities might diffuse into these components. A step of removing the impurities may be performed. In addition, a damaged region might be formed on the surface of the metal oxide 230b by the above dry etching method. Such a damaged region may be removed. The impurities result from components contained in the insulator 280, the insulator 275, the conductive layer 242B, or the conductive layer 242A, components contained in a member of an apparatus used to form the opening 258, components contained in a gas or a liquid used for etching, and the like. Examples of the impurities include hafnium, aluminum, silicon, tantalum, fluorine, and chlorine.

In particular, impurities such as aluminum and silicon might reduce the crystallinity of the metal oxide 230b. Thus, it is preferable that impurities such as aluminum and silicon be removed from the surface of the metal oxide 230b and the vicinity thereof. The concentration of the impurities is preferably reduced. For example, the concentration of aluminum atoms at the surface of the metal oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, yet still further preferably lower than 0.3 atomic %.

Note that the density of a crystal structure is reduced in a low-crystallinity region of the metal oxide 230b because of impurities such as aluminum and silicon. Thus, a large amount of V_{O}H is formed in the metal oxide 230b, so that it is highly possible that the transistor easily becomes normally on. Hence, the low-crystallinity region of the metal oxide 230b is preferably reduced or removed.

By contrast, the metal oxide 230b preferably has a layered CAAC structure. In particular, the CAAC structure preferably reaches a lower edge portion of a drain in the metal oxide 230b. Here, in the transistor 200, the conductor 242a or the conductor 242b and its vicinity function as a drain. That is, the metal oxide 230b in the vicinity of the lower edge portion of the conductor 242a or the conductor 242b preferably has a CAAC structure. In this manner, the low-crystallinity region of the metal oxide 230b is removed and the CAAC structure is formed also in the drain edge portion, which significantly affects the drain breakdown voltage, so that a variation in the electrical characteristics of the transistor 200 can be further suppressed. In addition, the reliability of the transistor 200 can be improved.

In order to remove impurities and the like attached to the surface of the metal oxide 230b in the above etching step, cleaning treatment is performed. Examples of the cleaning method include wet cleaning using a cleaning solution or the like (which can also be referred to as wet etching treatment), cleaning by plasma treatment using plasma, and cleaning by heat treatment. Note that these methods may be combined as appropriate to perform cleaning.

The wet cleaning can be performed using an aqueous solution in which ammonia water, oxalic acid, phosphoric acid, hydrofluoric acid, or the like is diluted with carbonated water or pure water. The wet cleaning may be performed using pure water, carbonated water, or the like. Alternatively, ultrasonic cleaning using such an aqueous solution, pure water, or carbonated water may be performed as the wet cleaning. Furthermore, these cleanings may be combined as appropriate to perform the wet cleaning.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the metal oxide 230b and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surface of the metal oxide 230a, the metal oxide 230b, or the like or diffused into the metal oxide 230a, the metal oxide 230b, or the like. Furthermore, the crystallinity of the metal oxide 230b can be increased.

After the etching or the cleaning, heat treatment may be performed. The heat treatment can be performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the metal oxide 230a and the metal oxide 230b to reduce oxygen vacancies. In addition, the crystallinity of the metal oxide 230b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

Next, an insulating film and a conductive film are formed to fill the opening 258 and then processed. Thus, as illustrated in FIG. 12C, the insulator 253, the insulator 254, and the conductor 260 (the conductor 260a and the conductor 260b) are formed in a position overlapping with the conductor 205. Specifically, the insulator 253 including a region positioned in the opening 258, the insulator 254 over the insulator 253, the conductor 260a over the insulator 254, and the conductor 260b over the conductor 260a are formed.

First, an insulating film to be the insulator 253 is formed. The insulating film can be formed by a sputtering method, a CVD method, an MBE method, a PLD method, or an ALD method, for example, and is preferably formed by an ALD method. It is preferable that the thickness of the insulator 253 be small and hardly vary. Since an ALD method is a deposition method in which a precursor and a reactant such as an oxidizer are alternately introduced and the film thickness can be adjusted with the number of repetition times of the cycle, accurate control of the film thickness is possible. The insulator 253 is preferably formed with good coverage on the bottom surface and the side surface of the opening 258. By an ALD method, atomic layers can be deposited one by one on the bottom surface and the side surface of the opening 258, whereby the insulator 253 can be formed in the opening 258 with good coverage.

When the insulating film to be the insulator 253 is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the metal oxide 230b can be reduced.

In this embodiment, hafnium oxide is deposited for the insulating film to be the insulator 253 by a thermal ALD method.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the metal oxide 230b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment may be followed successively by heat treatment without exposure to the air. The temperature of the heat treatment is preferably higher than or equal to 100° C. and lower than or equal to 750° C., further preferably higher than or equal to 300° C. and lower than or equal to 500° C., for example.

Furthermore, the microwave treatment can be performed using an oxygen gas and an argon gas, for example. Here, the proportion of the flow rate of the oxygen gas in the whole gas flow rate (hereinafter, also referred to as an oxygen flow rate ratio) in the microwave treatment is higher than 0% and lower than or equal to 100%. The oxygen flow rate ratio is preferably higher than 0% and lower than or equal to 50%. The oxygen flow rate ratio is further preferably higher than or equal to 10% and lower than or equal to 40%. The oxygen flow rate ratio is still further preferably higher than or equal to 10% and lower than or equal to 30%. The carrier concentration in the metal oxide 230b can be reduced by thus performing the microwave treatment in an atmosphere containing oxygen. In addition, preventing introduction of an excess amount of oxygen into the chamber in the microwave treatment can inhibit an excessive reduction in the carrier concentration in the metal oxide 230b.

The microwave treatment in an oxygen-containing atmosphere can convert an oxygen gas into plasma using a high-frequency wave such as a microwave or RF, and apply the oxygen plasma to a region of the metal oxide 230b which is between the conductor 242a and the conductor 242b. By the effect of the plasma, the microwave, or the like, V_{O}H in the region can be divided into an oxygen vacancy and hydrogen, and hydrogen can be removed from the region. That is, V_{O}H contained in the channel formation region can be reduced. Accordingly, oxygen vacancies and V_{O}H in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

The oxygen implanted into the channel formation region has any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the channel formation region has any one or more of the above forms, particularly suitably an oxygen radical. Furthermore, the film quality of the insulator 253 can be improved, leading to higher reliability of the transistor.

Meanwhile, the metal oxide 230b includes a region overlapping with the conductor 242a or the conductor 242b. The region can function as a source region or a drain region. Here, the conductor 242a and the conductor 242b preferably function as blocking films preventing the effects caused by the high-frequency wave such as a microwave or RF, the oxygen plasma, and the like in the microwave treatment in an oxygen-containing atmosphere. Therefore, the conductor 242a and the conductor 242b preferably have a function of blocking an electromagnetic wave of greater than or equal to 300 MHz and less than or equal to 300 GHz, for example, greater than or equal to 2.4 GHz and less than or equal to 2.5 GHz.

The conductor 242a and the conductor 242b block the effects of the high-frequency wave such as a microwave or RF, the oxygen plasma, and the like. Thus, the effects do not reach the region of the metal oxide 230b that overlaps with the conductor 242a or the conductor 242b. Hence, a reduction in V_{O}H and supply of an excess amount of oxygen due to the microwave treatment do not occur in the source region and the drain region, inhibiting a decrease in carrier concentration.

Furthermore, the insulator 253 having a barrier property against oxygen is provided to include a region in contact with the side surface of the conductor 242a and a region in contact with the side surface of the conductor 242b. This can inhibit formation of oxide films on the side surfaces of the conductor 242a and the conductor 242b by the microwave treatment.

Furthermore, the film quality of the insulator 253 can be improved, leading to higher reliability of the transistor.

In the above manner, oxygen vacancies and V_{O}H can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity, specifically the state of the low-resistance regions, before the microwave treatment is performed can be maintained. As a result, a change in the electrical characteristics of the transistor can be inhibited, and thus a variation in the electrical characteristics of transistors in the substrate plane can be inhibited.

In the microwave treatment, thermal energy is directly transmitted to the metal oxide 230b in some cases owing to an electromagnetic interaction between the microwave and a molecule in the metal oxide 230b. The metal oxide 230b may be heated by this thermal energy. Such heat treatment is sometimes referred to as microwave annealing. When microwave treatment is performed in an oxygen-containing atmosphere, an effect equivalent to that of oxygen annealing is sometimes obtained. In the case where hydrogen is contained in the metal oxide 230b, the thermal energy is transmitted to the hydrogen in the metal oxide 230b and the hydrogen activated by the energy is released from the metal oxide 230b in some cases.

Note that the microwave treatment may be performed not after the formation of the insulating film to be the insulator 253 but before the formation of the insulating film.

After the microwave treatment after the formation of the insulating film to be the insulator 253, heat treatment may be performed with the reduced pressure being maintained. Such treatment enables hydrogen in the insulating film, the metal oxide 230b, and the metal oxide 230a to be removed efficiently. Part of hydrogen is gettered by the conductor 242a and the conductor 242b in some cases. Alternatively, the step of performing microwave treatment and then performing heat treatment with the reduced pressure being maintained may be repeated a plurality of cycles. The repetition of the heat treatment enables hydrogen in the insulating film, the metal oxide 230b, and the metal oxide 230a to be removed more efficiently. Note that the temperature of the heat treatment is preferably higher than or equal to 300° C. and lower than or equal to 500° C. The microwave treatment, i.e., the microwave annealing, may also serve as the heat treatment. The heat treatment is not necessarily performed in the case where the metal oxide 230b and the like are adequately heated by the microwave annealing.

Furthermore, the microwave treatment improves the film quality of the insulating film to be the insulator 253, thereby inhibiting diffusion of hydrogen, water, impurities, and the like. Accordingly, hydrogen, water, impurities, and the like can be inhibited from diffusing into the metal oxide 230b, the metal oxide 230a, or the like through the insulator 253 in a later step such as formation of a conductive film to be the conductor 260 or later treatment such as heat treatment.

Next, an insulating film to be the insulator 254 is formed. The insulating film can be formed by a sputtering method, a CVD method, an MBE method, a PLD method, or an ALD method, for example. The insulating film is preferably formed by an ALD method, like the insulating film to be the insulator 253. By an ALD method, the insulating film to be the insulator 254 can be formed to have a small thickness and good coverage. In this embodiment, for the insulating film, silicon nitride is deposited by a PEALD method.

Next, a conductive film to be the conductor 260a and a conductive film to be the conductor 260b are formed in this order. The conductive film to be the conductor 260a and the conductive film to be the conductor 260b can each be formed by a sputtering method, a CVD method, an MBE method, a PLD method, or an ALD method, for example. In this embodiment, titanium nitride is deposited for the conductive film to be the conductor 260a by an ALD method, and tungsten is deposited for the conductive film to be the conductor 260b by a CVD method.

Then, the insulating film to be the insulator 253, the insulating film to be the insulator 254, the conductive film to be the conductor 260a, and the conductive film to be the conductor 260b are polished by CMP treatment until the insulator 280 is exposed. That is, portions of the insulating film to be the insulator 253, the insulating film to be the insulator 254, the conductive film to be the conductor 260a, and the conductive film to be the conductor 260b that are exposed from the opening 258 are removed. Thus, the insulator 253, the insulator 254, the conductor 260a, and the conductor 260b are formed in the opening 258 overlapping with the conductor 205.

The insulator 253 is provided to include a region in contact with the bottom surface of the opening 258 and a region in contact with the side surface of the opening 258, and the insulator 254 is provided along the bottom surface and the side surface of the opening 258 with the insulator 253 therebetween. The conductor 260 is placed to fill the opening 258 with the insulator 253 and the insulator 254 therebetween. In this manner, the transistor 200a and the transistor 200b are formed. As described above, the transistor 200a and the transistor 200b can be fabricated in parallel through the same steps.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 280.

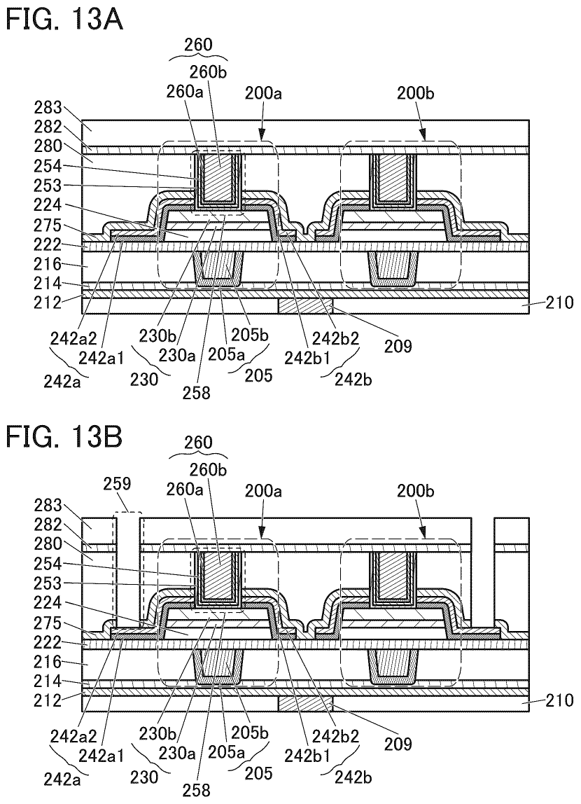

Next, as illustrated in FIG. 13A, the insulator 282 is formed over the insulator 253, the insulator 254, the conductor 260, and the insulator 280. The insulator 282 can be formed by a sputtering method, a CVD method, an MBE method, a PLD method, an ALD method, or the like, and a sputtering method is preferably used. By using a sputtering method that does not need to use a molecule containing hydrogen as a deposition gas, the hydrogen concentration in the insulator 282 can be reduced. After heat treatment performed after the formation of the insulator 253, the insulator 254, the conductor 260a, and the conductor 260b, the insulator 282 may be formed successively without exposure to the air.

In this embodiment, for the insulator 282, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. The RF power applied to the substrate is lower than or equal to 1.86 W/cm², preferably higher than or equal to 0 W/cm² and lower than or equal to 0.62 W/cm². With low RF power, the amount of oxygen implanted into the insulator 280 can be reduced. Alternatively, the insulator 282 may have a stacked-layer structure of two layers. In that case, for example, the lower layer of the insulator 282 is formed with an RF power of 0 W/cm² applied to the substrate, and the upper layer of the insulator 282 is formed with an RF power of 0.62 W/cm² applied to the substrate.

When the insulator 282 is formed by a sputtering method in an oxygen-containing atmosphere, oxygen can be added to the insulator 280 during the formation. Thus, excess oxygen can be contained in the insulator 280. At this time, the insulator 282 is preferably formed while the substrate is being heated.

After the insulator 282 is formed, the opening 204c illustrated in FIG. 4B may be formed, for example. Like the opening 204a and the opening 204b, the opening 204c can be formed by a lithography method and an etching method, for example. The opening 204c is formed to include a region overlapping with a region where the opening 206 is formed in a later step. For example, the opening 204c is formed to include a region overlapping with the conductor 209.

Then, the insulator 283 is formed over the insulator 282 as illustrated in FIG. 13A. The insulator 283 is preferably formed by a sputtering method. By using a sputtering method that does not need to use a molecule containing hydrogen as a deposition gas, the hydrogen concentration in the insulator 283 can be reduced. Without limitation to a sputtering method, the insulator 283 may be formed by a CVD method, an MBE method, a PLD method, an ALD method, and the like as appropriate.

Next, as illustrated in FIG. 13B, the opening 259 reaching the conductor 242a is formed in the insulator 283, the insulator 282, the insulator 280, and the insulator 275. The opening 259 can be formed by a lithography method and an etching method, for example. Specifically, the opening 259 can be formed in the following manner: a resist mask is formed by a lithography method and then part of the insulator 283, part of the insulator 282, part of the insulator 280, and part of the insulator 275 are processed by etching treatment through the resist mask.

Since the opening 259 has a high aspect ratio, part of the insulator 283, part of the insulator 282, part of the insulator 280, and part of the insulator 275 are preferably processed by anisotropic etching. Processing by a dry etching method is particularly preferable because it is suitable for fine processing. Part of the insulator 283, part of the insulator 282, part of the insulator 280, and part of the insulator 275 may be processed under different conditions. For example, part of the insulator 282 is preferably processed under different conditions from part of the insulator 283, part of the insulator 280, and part of the insulator 275 in some cases.

Next, a conductive film to be the conductor 241a and a conductive film to be the conductor 241b are formed in this order. These conductive films can be formed by a sputtering method, a CVD method, an MBE method, a PLD method, an ALD method, or the like.

The conductive film to be the conductor 241a is preferably formed by a deposition method that offers excellent coverage, such as an ALD method, for example. The conductive film to be the conductor 241b is preferably formed by a method that offers excellent embeddability, such as a CVD method or a sputtering method, for example.

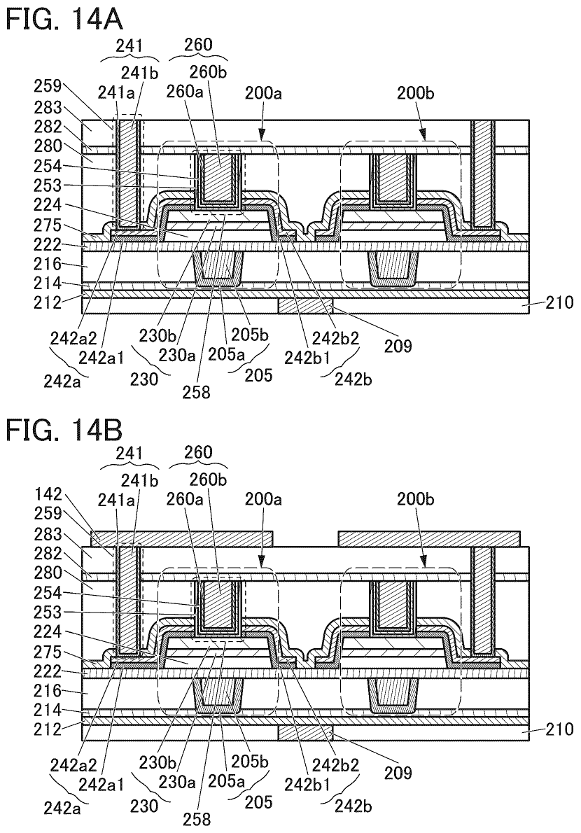

Next, by performing CMP treatment, part of the conductive film to be the conductor 241a and part of the conductive film to be the conductor 241b are removed to expose the top surface of the insulator 283. As a result, these conductive films remain only in the opening 259, so that the conductor 241 (the conductor 241a and the conductor 241b) having a flat top surface can be formed as illustrated in FIG. 14A. Note that the top surface of the insulator 283 is partly removed by the CMP treatment in some cases.

Next, as illustrated in FIG. 14B, the conductor 142 is formed over the conductor 241 and the insulator 283. The conductor 142 is formed to include a region in contact with the conductor 241 and a region in contact with the insulator 283, for example. The conductor 142 is formed to include a region in contact with the top surface of the conductor 241 and a region in contact with the top surface of the insulator 283, for example.

The conductor 142 is formed to include a region overlapping with at least one of the conductor 242a, the conductor 242b, and the conductor 260. For example, the conductor 142 is formed to include a region overlapping with the conductor 242a and a region overlapping with the conductor 260. The conductor 142 can be formed to include a region overlapping with the conductor 242b as well as the region overlapping with the conductor 242a and the region overlapping with the conductor 260.

The conductor 142 can be formed in the following manner, for example: a conductive film is formed over the conductor 241 and the insulator 283 and then a lithography method and an etching method are performed. The conductive film can be formed by a sputtering method, a CVD method, an MBE method, a PLD method, an ALD method, or the like.

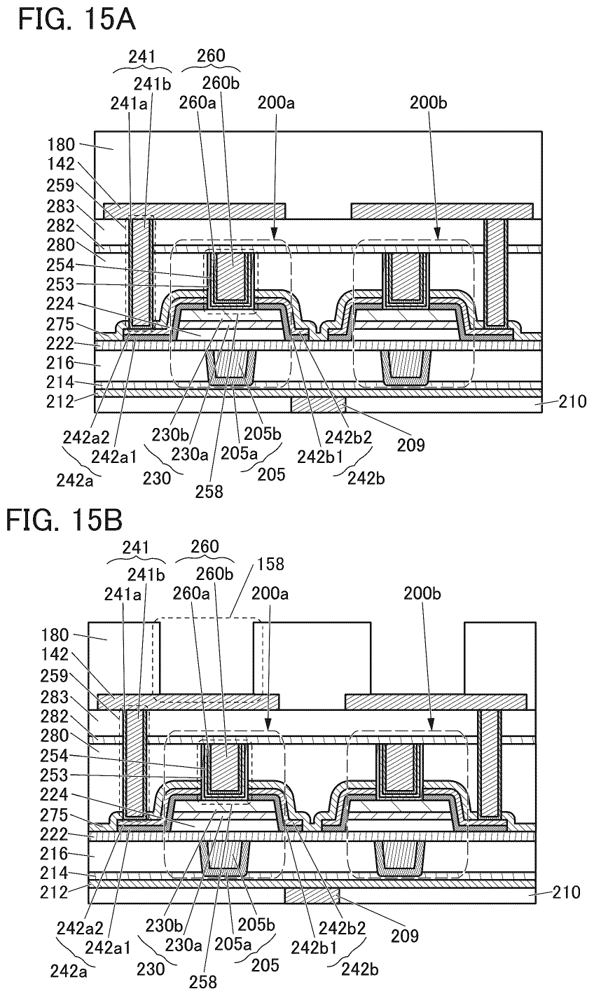

Next, as illustrated in FIG. 15A, the insulator 180 is formed over the insulator 283 to cover the top surface and the side surface of the conductor 142. The insulator 180 can be formed by a sputtering method, a CVD method, an MBE method, a PLD method, an ALD method, or the like, and a sputtering method is preferably used. By using a sputtering method that does not need to use a molecule containing hydrogen as a deposition gas, the hydrogen concentration in the insulator 180 can be reduced.

Next, as illustrated in FIG. 15B, the opening 158 reaching the conductor 142 is formed in the insulator 180. The opening 158 is formed to include a region overlapping with at least one of the conductor 242a, the conductor 242b, and the conductor 260. For example, the opening 158 is formed to include a region overlapping with the conductor 242a and a region overlapping with the conductor 260. The opening 158 can be formed to include a region overlapping with the conductor 242b as well as the region overlapping with the conductor 242a and the region overlapping with the conductor 260.

The opening 158 can be formed by a lithography method and an etching method, for example. Specifically, the opening 158 can be formed in the following manner: a resist mask is formed by a lithography method and then part of the insulator 180 is processed by etching treatment through the resist mask. The etching treatment is preferably performed by anisotropic etching and, for example, a dry etching method is preferably used.

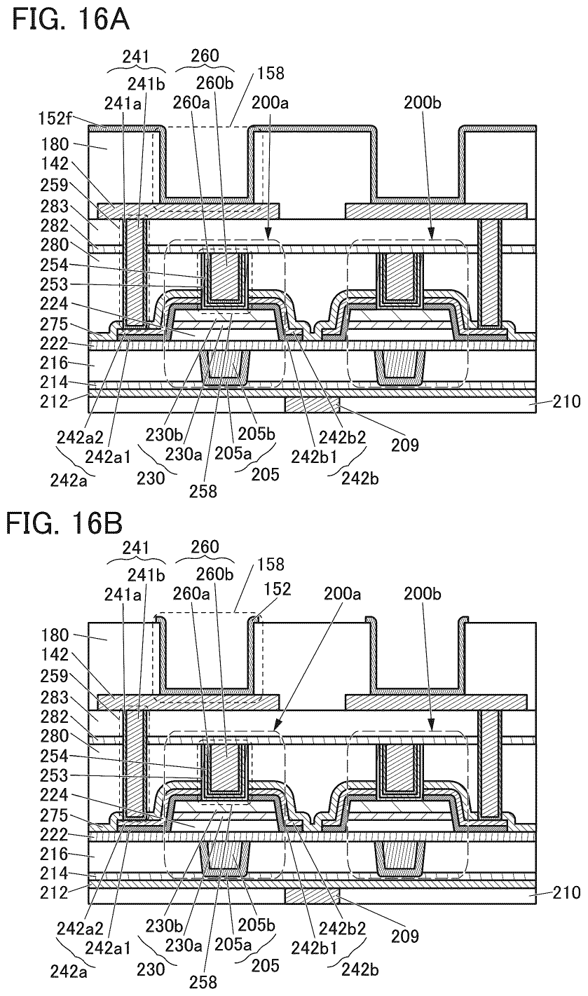

Next, as illustrated in FIG. 16A, a conductive film 152f is formed to cover the opening 158 and the insulator 180. The conductive film 152f is a conductive film to be the conductor 152 in a later step. The conductive film 152f is preferably formed to include a region in contact with the side surface of the opening 158 and a region in contact with the bottom surface of the opening 158. Thus, the conductive film 152f is preferably formed by a deposition method that offers excellent coverage, such as an ALD method. For the conductive film 152f, titanium nitride or tantalum nitride is deposited by an ALD method, for example.

Next, the conductive film 152f is processed by a lithography method and an etching method, for example, so that the conductor 152 is formed in the opening 158 as illustrated in FIG. 16B. The conductor 152 is formed to be electrically connected to the conductor 242a through the conductor 142 and the conductor 241. The conductor 152 can be formed to include a region in contact with the conductor 142 and, for example, can be formed to include a region in contact with the top surface of the conductor 142 and a region in contact with the side surface of the insulator 180. Note that as illustrated in FIG. 16B, the conductor 152 can be formed such that part of the conductor 152 is in contact with the top surface of the insulator 180.

The conductive film 152f may be processed by a CMP method. In that case, the opening 158 can be filled with a filler and CMP treatment can be performed on the filler and the conductive film 152f until the insulator 282 is exposed. In this manner, as illustrated in FIG. 3B, a shape can be obtained in which the uppermost portion of the conductor 152 is level or substantially level with the top surface of the insulator 180. The filler is removed after the formation of the conductor 152.

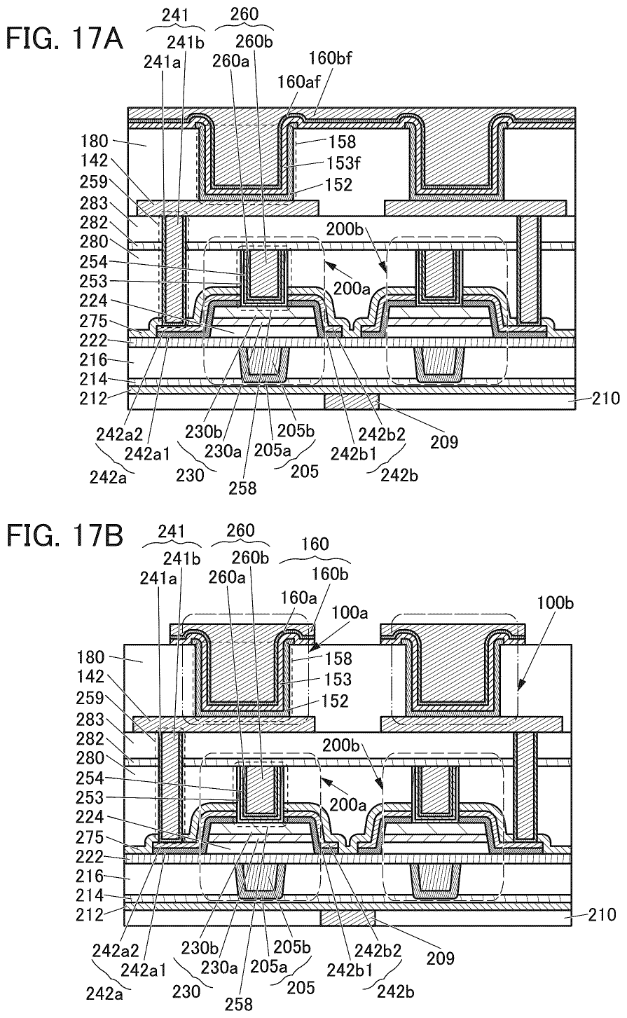

Next, as illustrated in FIG. 17A, an insulating film 153f is formed over the conductor 152 and the insulator 180. The insulating film 153f is an insulating film to be the insulator 153 in a later step. The insulating film 153f is preferably formed to include a region in contact with the conductor 152 in the opening 158. Thus, the insulating film 153f is preferably formed by a deposition method that offers excellent coverage, such as an ALD method. For the insulating film 153f, the above-described high-k material can be used.

Next, as illustrated in FIG. 17A, a conductive film 160af to be the conductor 160a and a conductive film 160bf to be the conductor 160b are formed in this order over the insulating film 153f. The conductive film 160af is a conductive film to be the conductor 160a in a later step, and the conductive film 160bf is a conductive film to be the conductor 160b in a later step. The conductive film 160af is preferably formed to include a region in contact with the insulating film 153f in the opening 158. The conductive film 160bf is preferably formed to fill the opening 158. Accordingly, the conductive film 160af is preferably formed by a deposition method that offers excellent coverage, such as an ALD method, and the conductive film 160bf is preferably formed by a deposition method that offers excellent embeddability, such as a CVD method or a sputtering method. For example, titanium nitride is deposited by an ALD method for the conductive film 160af, and tungsten is deposited by a CVD method for the conductive film 160bf.

Next, the conductive film 160bf is preferably planarized by CMP treatment, for example. In the case of performing the CMP treatment, a silicon oxide film or a silicon oxynitride film may be formed over the conductive film 160bf before the CMP treatment and the CMP treatment may be performed until the silicon oxide film or the silicon oxynitride film is removed.

Next, the insulating film 153f, the conductive film 160af, and the conductive film 160bf are processed by a lithography method and an etching method, for example. Thus, as illustrated in FIG. 17B, the insulator 153 over the conductor 152 and the conductor 160 (the conductor 160a and the conductor 160b) over the insulator 153 are formed. At this time, the insulator 153, the conductor 160a, and the conductor 160b are preferably formed to cover the side end portions of the conductor 152. With such a structure, the conductor 160 and the conductor 152 can be separated from each other by the insulator 153, so that a short circuit between the conductor 160 and the conductor 152 can be inhibited.

Although FIG. 17B illustrates an example in which the insulating film 153f is processed to form the insulator 153, the insulating film 153f is not necessarily processed. Specifically, a structure may be employed in which only the conductive film 160af and the conductive film 160bf are processed and the insulating film 153f is left. In that case, as illustrated in FIG. 3B, part of the insulator 153 is provided to be exposed from the conductor 160. This eliminates the need for processing the insulator 153; thus, the number of steps for fabricating the semiconductor device can be reduced and the productivity can be improved.

In this manner, the capacitor 100a and the capacitor 100b in each of which at least part of each of the conductor 152, the insulator 153, and the conductor 160 is formed in the opening 158 can be formed.

Through the steps illustrated in FIG. 11A to FIG. 17B, the transistor 200 and the capacitor 100 can be formed. In this manner, the memory cell 10 can be formed. Specifically, the memory cell 10a can be formed by forming the transistor 200a and the capacitor 100a, and the memory cell 10b can be formed by forming the transistor 200b and the capacitor 100b.

In the method for fabricating the semiconductor device of one embodiment of the present invention, the transistor 200 is formed and then the insulator 282, the insulator 283, and the insulator 180 are formed over the transistor 200. Next, the opening 158 is formed in the insulator 180 to include a region overlapping with at least one of the conductor 242a, the conductor 242b, and the conductor 260. After that, the capacitor 100 is formed in the opening 158. In this manner, the capacitor 100 is formed to include a region overlapping with at least one of the conductor 242a, the conductor 242b, and the conductor 260. When the semiconductor device is fabricated by this method, for example, the area occupied by the memory cell 10 can be reduced while the capacitance of the capacitor 100 is being ensured as compared with the case where the transistor 200 is formed, an opening reaching the conductor 242a is then provided in the insulator 280, and the capacitor 100 is provided in the opening. Thus, a semiconductor device that can be scaled down or highly integrated can be fabricated by the method for fabricating the semiconductor device of one embodiment of the present invention.

When the capacitor 100 is formed in the opening 158, the conductor 152 and the conductor 160 can face each other with the insulator 153 therebetween not only in a position along the bottom surface of the opening 158 but also in a position along the side surface of the opening 158. Thus, the capacitance per unit area of the capacitor 100 can be larger than that in the case where an opening is not provided and the capacitor 100 is formed over an insulator, for example.

As described above, increasing the capacitance of the capacitor 100 enables data to be retained in the memory cell 10 for a long time. Specifically, increasing the capacitance of the capacitor 100 enables electric charge corresponding to data to be retained in the capacitor 100 for a long time. Thus, the memory cell 10 can be a memory cell with a low refresh operation frequency. Accordingly, a semiconductor device with low power consumption can be fabricated by the method for fabricating the semiconductor device of one embodiment of the present invention.

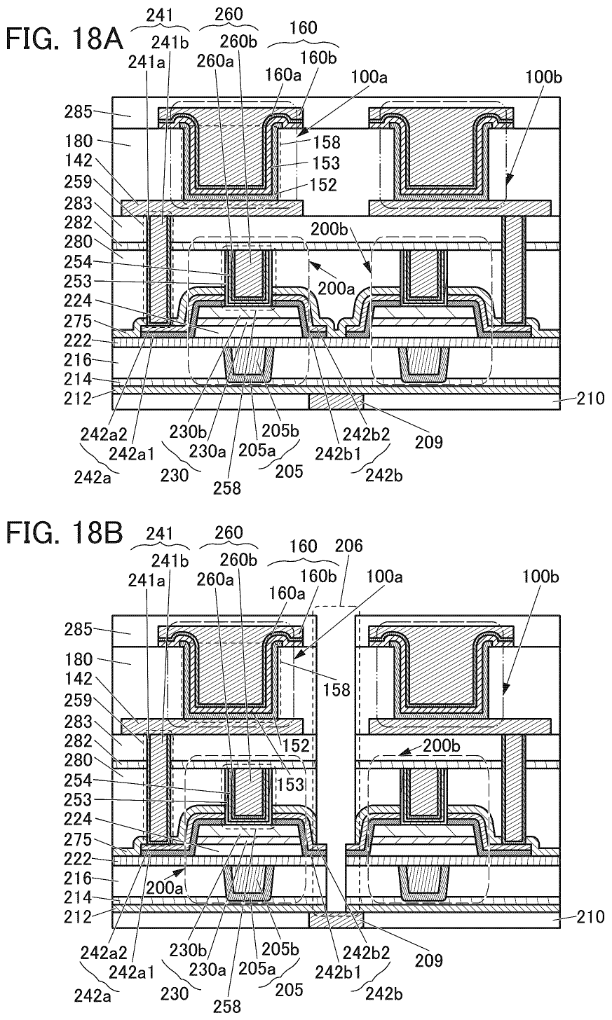

Next, as illustrated in FIG. 18A, the insulator 285 is formed over the insulator 180 and the conductor 160. The insulator 285 can be formed by a sputtering method, a CVD method, an MBE method, a PLD method, an ALD method, or the like, and a sputtering method is preferably used. By using a sputtering method that does not need to use a molecule containing hydrogen as a deposition gas, the hydrogen concentration in the insulator 285 can be reduced.

In this embodiment, for the insulator 285, silicon oxide is deposited by a sputtering method.

Next, as illustrated in FIG. 18B, the opening 206 reaching the conductor 209 is formed in the insulator 285, the insulator 180, the insulator 283, the insulator 282, the insulator 280, the insulator 275, the insulator 222, the insulator 216, the insulator 214, and the insulator 212.

Since the opening 206 has a high aspect ratio, part of the insulator 285, part of the insulator 180, part of the insulator 283, part of the insulator 282, part of the insulator 280, part of the insulator 275, part of the insulator 222, part of the insulator 216, part of the insulator 214, and part of the insulator 212 are preferably processed by anisotropic etching. Processing by a dry etching method is particularly preferable because it is suitable for fine processing. Part of the insulator 285, part of the insulator 180, part of the insulator 283, part of the insulator 282, part of the insulator 280, part of the insulator 275, part of the insulator 222, part of the insulator 216, part of the insulator 214, and part of the insulator 212 may be processed under different conditions. For example, part of the insulator 282, part of the insulator 222, and part of the insulator 214 are sometimes preferably processed under different conditions from part of the insulator 285, part of the insulator 180, part of the insulator 283, part of the insulator 280, part of the insulator 275, part of the insulator 216, and part of the insulator 212.

By the formation of the opening 206, the side surface of the conductor 242b is exposed; for example, the side surface of the conductor 242b in a region not overlapping with the metal oxide 230 is exposed. By the formation of the opening 206, part of the top surface of the conductor 242b is sometimes also exposed. Here, the opening 206 can be formed such that the side surface of the conductor 242b protrudes from the side surface of the insulator 275, the side surface of the insulator 280, the side surface of the insulator 282, the side surface of the insulator 283, the side surface of the insulator 180, and the side surface of the insulator 285, for example.

Here, in the case where the opening 204a is formed in the insulator 214, the opening 204b is formed in the insulator 222, and the opening 204c is formed in the insulator 282 as illustrated in FIG. 4B, the opening 206 is formed to include a region overlapping with the opening 204a, the opening 204b, and the opening 204c in a plan view. The opening 206 is preferably formed in the opening 204a, the opening 204b, and the opening 204c in the plan view.

As described above, a difficult-to-process material, e.g., a hard-to-etch material such as aluminum oxide or hafnium oxide, is sometimes used for the insulator 214, the insulator 222, and the insulator 282. Even in that case, forming the opening 206 after the formation of the opening 204a, the opening 204b, and the opening 204c eliminates the need for etching the insulators formed using a hard-to-etch material at the time of forming the opening 206. Thus, even in the case where a hard-to-etch material is used for the insulator 214, the insulator 222, and the insulator 282, the side surface of the opening 206 can be easily made perpendicular or substantially perpendicular to the substrate surface or the top surface of the conductor 209, for example. This can reduce the area occupied by the opening 206 and the area occupied by one memory cell. Thus, the semiconductor device can be scaled down or highly integrated.

After the opening 206 is formed by anisotropic etching to expose the top surface of the conductor 209, isotropic etching may be performed to make the side surface of the insulator 212, the side surface of the insulator 214, the side surface of the insulator 216, the side surface of the insulator 222, the side surface of the insulator 275, the side surface of the insulator 280, the side surface of the insulator 282, the side surface of the insulator 283, the side surface of the insulator 180, and the side surface of the insulator 285 recede. This can increase the width of the opening 206 in a cross-sectional view. As illustrated in FIG. 5A, for example, the side surface of the conductor 242b can protrude to the center of the opening 206 not only from the side surface of the insulator 275, the side surface of the insulator 280, the side surface of the insulator 282, the side surface of the insulator 283, the side surface of the insulator 180, and the side surface of the insulator 285 but also from the side surface of the insulator 212, the side surface of the insulator 214, the side surface of the insulator 216, and the side surface of the insulator 222. Thus, not only part of the top surface and part of the side surface of the conductor 242b but also part of the bottom surface thereof can be exposed.

Note that the opening 206 having the shape illustrated in FIG. 5B can be formed in the following manner, for example: the opening 206 having the shape illustrated in FIG. 4B is formed by anisotropic etching and then isotropic etching is performed. The diameter of the opening formed by anisotropic etching is made larger or isotropic etching time is made longer than that in the case of forming the opening 206 having the shape illustrated in FIG. 5B, for example, whereby the opening 206 having the shape illustrated in FIG. 6 can be formed. By the formation of the opening 206 having the shape illustrated in FIG. 6, at least part of each of the side surface of the insulator 214 and the side surface of the insulator 282 is exposed.

It is preferable that the anisotropic etching and the isotropic etching be performed successively without exposure to the air with the same etching apparatus under different conditions. For example, in the case where a dry etching method is used for both the anisotropic etching and the isotropic etching, one or more conditions of power supply, bias power, a flow rate of an etching gas, an etching gas species, pressure, and the like are changed so that switching from the anisotropic etching to the isotropic etching can be performed.

Alternatively, different etching methods may be used for the anisotropic etching and the isotropic etching. For example, a dry etching method can be used for the anisotropic etching and a wet etching method can be used for the isotropic etching.

Next, a conductive film to be the conductor 240a and a conductive film to be the conductor 240b are formed in this order. These conductive films can be formed by a sputtering method, a CVD method, an MBE method, a PLD method, an ALD method, or the like.

The conductive film to be the conductor 240a is preferably formed by a deposition method that offers excellent coverage, such as an ALD method, for example. The conductive film to be the conductor 240b is preferably formed by a method that offers excellent embeddability, such as a CVD method or a sputtering method, for example.

Next, by performing CMP treatment, part of the conductive film to be the conductor 240a and part of the conductive film to be the conductor 240b are removed to expose the top surface of the insulator 285. As a result, these conductive films remain in the opening 206, so that the conductor 240 (the conductor 240a and the conductor 240b) having a flat top surface can be formed as illustrated in FIG. 2A. Specifically, the conductor 240a can be formed to include a region in contact with the top surface of the conductor 209 and a region in contact with the side surface of the conductor 242b, and the conductor 240b having a flat top surface can be formed over the conductor 240a. The conductor 240a can be formed to also include a region in contact with the top surface of the conductor 242b. Furthermore, the conductor 240a can be formed to include a region in contact with at least part of the side surface of the insulator 212, a region in contact with at least part of the side surface of the insulator 214, a region in contact with at least part of the side surface of the insulator 216, a region in contact with at least part of the side surface of the insulator 222, a region in contact with at least part of the side surface of the insulator 275, a region in contact with at least part of the side surface of the insulator 280, a region in contact with at least part of the side surface of the insulator 282, a region in contact with at least part of the side surface of the insulator 283, a region in contact with at least part of the side surface of the insulator 180, and a region in contact with at least part of the side surface of the insulator 285. Note that the top surface of the insulator 285 is partly removed by the CMP treatment in some cases.

In this manner, the memory layer 61 illustrated in FIG. 2A can be formed. The memory layer 61 formed through the above steps can be the memory layer 61[1] illustrated in FIG. 7.

After that, the steps of forming the components from the insulator 214 to the conductor 240 described with reference to FIG. 11A to FIG. 18B are performed n−1 times, whereby the memory layer 61[2] to the memory layer 61[n] illustrated in FIG. 7 can be formed.

Next, the insulator 287 is formed over the memory layer 61[n], and the insulator 289 is formed over the insulator 287. The insulator 287 and the insulator 289 can be formed by a sputtering method, a CVD method, an MBE method, a PLD method, an ALD method, or the like, and a sputtering method is preferably used. By using a sputtering method that does not need to use a molecule containing hydrogen as a deposition gas, the hydrogen concentrations in the insulator 287 and the insulator 289 can be reduced.

Through the above steps, the semiconductor device illustrated in FIG. 7 can be fabricated. At least part of the structure, method, and the like described in this embodiment can be implemented in appropriate combination with any of the other embodiments described in this specification.

### Embodiment 2

In this embodiment, a structure example of a memory device including the semiconductor device provided with the memory cell and described in the above embodiment will be described. In this embodiment, a structure example of a memory device in which a layer including a functional circuit having functions of amplifying and outputting a data potential retained in a memory cell is provided between stacked layers including memory cells will be described.

### [Structure Example of Memory Device]

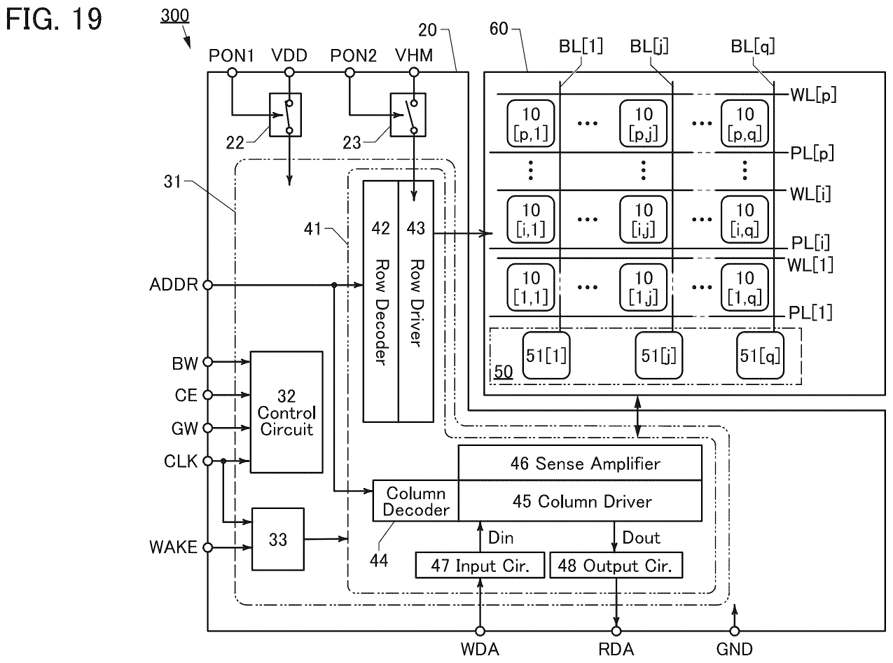

FIG. 19 is a block diagram illustrating a structure example of a memory device 300 of one embodiment of the present invention. The memory device 300 illustrated in FIG. 19 includes the driver circuit 20 and a memory array 60. The memory array 60 includes the plurality of memory cells 10 and the functional layer 50 including a plurality of functional circuits 51. FIG. 19 illustrates an example in which the memory array 60 includes the plurality of memory cells 10 arranged in a matrix of p rows and q columns (p and q are each an integer greater than or equal to 2). The functional circuits 51 are provided for the respective wirings BL, for example. FIG. 19 illustrates an example in which the memory device 300 includes the plurality of functional circuits 51 provided for the respective q wirings BL.

In FIG. 19, the memory cell 10 in the first row and the first column is referred to as a memory cell 10[1,1], and the memory cell 10 in the p-th row and the q-th column is referred to as a memory cell 10[p,q]. In this embodiment and the like, a given row is denoted as an i-th row in some cases. A given column is denoted as a j-th column in some cases. Thus, i is an integer greater than or equal to 1 and less than or equal to p, and j is an integer greater than or equal to 1 and less than or equal to q. In this embodiment and the like, the memory cell 10 in the i-th row and the j-th column is referred to as a memory cell 10[i,j]. Note that in this embodiment and the like, “i+α” (α is a positive or negative integer) is not below 1 and does not exceed p. Similarly, “j+α” is not below 1 and does not exceed q.

The memory array 60 includes p wirings WL extending in the row direction, p wirings PL extending in the row direction, and the q wirings BL extending in the column direction. In this embodiment and the like, the i-th wiring WL and the i-th wiring PL (in the i-th row) are respectively referred to as a wiring WL[i] and a wiring PL[i]. The j-th wiring BL (in the j-th column) is referred to as a wiring BL[j].

The plurality of memory cells 10 provided in the i-th row are electrically connected to the wiring WL[i] and the wiring PL[i]. The plurality of memory cells 10 provided in the j-th column are electrically connected to the wiring BL[j].

A DOSRAM (registered trademark) (Dynamic Oxide Semiconductor Random Access Memory) can be used for the memory array 60. A DOSRAM is a RAM including a 1T (transistor) 1C (capacitor) type memory cell and refers to a memory in which an access transistor is an OS transistor. An OS transistor has extremely low current that flows between a source electrode and a drain electrode in an off state, that is, leakage current. A DOSRAM can retain electric charge corresponding to data stored in a capacitor for a long time by turning off an access transistor. For this reason, the refresh operation frequency of a DOSRAM can be lower than that of a DRAM formed with a transistor containing silicon in its channel formation region (hereinafter, also referred to as a Si transistor). As a result, power consumption can be reduced.

In the memory array 60, the memory cells 10 can be provided in stacked layers by stacking OS transistors as described in Embodiment 1 and the like. For example, in the memory array 60 illustrated in FIG. 19, the memory layer 61[1] to the memory layer 61[n] can be provided in stacked layers as described in Embodiment 1 with reference to FIG. 7. When the memory layer 61[1] to the memory layer 61[n] included in the memory array 60 are placed in a direction perpendicular to the surface of the substrate provided with the driver circuit 20, the memory density in the memory array 60 can be increased. The memory array 60 can be formed by repeating the same manufacturing process in the perpendicular direction.

The wirings BL each function as a bit line for writing and reading data. The wirings WL each function as a word line for controlling the on state and the off state of an access transistor functioning as a switch. The wirings PL each function as a power supply line, e.g., a constant potential line, connected to the capacitor.

The memory cells 10 included in the memory layer 61[1] to the memory layer 61[n] are connected to the functional circuits 51 through the wirings BL. The wirings BL can be placed in the direction perpendicular to the surface of the substrate provided with the driver circuit 20. Thus, the lengths of the wirings between the memory array 60 and the functional circuits 51 can be shortened. Accordingly, a signal transmission distance between the two circuits connected to the wirings BL can be shortened, and the resistance and parasitic capacitance of the wirings BL can be significantly reduced, so that power consumption and signal delays can be reduced. Moreover, even when the capacitance of the capacitors included in the memory cells 10 is reduced, the memory cells 10 can operate.

The functional circuits 51 have functions of amplifying data potentials retained in the memory cells 10 and outputting the amplified data potentials to a sense amplifier 46 included in the driver circuit 20 through a wiring GBL (not illustrated) described later. With this structure, a slight difference between the potentials of the wirings BL can be amplified at the time of data reading. Like the wirings BL, the wiring GBL can be placed in the direction perpendicular to the surface of the substrate provided with the driver circuit 20. When the wirings BL and the wiring GBL are provided in the direction perpendicular to the surface of the substrate, the length of the wiring between the functional circuits 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

The wirings BL include regions in contact with the source electrodes or the drain electrodes of the transistors included in the memory cells 10. That is, the wirings BL are wirings for electrically connecting ones of the source electrodes and the drain electrodes of the transistors included in the memory cells 10 in the layers of the memory array 60 to the functional circuits 51 in the perpendicular direction.

The memory array 60 can be provided over the driver circuit 20 to overlap therewith. When the driver circuit 20 and the memory array 60 are provided to overlap with each other, a signal transmission distance between the driver circuit 20 and the memory array 60 can be shortened. Accordingly, electric resistance and parasitic capacitance between the driver circuit 20 and the memory array 60 are reduced, so that power consumption and signal delays can be reduced. In addition, the memory device 300 can be downsized.

The functional circuits 51 can be freely placed, for example, over a circuit formed using Si transistors, like the memory layer 61[1] to the memory layer 61[n] when the functional circuits 51 are formed using OS transistors which are also used as the transistors included in the memory cells 10 of the DOSRAM. Thus, the integration of the memory device 300 can be easily performed. With the structure in which signals are amplified by the functional circuits 51, a circuit in a subsequent stage, such as the sense amplifier 46, can be downsized, so that the memory device 300 can be downsized.

The driver circuit 20 includes a PSW 22 (power switch), a PSW 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit 32 has a function of performing a logical operation on the signal CE, the signal GW, and the signal BW to determine an operation mode (e.g., a writing operation and a reading operation) of the memory device 300. Alternatively, the control circuit 32 has a function of generating a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when a high-level signal is supplied as the signal WAKE, the signal CLK is input to the voltage generation circuit 33, and the voltage generation circuit 33 generates a negative voltage.

The peripheral circuit 41 is a circuit for performing writing and reading of data to/from the memory cells 10. The peripheral circuit 41 is a circuit which outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of a potential VDD to the peripheral circuit 31. The PSW 23 has a function of controlling supply of a potential VHM to the row driver 43. Here, in the memory device 300, a high power supply potential is the potential VDD and a low power supply potential is a potential GND (a ground potential). In addition, the potential VHM is a high power supply potential used to set a word line at a high level and is higher than the potential VDD. The on state or the off state of the PSW 22 is controlled by the signal PON1, and the on state or the off state of the PSW 23 is controlled by the signal PON2. The number of power domains to which the potential VDD is supplied is one in the peripheral circuit 31 in FIG. 19 but can be more than one. In that case, a power switch is provided for each power domain.

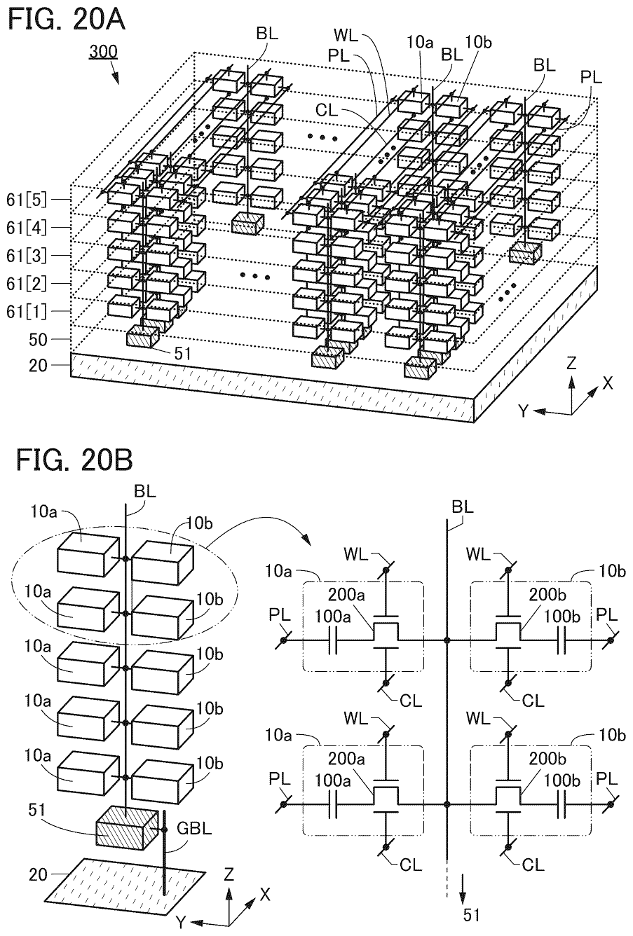

FIG. 20A is a perspective view illustrating a structure example of the memory device 300, and illustrates the driver circuit 20, the functional layer 50 over the driver circuit 20, and the memory layer 61[1] to the memory layer 61[5] over the functional layer 50, for example.

FIG. 20A illustrates the memory cell 10a and the memory cell 10b as the memory cells 10. FIG. 20A also illustrates the wiring WL, the wiring PL, and the wiring CL provided to extend in the X direction and the wiring BL provided to extend in the Z direction. For easy viewing of the drawing, some of the wirings WL and the wirings PL are not illustrated.

In this specification and the like, the X direction and the Y direction refer to directions parallel to the surface of the substrate provided with the driver circuit, and the Z direction refers to a direction perpendicular to the surface of the substrate provided with the driver circuit. The X direction, the Y direction, and the Z direction are perpendicular to one another.

FIG. 20B is a schematic view illustrating the functional circuit 51 connected to the wiring BL illustrated in FIG. 20A and the memory cells 10a and the memory cells 10b included in the memory layer 61[1] to the memory layer 61[5] connected to the wiring BL. FIG. 20B also illustrates the wiring GBL provided between the functional circuit 51 and the driver circuit 20. Note that a structure in which a plurality of memory cells (e.g., the memory cell 10a and the memory cell 10b) are electrically connected to one wiring BL is also referred to as “memory string”. In the drawing, the wiring GBL is sometimes denoted by a bold line for increasing visibility.

FIG. 20B illustrates examples of circuit structures of the memory cell 10a and the memory cell 10b connected to the wiring BL. In each of the memory cells 10, one of the source electrode and the drain electrode of the transistor 200 is electrically connected to one electrode of the capacitor 100. The other of the source electrode and the drain electrode of the transistor 200 is electrically connected to the wiring BL. The other electrode of the capacitor 100 is electrically connected to the wiring PL. The gate electrode (also referred to as the first gate electrode or the top gate electrode) of the transistor 200 is electrically connected to the wiring WL. The back gate electrode (also referred to as the second gate electrode) of the transistor 200 is electrically connected to the wiring CL.

The wiring PL is a wiring for supplying a constant potential for retaining the potential of the other electrode of the capacitor 100. The wiring CL is a wiring for supplying a constant potential for controlling the threshold voltage of the transistor 200. The wiring PL and the wiring CL may have the same potential. In that case, the number of wirings connected to the memory cell 10 can be reduced by connecting the two wirings.

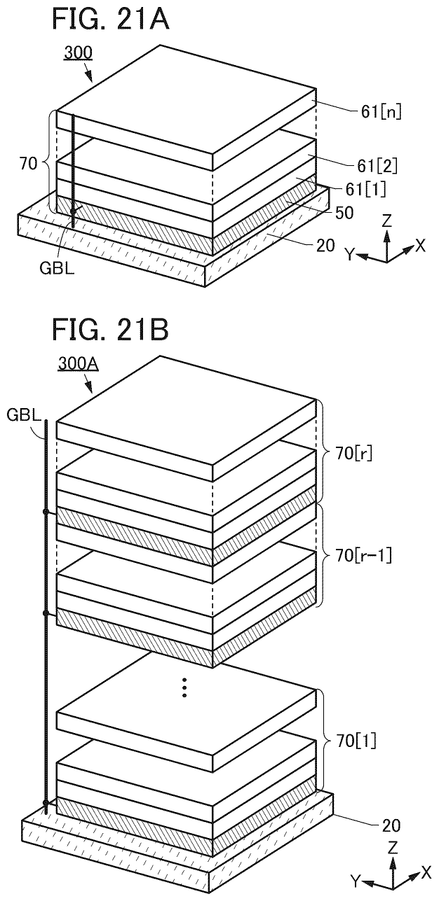

The wiring GBL illustrated in FIG. 20B is provided to electrically connect the driver circuit 20 and the functional circuit 51. FIG. 21A is a schematic view of the memory device 300 in which the functional circuit 51 and the memory layer 61[1] to the memory layer 61[n] are regarded as a repeating unit 70. Although FIG. 21A illustrates one wiring GBL, the wiring GBL is provided as appropriate depending on the number of functional circuits 51 provided in the functional layer 50.

The wiring GBL includes a region in contact with the source electrode or the drain electrode of the transistor included in the functional circuit 51, for example. That is, the wiring GBL is a wiring for electrically connecting one of the source electrode and the drain electrode of the transistor included in the functional circuit 51 in the functional layer 50 to the driver circuit 20 in the perpendicular direction, for example.

The repeating unit 70 including the functional layer 50 and the memory layer 61[1] to the memory layer 61[n] may have a stacked-layer structure. FIG. 21B is a schematic view of a memory device 300A of one embodiment of the present invention. As illustrated in FIG. 21B, a repeating unit 70[1] to a repeating unit 70[r] (r is an integer greater than or equal to 2) are provided in stacked layers in the memory device 300A. The wiring GBL is connected to the functional layers 50 included in the repeating units 70. The wiring GBL is provided as appropriate depending on the number of functional circuits 51 included in the functional layers 50.

### [Structure Examples of Memory Array and Functional Circuit]

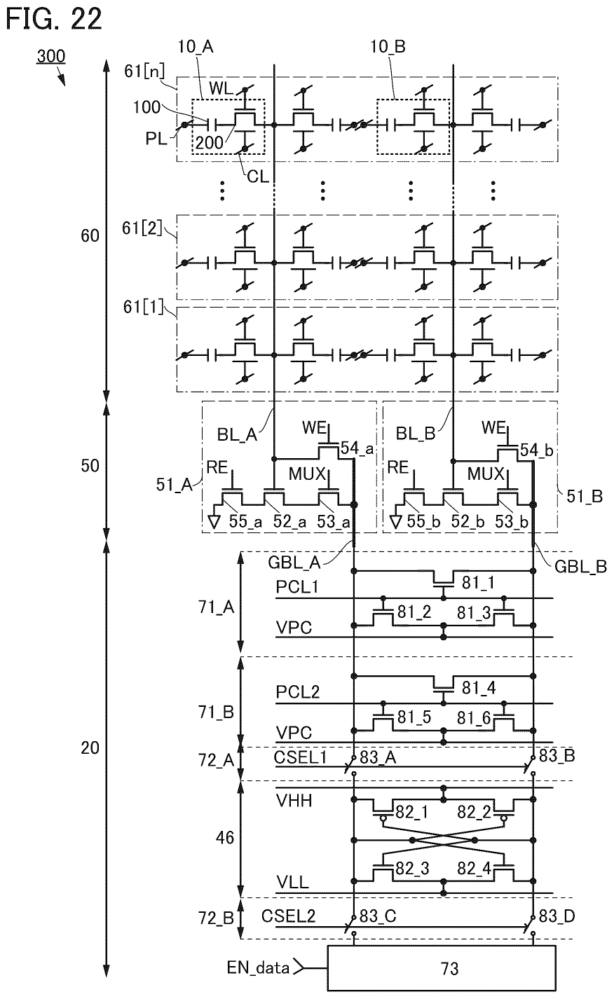

FIG. 22 is a circuit diagram illustrating structure examples of the memory array 60, the functional layer 50, and the driver circuit 20. FIG. 22 illustrates the driver circuit 20 connected to the wirings GBL (a wiring GBL_A and a wiring GBL_B) connected to the functional circuits 51 (a functional circuit 51_A and a functional circuit 51_B) connected to the memory cells 10 (a memory cell 10_A and a memory cell 10_B) connected to different wirings BL (a wiring BL_A and a wiring BL_B). FIG. 22 illustrates, as the driver circuit 20, a precharge circuit 71_A, a precharge circuit 71_B, a switch circuit 72_A, a switch circuit 72_B, and a write/read circuit 73 in addition to the sense amplifier 46.

The functional circuit 51_A includes a transistor 52_a, a transistor 53_a, a transistor 54_a, and a transistor 55_a. The functional circuit 51_B includes a transistor 52_b, a transistor 53_b, a transistor 54_b, and a transistor 55_b. The transistor 52_a to the transistor 55_a and the transistor 52_b to the transistor 55_b can be OS transistors.

The wiring BL_A is electrically connected to a gate electrode of the transistor 52_a and one of a source electrode and a drain electrode of the transistor 54_a. The wiring BL_B is electrically connected to a gate electrode of the transistor 52_b and one of a source electrode and a drain electrode of the transistor 54_b. The wiring GBL_A is electrically connected to one of a source electrode and a drain electrode of the transistor 53_a and the other of the source electrode and the drain electrode of the transistor 54_a. The wiring GBL_B is electrically connected to one of a source electrode and a drain electrode of the transistor 53_b and the other of the source electrode and the drain electrode of the transistor 54_b. The other of the source electrode and the drain electrode of the transistor 53_a is electrically connected to one electrode of the transistor 52_a, and the other of the source electrode and the drain electrode of the transistor 53_b is electrically connected to one electrode of the transistor 52_b. The other of the source electrode and the drain electrode of the transistor 52_a is electrically connected to one electrode of the transistor 55_a, and the other of the source electrode and the drain electrode of the transistor 52_b is electrically connected to one electrode of the transistor 55_b. A ground potential is supplied to the other of the source electrode and the drain electrode of the transistor 55_a and the other of the source electrode and the drain electrode of the transistor 55_b.

The wiring GBL_A and the wiring GBL_B are provided in the perpendicular direction like the wiring BL_A and the wiring BL_B and electrically connected to transistors included in the driver circuit 20. A selection signal MUX is supplied to a gate electrode of the transistor 53_a and a gate electrode of the transistor 53_b. A control signal WE is supplied to a gate electrode of the transistor 54_a and a gate electrode of the transistor 54_b. A control signal RE is supplied to a gate electrode of the transistor 55_a and a gate electrode of the transistor 55_b.

The sense amplifier 46 includes a transistor 82_1, a transistor 82_2, a transistor 82_3, and a transistor 82_4. The precharge circuit 71_A includes a transistor 81_1, a transistor 81_2, and a transistor 81_3. The precharge circuit 71_B includes a transistor 81_4, a transistor 81_5, and a transistor 81_6. The switch circuit 72_A includes a switch 83_A and a switch 83_B, and the switch circuit 72_B includes a switch 83_C and a switch 83_D. The one of the source electrode and the drain electrode of each of the transistor 53_a, the transistor 53_b, the transistor 54_a, and the transistor 54_b is connected to the transistors and the switches included in the precharge circuit 71_A, the precharge circuit 71_B, the sense amplifier 46, and the switch circuit 72_A.

The transistor 81_1 to the transistor 81_6, the transistor 82_3, and the transistor 82_4 can be n-channel transistors. The transistor 82_1 and the transistor 82_2 can be p-channel transistors. The transistor 81_1 to the transistor 81_6, the transistor 82_1 to the transistor 82_4, and the switch 83_A to the switch 83_D can be Si transistors.

The precharge circuit 71_A is a circuit for precharging the wiring BL_A and the wiring BL_B with an intermediate potential VPC corresponding to a potential VDD/2 between the potential VDD and the potential VSS in accordance with a precharge signal supplied to a precharge line PCL1. The precharge circuit 71_B is a circuit for precharging the wiring GBL_A and the wiring GBL_B with the intermediate potential VPC corresponding to the potential VDD/2 between the potential VDD and the potential VSS in accordance with a precharge signal supplied to a precharge line PCL2.

The sense amplifier 46 is electrically connected to a wiring VHH or a wiring VLL. The wiring VHH is a wiring supplying the potential VDD to the sense amplifier 46, and the wiring VLL is a wiring supplying the potential VSS to the sense amplifier 46, for example. The transistor 82_1 to the transistor 82_4 are transistors that form an inverter loop. The potentials of the wiring BL_A and the wiring BL_B precharged by selecting the memory cell 10_A and the memory cell 10_B are changed, and the potentials of the wiring GBL_A and the wiring GBL_B are set to the potential VDD or the potential VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on state and the off state of the switch circuit 72_A are switched under the control of a switch signal CSEL1. In the case where the switches 83_A and 83_B are n-channel transistors, the switches 83_A and 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 46. The on state and the off state of the switch circuit 72_B are switched under the control of a switch signal CSEL2. The switches 83_C and 83_D are similar to the switches 83_A and 83_B.

As illustrated in FIG. 22, the memory device 300 can have a structure in which the memory cells 10, the functional circuits 51, and the sense amplifier 46 are electrically connected to each other through the wirings BL and the wirings GBL provided in the perpendicular direction which is the shortest distance. Even with addition of the functional layer 50 including transistors included in the functional circuits 51, the loads of the wirings BL are reduced, whereby the writing time can be shortened and data reading can be facilitated.

As illustrated in FIG. 22, the transistors included in the functional circuit 51_A and the functional circuit 51_B are controlled in accordance with the control signal WE, the control signal RE, and the selection signal MUX. The transistors can output the potentials of the wirings BL through the wirings GBL to the driver circuit 20 in accordance with the control signals and the selection signal. The functional circuit 51_A and the functional circuit 51_B can function as a sense amplifier including OS transistors. With this structure, a slight difference between the potentials of the wirings BL can be amplified at the time of reading to drive the sense amplifier 46 formed using Si transistors.

### [Operation Example of Memory Cell, Functional Circuit, and Sense Amplifier]

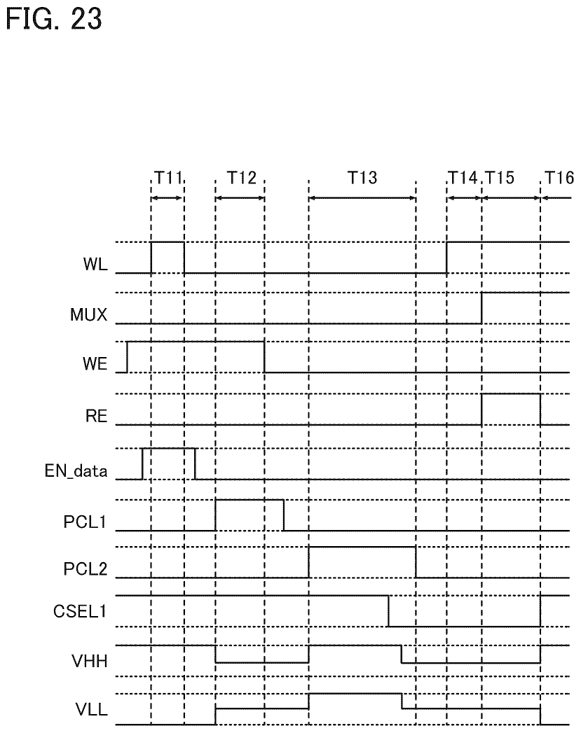

FIG. 23 is a timing chart showing an example of the operation of the circuit diagram illustrated in FIG. 22. In the timing chart shown in FIG. 23, a period T11 corresponds to a period for describing a write operation, a period T12 corresponds to a period for describing a precharge operation of the wiring BL, a period T13 corresponds to a period for describing a precharge operation of the wiring GBL, a period T14 corresponds to a period for describing a charge sharing operation, a period T15 corresponds to a period for describing a standby operation for reading, and a period T16 corresponds to a period for describing a read operation.

In the period T11, the potential of the wiring WL connected to the gate electrode of the transistor 200 included in the memory cell 10 to which a data signal is desired to be written is set to a high level. At this time, the control signal WE and the signal EN_data are set to a high level, and the data signal is written to the memory cell through the wiring GBL and the wiring BL.

In the period T12, in order to precharge the wiring BL, the precharge line PCL1 is set to a high level in a state where the control signal WE is at a high level. The wiring BL is precharged with a precharge potential. In the period T12, the wiring VHH and the wiring VLL through which a power supply potential is supplied to the sense amplifier 46 are both preferably set to the potential VDD/2 in order to suppress power consumption due to flow-through current.

In the period T13, in order to precharge the wiring GBL, the precharge line PCL2 is set to a high level. The wiring GBL is precharged with a precharge potential. In the period T13, the potentials of the wiring VHH and the wiring VLL are both set to the potential VDD, so that the wiring GBL with a large load can be precharged in a short time.

In the period T14, in order to cause charge sharing for balancing electric charge with which the wiring BL and the wiring GBL are precharged, the potential of the wiring WL is set to the high level. Thus, the wiring BL and the wiring GBL have the same potential. In the period T14, the potentials of the wiring VHH and the wiring VLL through which a power supply potential is supplied to the sense amplifier 46 are both preferably set to the potential VDD/2 in order to suppress power consumption due to flow-through current.

In the period T15, the selection signal MUX and the control signal RE are set to a high level. The period T15 is a period during which current flows through the transistor 52 in accordance with the potential of the wiring BL and the potential of the wiring GBL varies in accordance with the current amount. The switch signal CSEL1 is set to a low level so that the variation in the potential of the wiring GBL is not affected by the sense amplifier 46. The wiring VHH or the wiring VLL is similar to that in the period T14.

In the period T16, the switch signal CSEL1 is set to a high level and the variation in the potential of the wiring GBL is amplified by the bit line pair connected to the sense amplifier 46; thus, the data signal written to the memory cell is read.

### [Structure Example of Functional Circuit]

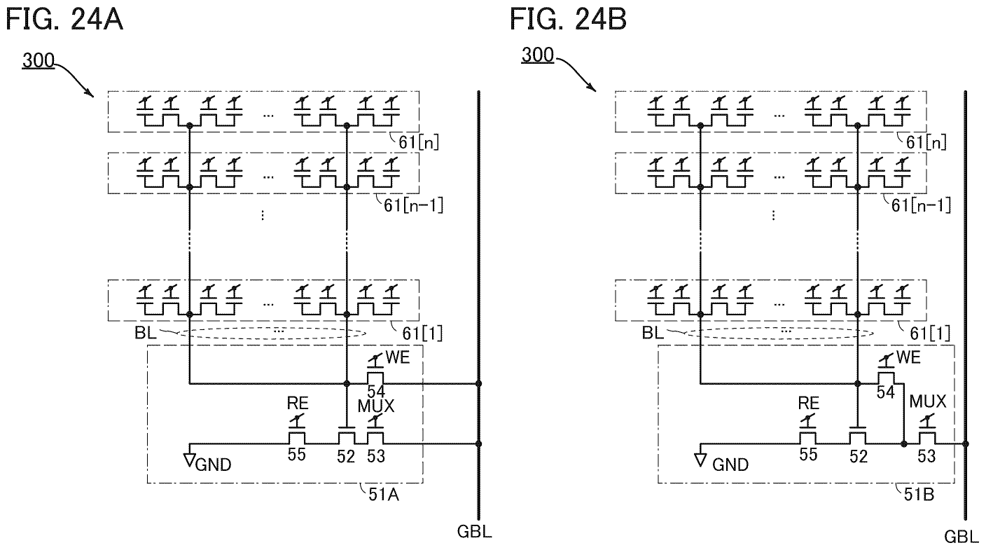

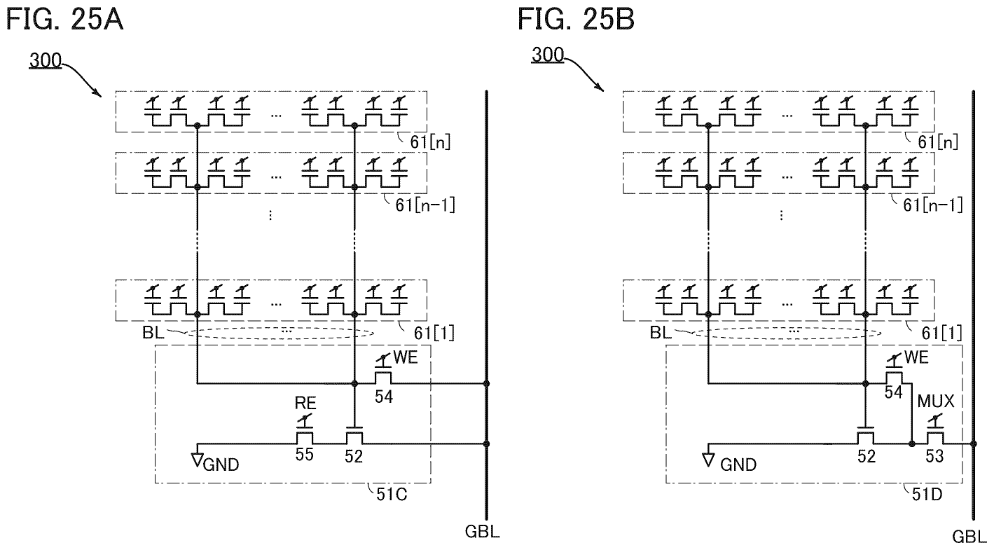

Next, specific structure examples of the functional circuits 51 functioning as the sense amplifier formed with OS transistors included in the functional layer 50 will be described with reference to FIG. 24A, FIG. 24B, FIG. 25A, and FIG. 25B.

FIG. 24A illustrates a functional circuit 51A corresponding to the functional circuit 51_A or the functional circuit 51_B illustrated in FIG. 22. The functional circuit 51A illustrated in FIG. 24A includes the transistor 52 to the transistor 55. Each of the transistor 52 to the transistor 55 can be an OS transistor and is illustrated as an n-channel transistor.

The transistor 52 is a transistor forming a source follower for amplifying the potential of the wiring GBL to a potential corresponding to the potential of the wiring BL in a period when the data signals are read from the memory cells 10. The transistor 53 is a transistor functioning as a switch where the selection signal MUX is input to a gate electrode and electrical continuity between a source electrode and a drain electrode is controlled in accordance with the selection signal MUX. The transistor 54 is a transistor functioning as a switch where the control signal WE is input to a gate electrode and electrical continuity between a source electrode and a drain electrode is controlled in accordance with the control signal WE. The transistor 55 is a transistor functioning as a switch where the control signal RE is input to a gate electrode and electrical continuity between a source electrode and a drain electrode is controlled in accordance with the control signal RE. Note that the potential GND, which is a fixed potential, is supplied to the source side of the transistor 55, for example.

Note that modification examples illustrated in FIG. 24B, FIG. 25A, and FIG. 25B are applicable to the structure of the functional circuit 51A illustrated in FIG. 24A. A functional circuit 51B in FIG. 24B has a structure in which one of the source electrode and the drain electrode of the transistor 54 is connected to not the wiring GBL but one of a source electrode and a drain electrode of the transistor 52. A functional circuit 51C in FIG. 25A corresponds to a structure in which the function of the transistor 53 is performed by the driver circuit 20 and thus the transistor 53 is omitted. A functional circuit 51D in FIG. 25B corresponds to a structure in which the transistor 55 is omitted.

At least part of the structure, method, and the like described in this embodiment can be implemented in appropriate combination with any of the other embodiments described in this specification.

### Embodiment 3

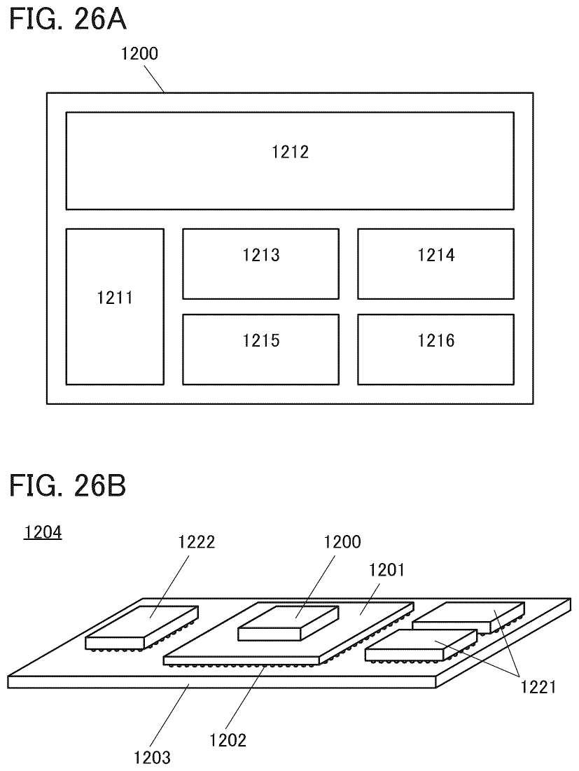

In this embodiment, an example of a chip 1200 on which the semiconductor device of the present invention is mounted will be described with reference to FIG. 26A and FIG. 26B. A plurality of circuits (systems) are mounted on the chip 1200. A technique for integrating a plurality of circuits (systems) into one chip is referred to as system on chip (SoC) in some cases. As illustrated in FIG. 26A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 26B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the DOSRAM described in the above embodiment can be used as the DRAMs 1221. In that case, the DRAMs 1221 can have lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a large number of pieces of data and thus can be used for image processing or a product-sum operation. When an image processing circuit or a product-sum operation circuit including an oxide semiconductor of the present invention is provided in the GPU 1212, image processing and a product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed. The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same steps. Therefore, even when the number of circuits needed for the chip 1200 increases, there is no need to increase the number of steps; thus, the chip 1200 can be fabricated at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is preferably used in portable electronic devices such as a smartphone, a tablet terminal, a laptop PC, and a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip. Furthermore, the GPU module 1204 can be used as an AI system module.

At least part of the structure, method, and the like described in this embodiment can be implemented in appropriate combination with any of the other embodiments described in this specification.

### Embodiment 4

In this embodiment, examples of electronic components and electronic devices in each of which the memory device or the like described in the above embodiment is incorporated will be described. With the use of the memory device described in the above embodiment for the electronic components and the electronic devices described below, the electronic components and the electronic devices can have lower power consumption and higher speed.

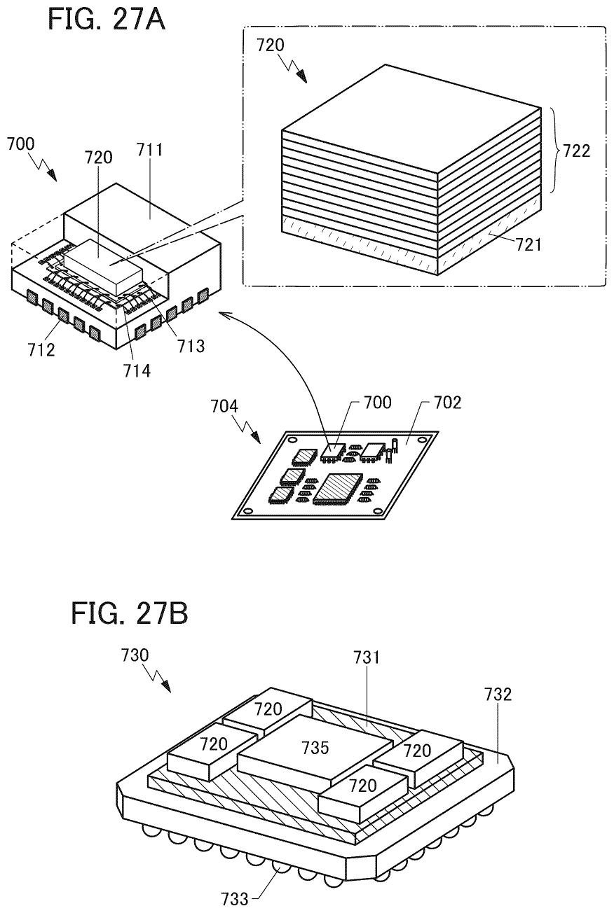

First, examples of an electronic component including a memory device 720 will be described with reference to FIG. 27A and FIG. 27B.

FIG. 27A is a perspective view of an electronic component 700 and a substrate (mounting board 704) on which the electronic component 700 is mounted. The electronic component 700 illustrated in FIG. 27A includes the memory device 720 in a mold 711. FIG. 27A omits part of the electronic component to show the inside of the electronic component 700. The electronic component 700 includes a land 712 outside the mold 711. The land 712 is electrically connected to an electrode pad 713, and the electrode pad 713 is electrically connected to the memory device 720 via a wire 714. The electronic component 700 is mounted on a printed circuit board 702, for example. A plurality of such electronic components are combined and electrically connected to each other on the printed circuit board 702, which forms the mounting board 704.

The memory device 720 includes a driver circuit layer 721 and a memory circuit layer 722.

FIG. 27B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the memory devices 720 are provided over the interposer 731.

The electronic component 730 using the memory device 720 as a high bandwidth memory (HBM) is illustrated as an example. An integrated circuit (a semiconductor device) such as a CPU, a GPU, or an FPGA (Field-Programmable Gate Array) can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be fabricated at lower cost than an integrated circuit because the silicon interposer does not need to be provided with an active element. Since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

A heat sink (radiator plate) may be provided to overlap with the electronic component 730. In the case of providing a heat sink, the heights of integrated circuits provided over the interposer 731 are preferably the same. In the electronic component 730 of this embodiment, the heights of the memory devices 720 and the semiconductor device 735 are preferably the same, for example.

An electrode 733 may be provided on the bottom portion of the package substrate 732 to mount the electronic component 730 on another substrate. FIG. 27B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods other than BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

At least part of the structure, method, and the like described in this embodiment can be implemented in appropriate combination with any of the other embodiments described in this specification.

### Embodiment 5

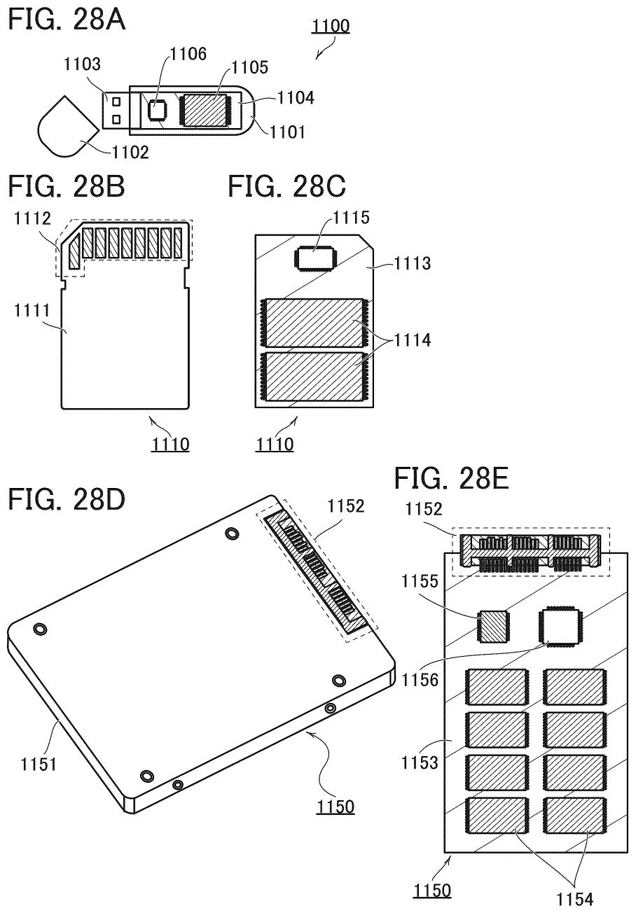

In this embodiment, application examples of the memory device using the memory device described in the above embodiment will be described. The memory device described in the above embodiment can be used in, for example, memory devices of a variety of electronic devices (e.g., information terminals, computers, smartphones, e-book readers, digital cameras (including video cameras), video recording/reproducing devices, and navigation systems). With the use of the memory device described in the above embodiment for the memory devices of the above electronic devices, the electronic devices can have lower power consumption and higher speed. Here, the computers refer not only to tablet computers, laptop computers, and desktop computers, but also to large computers such as server systems. Alternatively, the memory device described in the above embodiment is used for a variety of removable memory devices such as memory cards (e.g., SD cards), USB memories, and solid state drives (SSDs). FIG. 28A to FIG. 28E schematically illustrate some structure examples of removable memory devices. The memory device described in the above embodiment is processed into a packaged memory chip and used in a variety of storage devices and removable memories, for example.

FIG. 28A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The memory device described in the above embodiment can be incorporated in the memory chip 1105 or the like.

FIG. 28B is a schematic external view of an SD card, and FIG. 28C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The memory device described in the above embodiment can be incorporated in the memory chip 1114 or the like.

FIG. 28D is a schematic external view of an SSD, and FIG. 28E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The memory device described in the above embodiment can be incorporated in the memory chip 1154 or the like.

At least part of the structure, method, and the like described in this embodiment can be implemented in appropriate combination with any of the other embodiments described in this specification.

### Embodiment 6

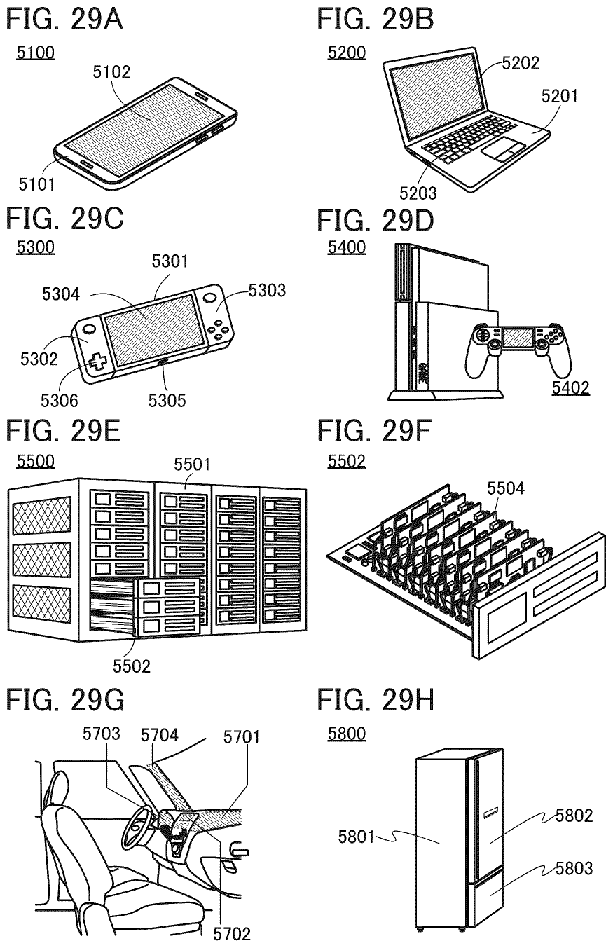

The memory device of one embodiment of the present invention can be used as a processor, e.g., a CPU and a GPU, and a chip. With the use of such a processor, e.g., a CPU or a GPU, or such a chip for an electronic device, the electronic device can have lower power consumption and higher speed. FIG. 29A to FIG. 29H illustrate specific examples of the electronic device provided with the processor, e.g., the CPU or the GPU, or the chip that includes the memory device.

### <Electronic Device and System>

The GPU or the chip of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or laptop information terminal or the like, digital signage, and a large game machine like a pachinko machine. When the GPU or the chip of one embodiment of the present invention is provided in the electronic device, the electronic device can include artificial intelligence.

The electronic device of one embodiment of the present invention may include an antenna. When a signal is received by the antenna, the electronic device can display a video, information, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, gradient, oscillation, odor, or infrared rays).

The electronic device of one embodiment of the present invention can have a variety of functions. For example, the electronic device can have a function of displaying a variety of information (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 29A to FIG. 29H illustrate examples of electronic devices.

### [Information Terminal]

FIG. 29A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is used for the information terminal 5100, the information terminal 5100 can execute an application utilizing artificial intelligence. Examples of the application utilizing artificial intelligence include an application for recognizing a conversation and displaying the contents of the conversation on the display portion 5102; an application for recognizing letters, figures, or the like input to the touch panel of the display portion 5102 by a user and displaying them on the display portion 5102; and an application for performing biometric authentication using fingerprints, voice prints, and the like.

FIG. 29B illustrates a laptop information terminal 5200. The laptop information terminal 5200 includes a main body 5201 of the information terminal, a display portion 5202, and a keyboard 5203.

Like the information terminal 5100 described above, when the chip of one embodiment of the present invention is used for the laptop information terminal 5200, the laptop information terminal 5200 can execute an application utilizing artificial intelligence. Examples of the application utilizing artificial intelligence include design-support software, text correction software, and software for automatic menu generation. Furthermore, with the use of the laptop information terminal 5200, novel artificial intelligence can be developed.

Although FIG. 29A and FIG. 29B illustrate a smartphone and a laptop information terminal, respectively, as examples of the information terminal in the above description, an information terminal other than a smartphone and a laptop information terminal may be used as the information terminal. Examples of information terminals other than a smartphone and a laptop information terminal include a PDA (Personal Digital Assistant), a desktop information terminal, and a workstation.

### [Game Machine]

FIG. 29C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), a video to be output to the display portion 5304 can be output to another video device (not illustrated). In that case, the housing 5302 and the housing 5303 can each function as an operating unit. Thus, a plurality of players can play a game at the same time. The chip described in the above embodiment can be incorporated into the chip provided on a substrate in the housing 5301, the housing 5302, and the housing 5303.

FIG. 29D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit itself, a peripheral circuit, and a module can be reduced.

Furthermore, when the GPU or the chip of one embodiment of the present invention is used for the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time in the game, and actions and words of game characters.

In addition, when a game requiring a plurality of players is played on the portable game machine 5300, the artificial intelligence can create a virtual game player. Thus, the game can be played alone with the game player created by the artificial intelligence as an opponent.

Although the portable game machine and the stationary game machine are illustrated as examples of game machines in FIG. 29C and FIG. 29D, the game machine using the GPU or the chip of one embodiment of the present invention is not limited thereto. Examples of the game machine using the GPU or the chip of one embodiment of the present invention include an arcade game machine installed in entertainment facilities (a game center, an amusement park, or the like), and a throwing machine for batting practice installed in sports facilities.

### [Large Computer]

The GPU or the chip of one embodiment of the present invention can be used in a large computer.

FIG. 29E is a diagram illustrating a supercomputer 5500 as an example of a large computer. FIG. 29F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, and the GPU or the chip described in the above embodiment can be mounted on the substrates 5504.

The supercomputer 5500 is a large computer mainly used for scientific computation. In scientific computation, an enormous amount of arithmetic operation needs to be processed at high speed; hence, power consumption is high and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit itself, a peripheral circuit, and a module can be reduced.

Although a supercomputer is illustrated as an example of a large computer in FIG. 29E and FIG. 29F, a large computer using the GPU or the chip of one embodiment of the present invention is not limited thereto. Other examples of large computers using the GPU or the chip of one embodiment of the present invention include a computer that provides service (a server) and a large general-purpose computer (a mainframe).

### [Moving Vehicle]

The GPU or the chip of one embodiment of the present invention can be used for an automobile, which is a moving vehicle, and the periphery of a driver's seat in the automobile.

FIG. 29G is a diagram illustrating an area around a windshield inside an automobile, which is an example of a moving vehicle. FIG. 29G illustrates a display panel 5701, a display panel 5702, and a display panel 5703 that are attached to a dashboard and a display panel 5704 that is attached to a pillar.

The display panel 5701 to the display panel 5703 can provide a user with a variety of kinds of information by displaying a speedometer, a tachometer, mileage, a fuel gauge, a gear state, air-condition setting, or the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for the view obstructed by the pillar (a blind spot) by showing a video taken by an image capturing device (not illustrated) provided for the automobile. That is, displaying an image taken by the image capturing device provided outside the automobile leads to compensation for the blind spot and an increase in safety. In addition, displaying a video to compensate for a portion that cannot be seen makes it possible for the driver to confirm the safety more naturally and comfortably. The display panel 5704 can also be used as a lighting device.

Since the GPU or the chip of one embodiment of the present invention can be used as a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is used for each of these moving vehicles.

### [Household Appliance]

FIG. 29H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is used for the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, and the like, a function of automatically adjusting temperature to be appropriate for the foods stored in the electric refrigerator-freezer 5800, or the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic devices, the functions of the electronic devices, the application examples of artificial intelligence, their effects, and the like described in this embodiment can be combined as appropriate with the description of another electronic device.

At least part of the structure, method, and the like described in this embodiment can be implemented in appropriate combination with any of the other embodiments described in this specification.

### Embodiment 7

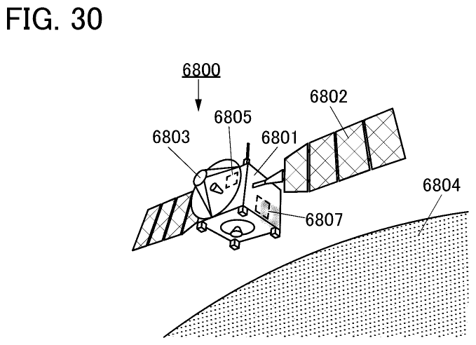

The semiconductor device of one embodiment of the present invention includes an OS transistor. A change in electrical characteristics of the OS transistor due to radiation irradiation is small, i.e., the OS transistor is highly resistant to radiation. Thus, the OS transistor can be suitably used in an environment where radiation can enter. For example, the OS transistor can be suitably used in outer space. In this embodiment, a specific example of using the semiconductor device of one embodiment of the present invention in a device for space will be described with reference to FIG. 30.

FIG. 30 illustrates an artificial satellite 6800 as an example of a device for space. The artificial satellite 6800 includes a body 6801, a solar panel 6802, an antenna 6803, a secondary battery 6805, and a control device 6807. In FIG. 30, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 includes one or more selected from a CPU, a GPU, and a memory device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

At least part of the structure, method, and the like described in this embodiment can be implemented in appropriate combination with any of the other embodiments described in this specification.

### REFERENCE NUMERALS

10: memory cell, 20: driver circuit, 50: functional layer, 52: transistor, 53: transistor, 55: transistor, 61: memory layer, 100: capacitor, 142: conductor, 152f: conductive film, 152: conductor, 153f: insulating film, 153: insulator, 158: opening, 160a: conductor, 160af: conductive film, 160b: conductor, 160bf: conductive film, 160: conductor, 180: insulator, 200: transistor, 203: insulator, 204a: opening, 204b: opening, 204c: opening, 205: conductor, 206: opening, 207: conductor, 208: insulator, 209: conductor, 210: insulator, 212: insulator, 214: insulator, 216: insulator, 222: insulator, 224f: insulating film, 224: insulator, 230a: metal oxide, 230af: metal oxide film, 230b: metal oxide, 230bf: metal oxide film, 230: metal oxide, 240: conductor, 241: conductor, 242a: conductor, 242A: conductive layer, 242Af: conductive film, 242b: conductor, 242B: conductive layer, 242Bf: conductive film, 242: conductor, 253: insulator, 254: insulator, 258: opening, 259: opening, 260: conductor, 275: insulator, 280: insulator, 282: insulator, 283: insulator, 285: insulator, 287: insulator, 289: insulator, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor

1. A semiconductor device comprising:
a first conductor, a first insulator, a second insulator, and a memory cell comprising a transistor and a capacitor,
wherein the transistor comprises a metal oxide, a second conductor, a third conductor, a fourth conductor, and a third insulator,
wherein the capacitor comprises a fifth conductor, a sixth conductor, and a fourth insulator,
wherein the second conductor covers a part of a top surface and a part of a side surface of the metal oxide and is electrically connected to the metal oxide,
wherein the third conductor covers a part of the top surface and a part of the side surface of the metal oxide and is electrically connected to the metal oxide,
wherein the third insulator comprises a region provided between the second conductor and the third conductor,
wherein the fourth conductor is provided over the third insulator,
wherein the first insulator is provided over the fourth conductor,
wherein the second insulator is provided over the first insulator,
wherein the second insulator comprises an opening comprising a region overlapping with at least one of the second conductor, the third conductor, and the fourth conductor,
wherein the fifth conductor comprises a region provided in the opening and is electrically connected to the second conductor,
wherein the fourth insulator is provided over the fifth conductor and comprises a region provided in the opening,
wherein the sixth conductor is provided over the fourth insulator and comprises a region provided in the opening, and
wherein the first conductor comprises a region in contact with a first side surface of the first insulator, a region in contact with a side surface of the second insulator, and a region in contact with a side surface of the third conductor.

2. A semiconductor device comprising:
a plurality of layers each comprising a first conductor, a first insulator, a second insulator, and a memory cell comprising a transistor and a capacitor,
wherein the plurality of layers are stacked,
wherein the transistor comprises a metal oxide, a second conductor, a third conductor, a fourth conductor, and a third insulator,
wherein the capacitor comprises a fifth conductor, a sixth conductor, and a fourth insulator,
wherein the second conductor covers a part of a top surface and a part of a side surface of the metal oxide and is electrically connected to the metal oxide,
wherein the third conductor covers a part of the top surface and a part of the side surface of the metal oxide and is electrically connected to the metal oxide,
wherein the third insulator comprises a region provided between the second conductor and the third conductor,
wherein the fourth conductor is provided over the third insulator,
wherein the first insulator is provided over the fourth conductor,
wherein the second insulator is provided over the first insulator,
wherein the second insulator comprises an opening comprising a region overlapping with at least one of the second conductor, the third conductor, and the fourth conductor,
wherein the fifth conductor comprises a region provided in the opening and is electrically connected to the second conductor,
wherein the fourth insulator is provided over the fifth conductor and comprises a region provided in the opening,
wherein the sixth conductor is provided over the fourth insulator and comprises a region provided in the opening,
wherein the first conductor comprises a region in contact with a first side surface of the first insulator, a region in contact with a side surface of the second insulator, and a region in contact with a side surface of the third conductor, and
wherein the first conductors are electrically connected to each other.

3. The semiconductor device according to claim 1,
wherein the memory cell comprises a seventh conductor and an eighth conductor,
wherein the first insulator is provided over the second conductor,
wherein the seventh conductor comprises a region in contact with a second side surface of the first insulator,
wherein the eighth conductor comprises a region in contact with a top surface of the first insulator, and
wherein the second conductor and the fifth conductor are electrically connected to each other through the seventh conductor and the eighth conductor.

4. The semiconductor device according to claim 3,
wherein the seventh conductor comprises a region in contact with a top surface of the second conductor, and
wherein the eighth conductor comprises a region in contact with a top surface of the seventh conductor.

5. The semiconductor device according to claim 3,
wherein the second insulator covers a top surface and a side surface of the eighth conductor, and
wherein the opening reaches the eighth conductor.

6. The semiconductor device according to claim 1,
wherein the first insulator is provided over the third conductor, and
wherein, in a cross-sectional view, a width of the first conductor in the region in contact with the third conductor is smaller than a width of the first conductor in the region in contact with the first insulator.

7. The semiconductor device according to claim 1,
wherein the metal oxide comprises indium, zinc, and one or more selected from gallium, aluminum, and tin.

8. A method for fabricating a semiconductor device, comprising:
forming a metal oxide;
forming a first conductive film over the metal oxide;
forming a conductive layer covering a top surface and a side surface of the metal oxide by processing the first conductive film;
forming a first conductor and a second conductor each partly covering the top surface and the side surface of the metal oxide by forming a first opening reaching the metal oxide in the conductive layer;
forming a first insulator comprising a region positioned in the first opening and a third conductor over the first insulator;
forming a second insulator over the first conductor, the second conductor, and the third conductor;
forming a third insulator over the second insulator;
forming a second opening comprising a region overlapping with at least one of the first conductor, the second conductor, and the third conductor in the third insulator;
forming a fourth conductor electrically connected to the first conductor, a fourth insulator over the fourth conductor, and a fifth conductor over the fourth insulator in the second opening;
forming a third opening in the third insulator and the second insulator to expose a side surface of the second conductor; and
forming a sixth conductor to comprise a region in contact with the side surface of the second conductor, a region in contact with a first side surface of the second insulator, and a region in contact with a side surface of the third insulator.

9. The method for fabricating a semiconductor device, according to claim 8,
wherein the metal oxide, the first conductor, the second conductor, the third conductor, and the first insulator form a transistor,
wherein the fourth conductor, the fourth insulator, and the fifth conductor form a capacitor, and
wherein the transistor and the capacitor form a memory cell.

10. The method for fabricating a semiconductor device, according to claim 8, further comprising:
forming a fourth opening reaching the first conductor in the second insulator after the second insulator is formed;
forming a seventh conductor in the fourth opening; and
forming an eighth conductor to comprise a region in contact with the seventh conductor and a region in contact with the second insulator,
wherein the third insulator is formed to cover a top surface and a side surface of the eighth conductor, and
wherein the second opening reaching the eighth conductor is formed in the third insulator.

11. The method for fabricating a semiconductor device, according to claim 8,
wherein the third opening is formed such that the side surface of the second conductor protrudes from the side surface of the second insulator.

12. The semiconductor device according to claim 2,
wherein the memory cell comprises a seventh conductor and an eighth conductor,
wherein the first insulator is provided over the second conductor,
wherein the seventh conductor comprises a region in contact with a second side surface of the first insulator,
wherein the eighth conductor comprises a region in contact with a top surface of the first insulator, and
wherein the second conductor and the fifth conductor are electrically connected to each other through the seventh conductor and the eighth conductor.

13. The semiconductor device according to claim 12,
wherein the seventh conductor comprises a region in contact with a top surface of the second conductor, and
wherein the eighth conductor comprises a region in contact with a top surface of the seventh conductor.

14. The semiconductor device according to claim 12,
wherein the second insulator covers a top surface and a side surface of the eighth conductor, and
wherein the opening reaches the eighth conductor.

15. The semiconductor device according to claim 2,
wherein the first insulator is provided over the third conductor, and
wherein, in a cross-sectional view, a width of the first conductor in the region in contact with the third conductor is smaller than a width of the first conductor in the region in contact with the first insulator.

16. The semiconductor device according to claim 2,
wherein the metal oxide comprises indium, zinc, and one or more selected from gallium, aluminum, and tin.
